(19) United States
(12) Patent Application Publication
(10) Pub. No.: US 2025/0160123 A1
(43) Pub. Date: May 15, 2025

(54) SEMICONDUCTOR DEVICE

(71) Applicant: Semiconductor Energy Laboratory Co., Ltd., Atsugi-shi, Kanagawa-ken (JP)

(72) Inventors: Yasuharu HOSAKA, Tochigi (JP); Yukinori SHIMA, Tatebayashi (JP); Masami JINTYOU, Shimotsuga (JP); Masataka NAKADA, Tochigi (JP); Junichi KOEZUKA, Tochigi (JP); Kenichi OKAZAKI, Atsugi (JP)

(21) Appl. No.: 18/835,069

(22) PCT Filed: Mar. 6, 2023
(86) PCT No.: PCT/IB2023/052049

§ 371 Date: Aug. 1, 2024

(30) Foreign Application Priority Data
Mar. 18, 2022 (JP) 2022-044442
Mar. 24, 2022 (JP) 2022-049086

(51) Int. Cl. H10K 59/121; H10K 59/12

(52) U.S. Cl. CPC H10K 59/1213; H10K 59/1201

(57) ABSTRACT

A semiconductor device including a transistor having a minute size is provided. The semiconductor device includes a transistor, a first insulating layer, and a second insulating layer. The transistor includes a first semiconductor layer, a first conductive layer, a second conductive layer including a region overlapping with the first conductive layer with the first insulating layer therebetween, a third conductive layer, and a third insulating layer. The second conductive layer and the first insulating layer have a first opening reaching the first conductive layer. The first semiconductor layer is in contact with a top surface and a side surface of the second conductive layer, a side surface of the first insulating layer, and a top surface of the first conductive layer. The third insulating layer is provided over the first insulating layer, the first semiconductor layer, and the second conductive layer. The third conductive layer is provided over the third insulating layer. The second insulating layer is provided over the third conductive layer and the third insulating layer.

### TECHNICAL FIELD

One embodiment of the present invention relates to a semiconductor device, a display apparatus, a display module, and an electronic device. One embodiment of the present invention relates to a manufacturing method of a semiconductor device and a manufacturing method of a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method of driving any of them, and a manufacturing method of any of them.

### BACKGROUND ART

Semiconductor devices including transistors have been widely used in display apparatuses and electronic devices, and the semiconductor devices have been required to achieve increasingly high integration and high-speed operation. In the case where semiconductor devices are applied to high-definition display apparatuses, highly integrated semiconductor devices are required, for example. One way of increasing the degree of integration of transistors is the recent development of transistors having minute sizes.

In recent years, display apparatuses applicable to virtual reality (VR), augmented reality (AR), substitutional reality (SR), or mixed reality (MR) have been needed. VR, AR, SR, and MR are collectively referred to as XR (Extended Reality). Display apparatuses for XR have been desired to have higher definition and higher color reproducibility so that realistic feeling and the sense of immersion can be enhanced. Examples of devices applicable to such display apparatuses include a liquid crystal display apparatus and a light-emitting apparatus including a light-emitting device (also referred to as a light-emitting element) such as an organic EL (Electro Luminescence) device or a light-emitting diode (LED).

Patent Document 1 discloses a display apparatus using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a semiconductor device including a transistor having a minute size and a manufacturing method thereof. Another object of one embodiment of the present invention is to provide a small semiconductor device and a manufacturing method thereof. Another object of one embodiment of the present invention is to provide a semiconductor device including a transistor with a high on-state current and a manufacturing method thereof. Another object of one embodiment of the present invention is to provide a semiconductor device having favorable electrical characteristics and a manufacturing method thereof. Another object of one embodiment of the present invention is to provide a highly reliable semiconductor device and a manufacturing method thereof. Another object of one embodiment of the present invention is to provide a manufacturing method of a semiconductor device with high productivity. Another object of one embodiment of the present invention is to provide a novel semiconductor device and a manufacturing method thereof.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor, a second transistor, a first insulating layer, and a second insulating layer. The first transistor includes a first semiconductor layer, a first conductive layer, a second conductive layer including a region overlapping with the first conductive layer with the first insulating layer therebetween, a third conductive layer, and a third insulating layer. The second conductive layer and the first insulating layer have a first opening reaching the first conductive layer. The first semiconductor layer is in contact with a top surface and a side surface of the second conductive layer, a side surface of the first insulating layer, and a top surface of the first conductive layer. The third insulating layer is provided over the first insulating layer, the first semiconductor layer, and the second conductive layer. The third conductive layer is provided over the third insulating layer. The second insulating layer is provided over the third conductive layer and the third insulating layer. The second transistor includes a second semiconductor layer, the second conductive layer, a fourth conductive layer including a region overlapping with the second conductive layer with the second insulating layer and the third insulating layer therebetween, a fifth conductive layer, and a fourth insulating layer. The fourth conductive layer, the second insulating layer, and the third insulating layer have a second opening reaching the second conductive layer. The second semiconductor layer is in contact with a top surface and a side surface of the fourth conductive layer, a side surface of the second insulating layer, a side surface of the third insulating layer, and the top surface of the second conductive layer. The fourth insulating layer is provided over the second semiconductor layer. The fifth conductive layer is provided over the fourth insulating layer. The first insulating layer has a stacked-layer structure of a fifth insulating layer and a sixth insulating layer over the fifth insulating layer. In the semiconductor device, the sixth insulating layer includes a region having a higher film density than the fifth insulating layer.

One embodiment of the present invention is a semiconductor device including a first transistor, a second transistor, a first insulating layer, and a second insulating layer. The first transistor includes a first semiconductor layer, a first conductive layer, a second conductive layer including a region overlapping with the first conductive layer with the first insulating layer therebetween, a third conductive layer, and a third insulating layer. The second conductive layer and the first insulating layer have a first opening reaching the first conductive layer. The first semiconductor layer is in contact with a top surface and a side surface of the second conductive layer, a side surface of the first insulating layer, and a top surface of the first conductive layer. The third insulating layer is provided over the first insulating layer, the first semiconductor layer, and the second conductive layer. The third conductive layer is provided over the third insulating layer. The second insulating layer is provided over the third conductive layer and the third insulating layer. The second transistor includes a second semiconductor layer, the second conductive layer, a fourth conductive layer including a region overlapping with the second conductive layer with the second insulating layer and the third insulating layer therebetween, a fifth conductive layer, and a fourth insulating layer. The fourth conductive layer, the second insulating layer, and the third insulating layer have a second opening reaching the second conductive layer. The second semiconductor layer is in contact with a top surface and a side surface of the fourth conductive layer, a side surface of the second insulating layer, a side surface of the third insulating layer, and the top surface of the second conductive layer. The fourth insulating layer is provided over the second semiconductor layer. The fifth conductive layer is provided over the fourth insulating layer. The first insulating layer has a stacked-layer structure of a fifth insulating layer and a sixth insulating layer over the fifth insulating layer. The sixth insulating layer includes a region having a higher nitrogen content than the fifth insulating layer.

One embodiment of the present invention is a semiconductor device including a first transistor, a second transistor, a first insulating layer, and a second insulating layer. The first transistor includes a first semiconductor layer, a first conductive layer, a second conductive layer including a region overlapping with the first conductive layer with the first insulating layer therebetween, a third conductive layer, and a third insulating layer. The second conductive layer and the first insulating layer have a first opening reaching the first conductive layer. The first semiconductor layer is in contact with a top surface and a side surface of the second conductive layer, a side surface of the first insulating layer, and a top surface of the first conductive layer. The third insulating layer is provided over the first insulating layer, the first semiconductor layer, and the second conductive layer. The third conductive layer is provided over the third insulating layer. The second insulating layer is provided over the third conductive layer and the third insulating layer. The second transistor includes a second semiconductor layer, the third conductive layer, a fourth conductive layer comprising a region overlapping with the third conductive layer with the second insulating layer therebetween, a fifth conductive layer, and a fourth insulating layer. The fourth conductive layer and the second insulating layer have a second opening reaching the third conductive layer. The second semiconductor layer is in contact with a top surface and a side surface of the fourth conductive layer, a side surface of the second insulating layer, and a top surface of the third conductive layer. The fourth insulating layer is provided over the second semiconductor layer. The fifth conductive layer is provided over the fourth insulating layer. The first insulating layer has a stacked-layer structure of a fifth insulating layer and a sixth insulating layer over the fifth insulating layer. The sixth insulating layer includes a region having a higher film density than the fifth insulating layer.

One embodiment of the present invention is a semiconductor device including a first transistor, a second transistor, a first insulating layer, and a second insulating layer. The first transistor includes a first semiconductor layer, a first conductive layer, a second conductive layer including a region overlapping with the first conductive layer with the first insulating layer therebetween, a third conductive layer, and a third insulating layer. The second conductive layer and the first insulating layer have a first opening reaching the first conductive layer. The first semiconductor layer is in contact with a top surface and a side surface of the second conductive layer, a side surface of the first insulating layer, and a top surface of the first conductive layer. The third insulating layer is provided over the first insulating layer, the first semiconductor layer, and the second conductive layer. The third conductive layer is provided over the third insulating layer. The second insulating layer is provided over the third conductive layer and the third insulating layer. The second transistor includes a second semiconductor layer, the third conductive layer, a fourth conductive layer comprising a region overlapping with the third conductive layer with the second insulating layer therebetween, a fifth conductive layer, and a fourth insulating layer. The fourth conductive layer and the second insulating layer have a second opening reaching the third conductive layer. The second semiconductor layer is in contact with a top surface and a side surface of the fourth conductive layer, a side surface of the second insulating layer, and a top surface of the third conductive layer. The fourth insulating layer is provided over the second semiconductor layer. The fifth conductive layer is provided over the fourth insulating layer. The first insulating layer has a stacked-layer structure of a fifth insulating layer and a sixth insulating layer over the fifth insulating layer. In the semiconductor device, the sixth insulating layer includes a region having a higher nitrogen content than the fifth insulating layer.

In the above semiconductor device, the first insulating layer preferably includes a seventh insulating layer. The seventh insulating layer is preferably positioned between the fifth insulating layer and the first conductive layer. The seventh insulating layer preferably includes a region having a higher film density than the fifth insulating layer.

In the above semiconductor device, the first insulating layer preferably includes a seventh insulating layer. The seventh insulating layer is preferably positioned between the fifth insulating layer and the first conductive layer. The seventh insulating layer preferably includes a region having a higher nitrogen content than the fifth insulating layer.

In the above semiconductor device, the thickness of the first insulating layer is preferably greater than or equal to 0.01 μm and less than 3 μm.

In the above semiconductor device, the first conductive layer preferably includes an oxide conductor.

In the above semiconductor device, the first conductive layer preferably includes a sixth conductive layer and a seventh conductive layer over the sixth conductive layer. The seventh conductive layer preferably has a third opening. The first semiconductor layer preferably includes a region in contact with the sixth conductive layer through the third opening. The sixth conductive layer preferably includes an oxide conductor.

In the above semiconductor device, the first semiconductor layer and the second semiconductor layer each preferably contain indium. The proportion of the number of indium atoms in the total number of atoms of all contained metal elements is preferably higher in the second semiconductor layer than in the first semiconductor layer.

In the above semiconductor device, the first semiconductor layer and the second semiconductor layer each preferably contain indium. The proportion of the number of indium atoms in the total number of atoms of all contained metal elements is preferably higher in the first semiconductor layer than in the second semiconductor layer.

### Effect of the Invention

One embodiment of the present invention can provide a semiconductor device including a transistor having a minute size and a manufacturing method thereof. One embodiment of the present invention can provide a small semiconductor device and a manufacturing method thereof. One embodiment of the present invention can provide a semiconductor device including a transistor with a high on-state current and a manufacturing method thereof. One embodiment of the present invention can provide a semiconductor device having favorable electrical characteristics and a manufacturing method thereof. One embodiment of the present invention can provide a highly reliable semiconductor device and a manufacturing method thereof. One embodiment of the present invention can provide a manufacturing method of a semiconductor device with high productivity. One embodiment of the present invention can provide a novel semiconductor device and a manufacturing method thereof.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B is an equivalent circuit diagram of the semiconductor device. FIG. 1C is a cross-sectional view illustrating the example of the semiconductor device.

FIG. 2A is a cross-sectional view illustrating an example of a semiconductor device. FIG. 2B is a perspective view illustrating the example of the semiconductor device.

FIG. 3A to FIG. 3E are perspective views illustrating examples of a semiconductor device.

FIG. 4A to FIG. 4E are perspective views illustrating examples of a semiconductor device.

FIG. 5A is a top view illustrating an example of a semiconductor device. FIG. 5B is a cross-sectional view illustrating the example of the semiconductor device.

FIG. 6A is a top view illustrating an example of a semiconductor device. FIG. 6B is a cross-sectional view illustrating the example of the semiconductor device.

FIG. 7A and FIG. 7B are cross-sectional views illustrating examples of a semiconductor device.

FIG. 8A and FIG. 8B are cross-sectional views illustrating examples of a semiconductor device.

FIG. 9A and FIG. 9B are cross-sectional views illustrating examples of a semiconductor device.

FIG. 10 is a cross-sectional view illustrating an example of a semiconductor device.

FIG. 11A is a top view illustrating an example of a semiconductor device. FIG. 11B and FIG. 11C are cross-sectional views illustrating the example of the semiconductor device.

FIG. 12A is a top view illustrating an example of a semiconductor device. FIG. 12B and FIG. 12C are cross-sectional views illustrating the example of the semiconductor device.

FIG. 13A is a top view illustrating an example of a semiconductor device. FIG. 13B is an equivalent circuit diagram of the semiconductor device. FIG. 13C is a cross-sectional view illustrating the example of the semiconductor device.

FIG. 14 is a cross-sectional view illustrating an example of a semiconductor device.

FIG. 15A and FIG. 15B are equivalent circuit diagrams of a semiconductor device. FIG. 15C is a top view illustrating an example of the semiconductor device.

FIG. 16 is a cross-sectional view illustrating an example of a semiconductor device.

FIG. 17 is a perspective view illustrating an example of a semiconductor device.

FIG. 18A to FIG. 18D are perspective views illustrating examples of a semiconductor device.

FIG. 19A and FIG. 19B are equivalent circuit diagrams of a semiconductor device. FIG. 19C is a top view illustrating an example of the semiconductor device.

FIG. 20 is a cross-sectional view illustrating an example of a semiconductor device.

FIG. 21 is a perspective view illustrating an example of a semiconductor device.

FIG. 22A to FIG. 22D are perspective views illustrating examples of a semiconductor device.

FIG. 23A1 and FIG. 23B1 are perspective views illustrating an example of a method for manufacturing a semiconductor device. FIG. 23A2 and FIG. 23B2 are cross-sectional views illustrating the example of the method for manufacturing the semiconductor device.

FIG. 24A1 and FIG. 24B1 are perspective views illustrating an example of a method for manufacturing a semiconductor device. FIG. 24A2 and FIG. 24B2 are cross-sectional views illustrating the example of the method for manufacturing the semiconductor device.

FIG. 25A1 and FIG. 25B1 are perspective views illustrating an example of a method for manufacturing a semiconductor device. FIG. 25A2 and FIG. 25B2 are cross-sectional views illustrating the example of the method for manufacturing the semiconductor device.

FIG. 26A1 and FIG. 26B1 are perspective views illustrating an example of a method for manufacturing a semiconductor device. FIG. 26A2 and FIG. 26B2 are cross-sectional views illustrating the example of the method for manufacturing the semiconductor device.

FIG. 27A1 and FIG. 27B1 are perspective views illustrating an example of a method for manufacturing a semiconductor device. FIG. 27A2 and FIG. 27B2 are cross-sectional views illustrating the example of the method for manufacturing the semiconductor device.

FIG. 28A1 and FIG. 28B1 are perspective views illustrating an example of a method for manufacturing a semiconductor device. FIG. 28A2 and FIG. 28B2 are cross-sectional views illustrating the example of the method for manufacturing the semiconductor device.

FIG. 29A1 and FIG. 29B1 are perspective views illustrating an example of a method for manufacturing a semiconductor device. FIG. 29A2 and FIG. 29B2 are cross-sectional views illustrating the example of the method for manufacturing the semiconductor device.

FIG. 30A1 and FIG. 30B1 are perspective views illustrating an example of a method for manufacturing a semiconductor device. FIG. 30A2 and FIG. 30B2 are cross-sectional views illustrating the example of the method for manufacturing the semiconductor device.

FIG. 31A is a perspective view of a display apparatus. FIG. 31B is a block diagram of the display apparatus.

FIG. 32A is a circuit diagram of a latch circuit. FIG. 32B is a circuit diagram of an inverter circuit.

FIG. 33A is a circuit diagram of a pixel circuit. FIG. 33B is a cross-sectional view illustrating an example of the pixel circuit.

FIG. 34 is a cross-sectional view illustrating a structure example of a display apparatus.

FIG. 35A to FIG. 35C are cross-sectional views illustrating a structure example of a display apparatus.

FIG. 36 is a cross-sectional view illustrating a structure example of a display apparatus.

FIG. 37A to FIG. 37G are diagrams illustrating pixel examples.

FIG. 38A to FIG. 38K are diagrams illustrating pixel examples.

FIG. 39A to FIG. 39F are diagrams illustrating structure examples of a light-emitting device.

FIG. 40A to FIG. 40C are diagrams illustrating structure examples of a light-emitting device.

FIG. 41A and FIG. 41B are diagrams illustrating a structure example of a display apparatus.

FIG. 42A to FIG. 42D are diagrams illustrating structure examples of a display apparatus.

FIG. 43A to FIG. 43C are diagrams illustrating structure examples of a display apparatus.

FIG. 44A to FIG. 44D are diagrams illustrating structure examples of a display apparatus.

FIG. 45A to FIG. 45F are diagrams illustrating structure examples of a display apparatus.

FIG. 46A to FIG. 46F are diagrams illustrating structure examples of a display apparatus.

FIG. 47A to FIG. 47F are diagrams illustrating examples of electronic devices.

FIG. 48A to FIG. 48F are diagrams illustrating examples of electronic devices.

FIG. 49A and FIG. 49B are diagrams showing characteristics of transistors of Example.

FIG. 50A and FIG. 50B are diagrams showing characteristics of transistors of Example.

FIG. 51A and FIG. 51B are diagrams showing characteristics of transistors of Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure.

In this specification and the like, a structure in which at least light-emitting layers of light-emitting devices having different emission wavelengths are separately formed may be referred to as a SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to such a shape that at least part of the side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the structure are not necessarily completely flat and may be substantially flat with a slight curvature or substantially flat with slight unevenness.

Note that in this specification and the like, a mask layer (also referred to as a sacrificial layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

In this specification and the like, the expression “having substantially the same top surface shapes” means that at least outlines of stacked layers partly overlap with each other. For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “top surface shapes are substantially the same”.

### Embodiment 1

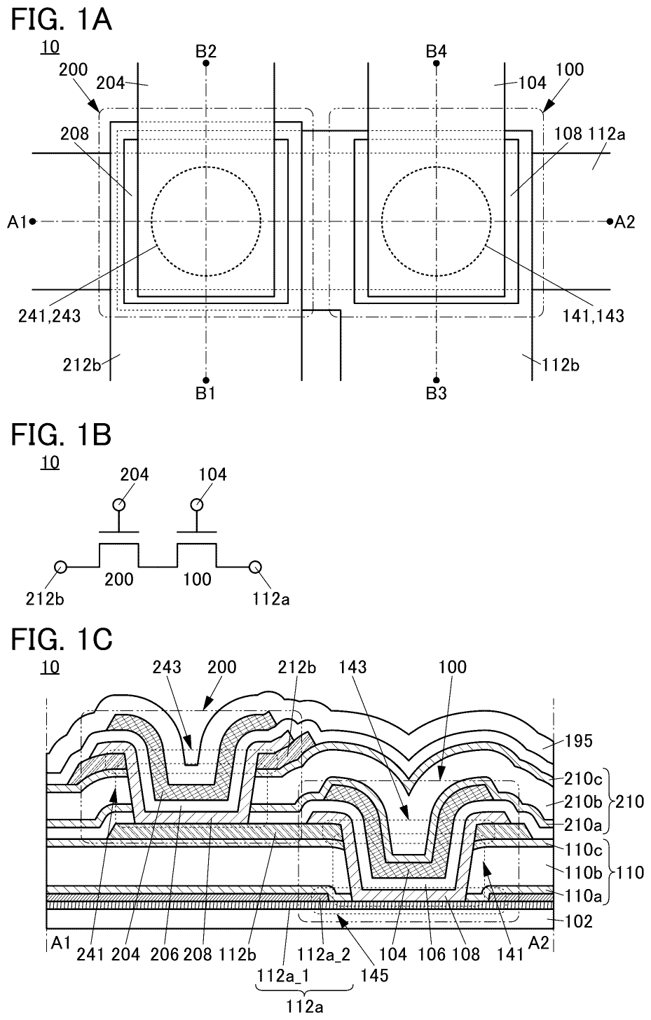

In this embodiment, a semiconductor device of one embodiment of the present invention, a manufacturing method thereof, and the like will be described with reference to FIG. 1 to FIG. 30.

### Structure Example 1

### Structure Example 1-1

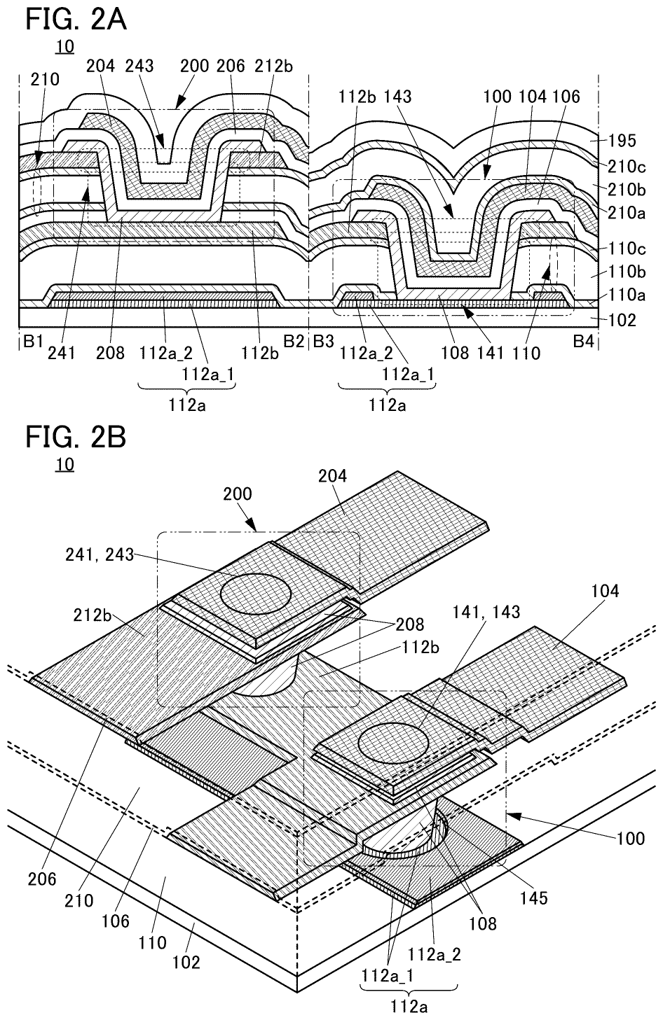

The semiconductor device of one embodiment of the present invention will be described. FIG. 1A is a top view (also referred to as a plan view) of a semiconductor device 10. FIG. 1B is an equivalent circuit diagram of the semiconductor device 10. FIG. 1C is a cross-sectional view of a cross section along the dashed-dotted line A1-A2 in FIG. 1A, and FIG. 2A is a cross-sectional view of cross sections along the dashed-dotted line B1-B2 and the dashed-dotted line B3-B4 in FIG. 1A. FIG. 2B is a perspective view of the semiconductor device 10. Note that in FIG. 1A, some components (e.g., an insulating layer) of the semiconductor device 10 are not illustrated. Some components are not illustrated in top views of semiconductor devices in the following drawings, as in FIG. 1A. For easy understanding, an insulating layer is illustrated as a transparent layer and its outline is indicated by a dashed line in FIG. 2B.

The semiconductor device 10 includes a transistor 100 and a transistor 200. One of a source electrode and a drain electrode of the transistor 100 is electrically connected to one of a source electrode and a drain electrode of the transistor 200.

Although the transistor 100 and the transistor 200 are shown as n-channel transistors in FIG. 1B, one embodiment of the present invention is not limited thereto. One or both of the transistor 100 and the transistor 200 may be a p-channel transistor(s).

The transistor 100 is provided over a substrate 102. The transistor 100 includes a conductive layer 104, an insulating layer 106, a semiconductor layer 108, a conductive layer 112a, and a conductive layer 112b. The conductive layer 104 functions as a gate electrode. Part of the insulating layer 106 functions as a gate insulating layer. The conductive layer 112b functions as one of the source electrode and the drain electrode, and the conductive layer 112a functions as the other. In the semiconductor layer 108, the whole region that is between the source electrode and the drain electrode and overlaps with the gate electrode with the gate insulating layer therebetween functions as a channel formation region. In the semiconductor layer 108, a region in contact with the source electrode functions as a source region, and a region in contact with the drain electrode functions as a drain region.

The transistor 200 can have a structure similar to that of the transistor 100. The transistor 200 includes a conductive layer 204, an insulating layer 206, a semiconductor layer 208, the conductive layer 112b, and a conductive layer 212b. The conductive layer 204 functions as a gate electrode. Part of the insulating layer 206 functions as a gate insulating layer. The conductive layer 112b functions as one of the source electrode and the drain electrode, and the conductive layer 212b functions as the other. In the semiconductor layer 208, the whole region that is between the source electrode and the drain electrode and overlaps with the gate electrode with the gate insulating layer therebetween functions as a channel formation region. In the semiconductor layer 208, a region in contact with the source electrode functions as a source region, and a region in contact with the drain electrode functions as a drain region.

The conductive layer 112b functions as one of the source electrode and the drain electrode of the transistor 100 and also functions as one of the source electrode and the drain electrode of the transistor 200. The transistor 100 and the transistor 200 share the conductive layer 112b, whereby the area occupied by the circuit can be reduced and thus a small semiconductor device can be provided.

First, the detailed structure of the transistor 100 will be described.

The conductive layer 112a is provided over the substrate 102, an insulating layer 110 is provided over the conductive layer 112a, and the conductive layer 112b is provided over the insulating layer 110. The insulating layer 110 includes a region interposed between the conductive layer 112a and the conductive layer 112b. The conductive layer 112a includes a region overlapping with the conductive layer 112b with the insulating layer 110 therebetween. The insulating layer 110 has an opening 141 in a region overlapping with the conductive layer 112a. The conductive layer 112a is exposed in the opening 141. The conductive layer 112b has an opening 143 in a region overlapping with the conductive layer 112a. The opening 143 is provided in a region overlapping with the opening 141.

The conductive layer 112a and the conductive layer 112b may each have a stacked-layer structure. FIG. 1C and the like illustrate a structure in which the conductive layer 112a has a stacked-layer structure of a conductive layer 112a_1 and a conductive layer 112a_2 over the conductive layer 112a_1. As illustrated in FIG. 1C, the conductive layer 112a_2 has an opening 145, and the conductive layer 112a_1 is exposed in the opening 145. In the opening 145, the conductive layer 112a_1 includes a region in contact with the semiconductor layer 108. It is preferable that the conductive layer 112a_2 not include a region in contact with the semiconductor layer 108.

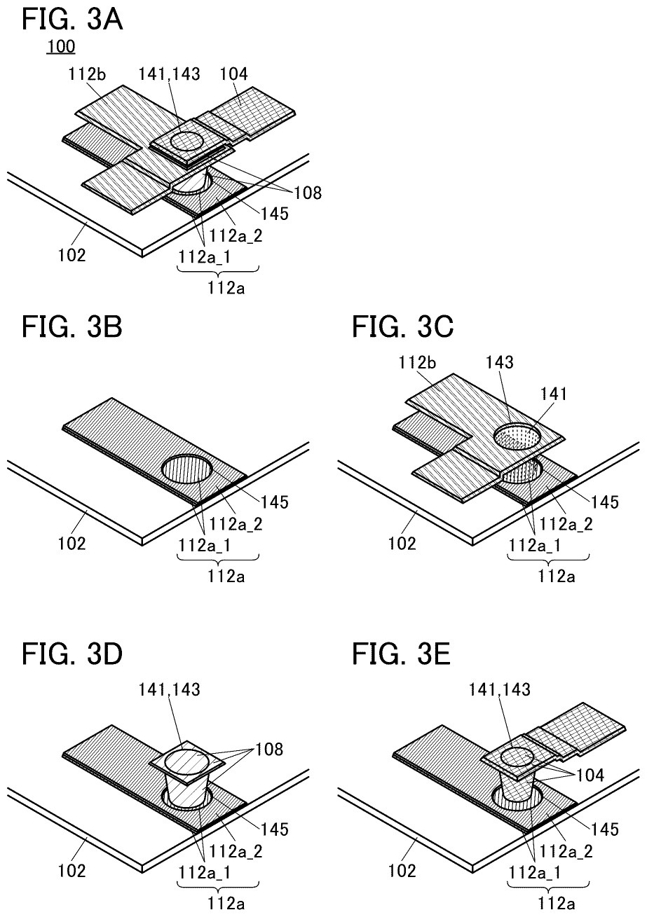

FIG. 3A is a perspective view selectively illustrating the transistor 100. FIG. 3B is a perspective view selectively illustrating the conductive layer 112a. The conductive layer 112a_2 has the opening 145 in a region overlapping with the conductive layer 112a_1.

FIG. 3C is a perspective view selectively illustrating the conductive layer 112a, the conductive layer 112b, the opening 141, and the opening 143. Note that the opening 141 provided in the insulating layer 110 is indicated by dashed lines. As illustrated in FIG. 3C, the conductive layer 112b has the opening 143 in a region overlapping with the conductive layer 112a.

The top-view shapes of the opening 141 and the opening 143 can be circular or elliptic, for example. Examples of the top-view shapes of the opening 141 and the opening 143 include polygons such as a triangle, a tetragon (including a rectangle, a rhombus, and a square), and a pentagon; and polygons with rounded corners. The top-view shapes of the opening 141 and the opening 143 are preferably circular as illustrated in FIG. 1A. In the case where the top-view shapes of the opening 141 and the opening 143 are circular, high processing accuracy to form each of the opening 141 and the opening 143 is possible and the opening 141 and the opening 143 having minute sizes can be formed. Note that in this specification and the like, a circular shape is not necessarily a perfect circular shape.

An end portion of the conductive layer 112b on the opening 143 side is preferably aligned or substantially aligned with an end portion of the insulating layer 110 on the opening 141 side. In other words, the top-view shape of the opening 143 is the same or substantially the same as the top-view shape of the opening 141. Note that in this specification and the like, the end portion of the conductive layer 112b on the opening 143 side refers to an end portion of the bottom surface of the conductive layer 112b on the opening 143 side. The bottom surface of the conductive layer 112b refers to the surface thereof on the insulating layer 110 side. The end portion of the insulating layer 110 on the opening 141 side refers to an end portion of the top surface of the insulating layer 110 on the opening 141 side. The top surface of the insulating layer 110 refers to the surface thereof on the conductive layer 112b side. The top-view shape of the opening 143 refers to the shape of the end portion of the bottom surface of the conductive layer 112b on the opening 143 side. The top-view shape of the opening 141 refers to the shape of the end portion of the top surface of the insulating layer 110 on the opening 141 side.

In the case where end portions are the same or substantially the same, the end portions can also be said to be aligned or substantially aligned with each other. In the case where end portions are aligned or substantially aligned with each other and the case where top surface shapes are the same or substantially the same, it can be said that outlines of stacked layers at least partly overlap with each other in a top view (also referred to as a plan view). For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions are substantially aligned with each other” or the expression “top surface shapes are substantially the same”.

The opening 141 can be formed using a resist mask used for the formation of the opening 143, for example. Specifically, an insulating film to be the insulating layer 110, a conductive film to be the conductive layer 112b over the insulating film, and a resist mask over the conductive film are formed. Then, the opening 143 is formed in the conductive film using the resist mask and then the opening 141 is formed in the insulating film using the resist mask, whereby an end portion of the opening 141 and an end portion of the opening 143 can be the same or substantially the same. With such a structure, processes can be simplified.

After the opening 143 is formed, the opening 141 may be formed in a step different from that of the opening 143. There is no particular limitation on the formation order of the opening 141 and the opening 143. For example, after the opening 141 is formed in the insulating film to be the insulating layer 110, a conductive film to be the conductive layer 112b may be formed, and the opening 143 may be formed in the conductive film.

The end portion of the conductive layer 112b on the opening 143 side is not necessarily aligned with the end portion of the insulating layer 110 on the opening 141 side. That is, the top-view shape of the opening 143 is not necessarily the same as the top-view shape of the opening 141. In the top view, the opening 143 preferably covers the opening 141 completely. The end portion of the conductive layer 112b on the opening 143 side may be located outward from the end portion of the insulating layer 110 on the opening 141 side. The semiconductor layer 108 includes a region in contact with the top surface and the side surface of the conductive layer 112b, the top surface and the side surface of the insulating layer 110, and the top surface of the conductive layer 112a. With such a structure, a step on the formation surface of a layer (e.g., the semiconductor layer 108) formed over the conductive layer 112a, the conductive layer 112b, and the insulating layer 110 is reduced. Accordingly, the coverage with layers formed over the conductive layer 112a, the conductive layer 112b, and the insulating layer 110 can be improved, which can inhibit defects such as step disconnection or a void from being generated in the layer.

The semiconductor layer 108 is provided to cover the opening 141 and the opening 143. The semiconductor layer 108 includes a region in contact with the top surface and the side surface of the conductive layer 112b, the side surface of the insulating layer 110, and the top surface of the conductive layer 112a. The semiconductor layer 108 is electrically connected to the conductive layer 112a through the opening 141 and the opening 143. The semiconductor layer 108 has a shape along the shapes of the top surface and the side surface of the conductive layer 112b, the side surface of the insulating layer 110, and the top surface of the conductive layer 112a.

Although this embodiment describes the structure in which the opening 141 and the opening 143 are provided in the insulating layer 110 and the conductive layer 112b and the semiconductor layer 108 is provided to cover the opening 141 and the opening 143, one embodiment of the present invention is not limited thereto. The semiconductor device of one embodiment of the present invention includes a first region where the insulating layer 110 is provided over the conductive layer 112a and a second region where the insulating layer 110 is not provided over the conductive layer 112a. In the transistor 100, the semiconductor layer 108 is provided at a step generated by the first region and the second region. The insulating layer 106 is provided over the semiconductor layer 108, and the conductive layer 104 is provided to overlap with the semiconductor layer 108 between the conductive layer 112a and the conductive layer 112b, with the insulating layer 106 therebetween.

The semiconductor layer 108 preferably covers the end portion of the conductive layer 112b on the opening 143 side. FIG. 1C and the like illustrate the structure in which an end portion of the semiconductor layer 108 is positioned over the conductive layer 112b. That is, the end portion of the semiconductor layer 108 is in contact with the top surface of the conductive layer 112b. Note that the semiconductor layer 108 may extend to and cover an end portion of the conductive layer 112b that does not face the opening 143. The end portion of the semiconductor layer 108 may be in contact with the top surface of the insulating layer 110.

FIG. 3D is a perspective view selectively illustrating the conductive layer 112a and the semiconductor layer 108. As illustrated in FIG. 3C, the semiconductor layer 108 is provided to cover the opening 141 and the opening 143. As illustrated in FIG. 1C and the like, the semiconductor layer 108 includes a region in contact with the top surface of the conductive layer 112a in the opening 141. Specifically, the semiconductor layer 108 preferably includes a region in contact with the top surface of the conductive layer 112a_1 in the opening 141.

Although the semiconductor layer 108 has a single-layer structure in FIG. 1C and the like, one embodiment of the present invention is not limited thereto. The semiconductor layer 108 may have a stacked-layer structure of two or more layers.

The insulating layer 106 functioning as the gate insulating layer of the transistor 100 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface of the insulating layer 110, the top surface and the side surface of the conductive layer 112b, the top surface and the side surface of the semiconductor layer 108, and the top surface of the conductive layer 112a.

The conductive layer 104 functioning as the gate electrode of the transistor 100 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106.

FIG. 3E is a perspective view selectively illustrating the conductive layer 112a and the conductive layer 104. As illustrated in FIG. 3E, the conductive layer 104 is provided to cover the opening 141 and the opening 143.

As illustrated in FIG. 1C and the like, the conductive layer 104 includes the region overlapping with the semiconductor layer 108 with the insulating layer 106 therebetween in the opening 141 and the opening 143. The conductive layer 104 also includes a region overlapping with the conductive layer 112a and a region overlapping with the conductive layer 112b with the insulating layer 106 and the semiconductor layer 108 therebetween. The conductive layer 104 preferably covers the end portion of the conductive layer 112b on the opening 143 side. With such a structure, in the semiconductor layer 108, the whole region that is between the source electrode and the drain electrode and overlaps with the gate electrode with the gate insulating layer therebetween can function as a channel formation region.

Next, the detailed structure of the transistor 200 will be described.

The insulating layer 106 is provided over the conductive layer 112b, an insulating layer 210 is provided over the insulating layer 106, and the conductive layer 212b is provided over the insulating layer 210. The insulating layer 106 and the insulating layer 210 each include a region interposed between the conductive layer 112b and the conductive layer 212b. The conductive layer 112b includes a region overlapping with the conductive layer 212b with the insulating layer 106 and the insulating layer 210 therebetween. The insulating layer 106 and the insulating layer 210 have an opening 241 in a region overlapping with the conductive layer 112b. The conductive layer 112b is exposed in the opening 241. The conductive layer 212b has an opening 243 in a region overlapping with the conductive layer 112b. The opening 243 is provided in a region overlapping with the opening 241.

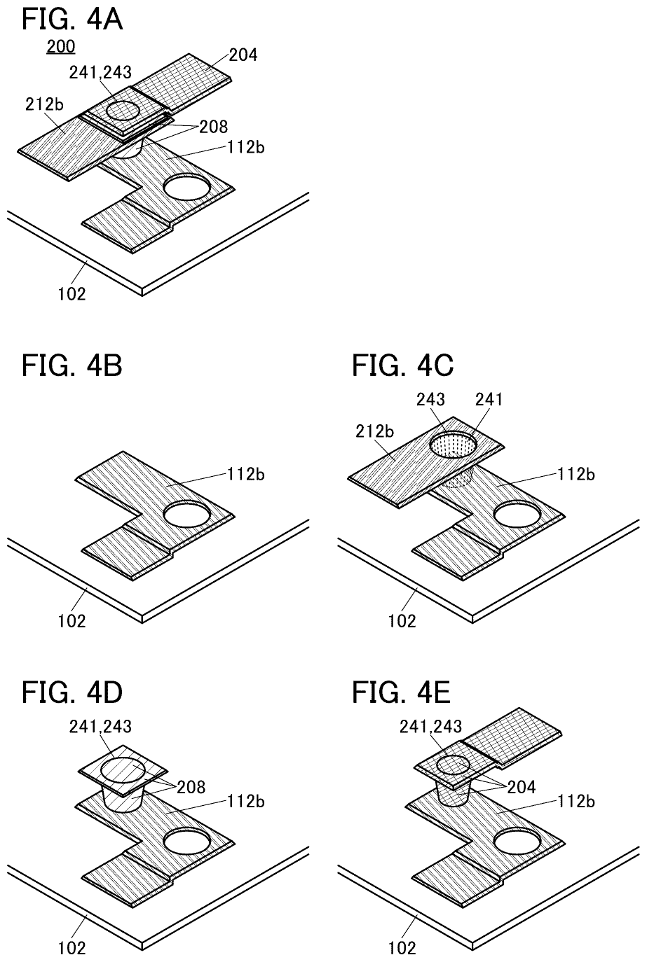

FIG. 4A is a perspective view selectively illustrating the transistor 200. FIG. 4B is a perspective view selectively illustrating the conductive layer 112b. FIG. 4C is a perspective view selectively illustrating the conductive layer 112b, the conductive layer 212b, the opening 241, and the opening 243. Note that the opening 241 provided in the insulating layer 106 and the insulating layer 210 is indicated by dashed lines. As illustrated in FIG. 4C, the conductive layer 212b has the opening 243 in a region overlapping with the conductive layer 112b.

For the top-view shapes of the opening 241 and the opening 243, the description of the opening 141 and the opening 143 can be referred to. The top-view shapes of the opening 241 and the opening 243 are preferably circular as illustrated in FIG. 1A.

An end portion of the conductive layer 212b on the opening 243 side is preferably aligned or substantially aligned with an end portion of the insulating layer 210 on the opening 241 side. In other words, the top-view shape of the opening 243 is the same or substantially the same as the top-view shape of the opening 241. Note that in this specification and the like, the end portion of the conductive layer 212b on the opening 243 side refers to an end portion of the bottom surface of the conductive layer 212b on the opening 243 side. The bottom surface of the conductive layer 212b refers to the surface thereof on the insulating layer 210 side. The end portion of the insulating layer 210 on the opening 241 side refers to an end portion of the top surface of the insulating layer 210 on the opening 241 side. The top surface of the insulating layer 210 refers to the surface thereof on the conductive layer 212b side. The top-view shape of the opening 243 refers to the shape of the end portion of the bottom surface of the conductive layer 212b on the opening 243 side. The top-view shape of the opening 241 refers to the shape of the end portion of the top surface of the insulating layer 210 on the opening 241 side.

The opening 241 and the opening 243 can be formed by a method similar to that for forming the opening 141 and the opening 143. Note that the end portion of the conductive layer 212b on the opening 243 side is not necessarily aligned with the end portion of the insulating layer 210 on the opening 241 side.

The semiconductor layer 208 is provided to cover the opening 241 and the opening 243. The semiconductor layer 208 includes a region in contact with the top surface and the side surface of the conductive layer 212b, the side surface of the insulating layer 110, the side surface of the insulating layer 106, and the top surface of the conductive layer 112b. The semiconductor layer 208 is electrically connected to the conductive layer 112b through the opening 241 and the opening 243. The semiconductor layer 208 has a shape along the shapes of the top surface and the side surface of the conductive layer 212b, the side surface of the insulating layer 210, the side surface of the insulating layer 106, and the top surface of the conductive layer 112b.

Although this embodiment describes the structure in which the opening 241 and the opening 243 are provided in the insulating layer 106, the insulating layer 210, and the conductive layer 212b and the semiconductor layer 208 is provided to cover the opening 241 and the opening 243, one embodiment of the present invention is not limited thereto. The semiconductor device of one embodiment of the present invention includes a third region where the insulating layer 106 and the insulating layer 110 are provided over the conductive layer 112b and a fourth region where one or both of the insulating layer 106 and the insulating layer 110 are not provided over the conductive layer 112b. In the transistor 200, the semiconductor layer 208 is provided at a step generated by the third region and the fourth region. The insulating layer 206 is provided over the semiconductor layer 208, and the conductive layer 204 is provided to overlap with the semiconductor layer 208 between the conductive layer 112b and the conductive layer 212b, with the insulating layer 206 therebetween.

The semiconductor layer 208 preferably covers the end portion of the conductive layer 212b on the opening 243 side. FIG. 1C and the like illustrate the structure in which an end portion of the semiconductor layer 208 is positioned over the conductive layer 212b. That is, the end portion of the semiconductor layer 208 is in contact with the top surface of the conductive layer 212b. Note that the semiconductor layer 208 may extend to and cover an end portion of the conductive layer 212b that does not face the opening 243. The end portion of the semiconductor layer 208 may be in contact with the top surface of the insulating layer 210.

FIG. 4D is a perspective view selectively illustrating the conductive layer 112b and the semiconductor layer 208. As illustrated in FIG. 4D, the semiconductor layer 208 is provided to cover the opening 241 and the opening 243. The semiconductor layer 208 includes a region in contact with the top surface of the conductive layer 112b in the opening 241.

Although the semiconductor layer 208 has a single-layer structure in FIG. 1C and the like, one embodiment of the present invention is not limited thereto. The semiconductor layer 208 may have a stacked-layer structure of two or more layers.

The insulating layer 206 functioning as the gate insulating layer of the transistor 200 is provided to cover the opening 241 and the opening 243. The insulating layer 206 is provided over the semiconductor layer 208, the conductive layer 212b, and the insulating layer 210. The insulating layer 206 includes a region in contact with the top surface and the side surface of the semiconductor layer 208, the top surface and the side surface of the conductive layer 212b, and the top surface of the insulating layer 210. The insulating layer 206 has a shape along the shapes of the top surface of the insulating layer 210, the top surface and the side surface of the conductive layer 212b, the top surface and the side surface of the semiconductor layer 208, and the top surface of the conductive layer 112b.

The conductive layer 204 functioning as the gate electrode of the transistor 200 is provided over the insulating layer 206 and includes a region in contact with the top surface of the insulating layer 206. The conductive layer 204 includes a region overlapping with the semiconductor layer 208 with the insulating layer 206 therebetween. The conductive layer 204 has a shape along the shape of the top surface of the insulating layer 206.

FIG. 4E is a perspective view selectively illustrating the conductive layer 112b and the conductive layer 204. As illustrated in FIG. 4E, the conductive layer 204 is provided to cover the opening 241 and the opening 243.

As illustrated in FIG. 1C and the like, the conductive layer 204 includes the region overlapping with the semiconductor layer 208 with the insulating layer 206 therebetween in the opening 241 and the opening 243. The conductive layer 204 also includes a region overlapping with the conductive layer 112b and a region overlapping with the conductive layer 212b with the insulating layer 206 and the semiconductor layer 208 therebetween. The conductive layer 204 preferably covers the end portion of the conductive layer 212b on the opening 243 side. With such a structure, in the semiconductor layer 208, the whole region that is between the source electrode and the drain electrode and overlaps with the gate electrode with the gate insulating layer therebetween can function as a channel formation region.

The transistor 100 is what is called a top-gate transistor including the gate electrode above the semiconductor layer 108. Furthermore, since the bottom surface of the semiconductor layer 108 is in contact with the source electrode and the drain electrode, the transistor 100 can be referred to as a TGBC (Top Gate Bottom Contact) transistor. Similarly, the transistor 200 can be referred to as a TGBC transistor.

The conductive layer 112a, the conductive layer 112b, and the conductive layer 104 can function as wirings, and the transistor 100 can be provided in a region where these wirings overlap with each other. Similarly, the conductive layer 112b, the conductive layer 212b, and the conductive layer 104 can function as wirings, and the transistor 200 can be provided in a region where these wirings overlap with each other. That is, the areas occupied by the transistor 100, the transistor 200, and the wirings can be reduced in the circuit including the transistor 100, the transistor 200, and the wirings. Accordingly, the area occupied by the circuit can be reduced, which makes it possible to provide a small semiconductor device. The transistor 100 may include a region overlapping with the transistor 200. When the transistor 100 includes a region overlapping with the transistor 200, the area occupied by the circuit can be further reduced. When the semiconductor device of one embodiment of the present invention is used for a pixel circuit of a display apparatus, the area occupied by the pixel circuit can be reduced and the display apparatus can have high definition, for example. When the semiconductor device of one embodiment of the present invention is used for a driver circuit (e.g., a gate line driver circuit and a source line driver circuit) of a display apparatus, the area occupied by the driver circuit can be reduced and the display apparatus can have a narrow bezel.

In the semiconductor device of one embodiment of the present invention, the conductive layer 112a, the conductive layer 112b, the conductive layer 104, the conductive layer 212b, and the conductive layer 204 functioning as wirings are provided in different layers. Accordingly, the conductive layers can be placed in their respective layers, leading to high layout flexibility and a reduction in the area occupied by the circuit.

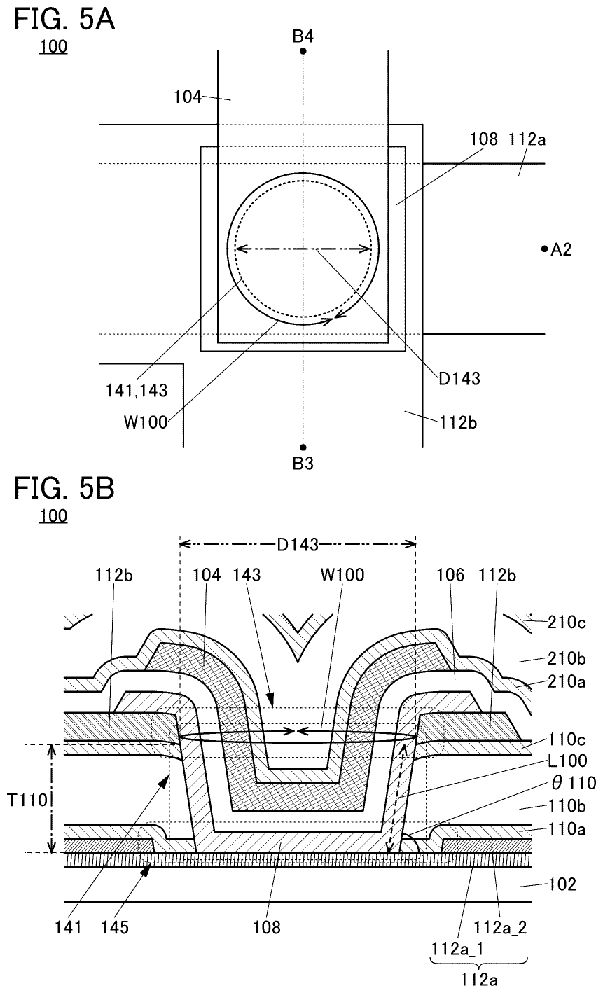

Here, the channel length and the channel width of the transistor 100 will be described with reference to FIG. 5A and FIG. 5B. FIG. 5A is a top view of the transistor 100. FIG. 5B is an enlarged view of FIG. 1C.

In the semiconductor layer 108, a region in contact with the conductive layer 112a functions as the other of the source region and the drain region, a region in contact with the conductive layer 112b functions as one of the source region and the drain region, and a region between the source region and the drain region functions as a channel formation region.

The channel length of the transistor 100 is a distance between the source region and the drain region. In FIG. 5B, a channel length L100 of the transistor 100 is indicated by a dashed double-headed arrow. In the cross-sectional view, the channel length L100 is a distance between an end portion of the region where the semiconductor layer 108 is in contact with the conductive layer 112a and an end portion of the region where the semiconductor layer 108 is in contact with the conductive layer 112b.

Here, the channel length L100 of the transistor 100 corresponds to the length of the side surface of the insulating layer 110 on the opening 141 side in the cross-sectional view. That is, the channel length L100 is determined depending on a thickness T110 of the insulating layer 110 and an angle θ110 formed by the side surface of the insulating layer 110 on the opening 141 side and the formation surface of the insulating layer 110 (here, the top surface of the conductive layer 112a), and is not affected by the performance of a light-exposure apparatus used for manufacturing the transistor. Thus, the channel length L100 can be a value smaller than that of the resolution limit of a light-exposure apparatus, which enables a transistor having a minute size. For example, the channel length L100 is preferably greater than or equal to 0.01 μm and less than 3 μm, further preferably greater than or equal to 0.05 μm and less than 3 μm, further preferably greater than or equal to 0.1 μm and less than 3 μm, still further preferably greater than or equal to 0.15 μm and less than 3 μm, yet still further preferably greater than or equal to 0.2 μm and less than 3 μm, yet still further preferably greater than or equal to 0.2 μm and less than 2.5 μm, yet still further preferably greater than or equal to 0.2 μm and less than 2 μm, yet still further preferably greater than or equal to 0.2 μm and less than 1.5 μm, yet still further preferably greater than or equal to 0.3 μm and less than or equal to 1.5 μm, yet still further preferably greater than or equal to 0.3 μm and less than or equal to 1.2 μm, yet still further preferably greater than or equal to 0.4 μm and less than or equal to 1.2 μm, yet still further preferably greater than or equal to 0.4 μm and less than or equal to 1 μm, yet still further preferably greater than or equal to 0.5 μm and less than or equal to 1 μm. In FIG. 5B, the thickness T110 of the insulating layer 110 is indicated by a dashed-dotted double-headed arrow.

The reduction in the channel length L100 can increase the on-state current of the transistor 100. With use of the transistor 100, a circuit capable of high-speed operation can be fabricated. Furthermore, the area occupied by the circuit can be reduced. Therefore, a small semiconductor device can be obtained. The application of the semiconductor device of one embodiment of the present invention to a large display apparatus or a high-definition display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110 and the angle θ110 of the insulating layer 110, the channel length L100 can be controlled.

The thickness T110 of the insulating layer 110 is preferably greater than or equal to 0.01 μm and less than 3 μm, further preferably greater than or equal to 0.05 μm and less than 3 μm, further preferably greater than or equal to 0.1 μm and less than 3 μm, still further preferably greater than or equal to 0.15 μm and less than 3 μm, yet still further preferably greater than or equal to 0.2 μm and less than 3 μm, yet still further preferably greater than or equal to 0.2 μm and less than 2.5 μm, yet still further preferably greater than or equal to 0.2 μm and less than 2 μm, yet still further preferably greater than or equal to 0.2 μm and less than 1.5 μm, yet still further preferably greater than or equal to 0.3 μm and less than or equal to 1.5 μm, yet still further preferably greater than or equal to 0.3 μm and less than or equal to 1.2 μm, yet still further preferably greater than or equal to 0.4 μm and less than or equal to 1.2 μm, yet still further preferably greater than or equal to 0.4 μm and less than or equal to 1 μm, yet still further preferably greater than or equal to 0.5 μm and less than or equal to 1 μm.

The side surface of the insulating layer 110 on the opening 141 side preferably has a tapered shape. The angle θ110 formed by the side surface of the insulating layer 110 on the opening 141 side and the formation surface of the insulating layer 110 (here, the top surface of the conductive layer 112a) is preferably smaller than 90°. By reducing the angle θ110, the coverage with a layer (e.g., the semiconductor layer 108) provided over the insulating layer 110 can be improved. However, reducing the angle θ110 might reduce the contact area between the semiconductor layer 108 and the conductive layer 112a to increase the contact resistance between the semiconductor layer 108 and the conductive layer 112a. The angle θ110 is preferably greater than or equal to 45° and less than 90°, further preferably greater than or equal to 50° and less than 90°, further preferably greater than or equal to 55° and less than 90°, further preferably greater than or equal to 60° and less than 90°, further preferably greater than or equal to 60° and less than or equal to 85°, still further preferably greater than or equal to 65° and less than or equal to 85°, yet further preferably greater than or equal to 65° and less than or equal to 80°, yet still further preferably greater than or equal to 70° and less than or equal to 80°. When the angle θ110 is in the above range, the coverage with the layer (e.g., the semiconductor layer 108) formed over the conductive layer 112a and the insulating layer 110 can be improved, which can inhibit defects such as step disconnection or a void from being generated in the layer. In addition, the contact resistance between the semiconductor layer 108 and the conductive layer 112a can be reduced.

Although FIG. 5B and the like illustrate the structure in which the side surface of the insulating layer 110 on the opening 141 side is linear in the cross-sectional view, one embodiment of the present invention is not limited thereto. In the cross-sectional view, the side surface of the insulating layer 110 on the opening 141 side may be curved, or the side surface may include both a linear region and a curved region.

It is preferable that the conductive layer 112b not be provided inside the opening 141. Specifically, it is preferable that the conductive layer 112b not include a region in contact with the side surface of the insulating layer 110 on the opening 141 side. If the conductive layer 112b is also provided inside the opening 141, the channel length L100 of the transistor 100 is shorter than the length of the side surface of the insulating layer 110 and the channel length L100 is difficult to control in some cases. Accordingly, it is preferable that the top-view shape of the opening 143 be the same as the top-view shape of the opening 141, or the opening 143 cover the opening 141 completely in the top view.

The channel width of the transistor 100 is the width of the source region or the width of the drain region in a direction orthogonal to the channel length direction. In other words, the channel width is the width of the region where the semiconductor layer 108 is in contact with the conductive layer 112a or the width of the region where the semiconductor layer 108 is in contact with the conductive layer 112b in the direction orthogonal to the channel length direction. Here, the channel width of the transistor 100 is described as the width of the region where the semiconductor layer 108 is in contact with the conductive layer 112b in the direction orthogonal to the channel length direction. In FIG. 5A and FIG. 5B, a channel width W100 of the transistor 100 is indicated by a solid double-headed arrow. In the top view, the channel width W100 is the length of the end portion of the bottom surface of the conductive layer 112b on the opening 143 side.

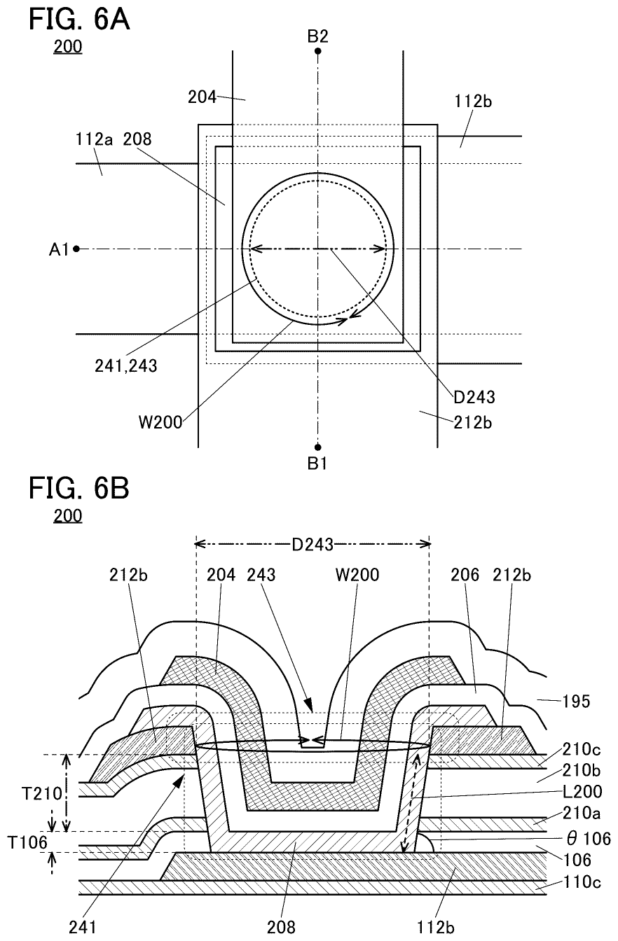

The channel width W100 is determined depending on the top-view shape of the opening 143. In FIG. 5A and FIG. 5B, a width D143 of the opening 143 is denoted by a dashed double-dotted double-headed arrow. In the top view, the width D143 refers to the short side of the smallest rectangle that is circumscribed around the opening 143. In the case where the opening 143 is formed by a photolithography method, the width D143 of the opening 143 is larger than or equal to the resolution limit of a light-exposure apparatus. For example, the width D143 is preferably greater than or equal to 0.2 μm and less than 5 μm, further preferably greater than or equal to 0.2 μm and less than 4.5 μm, further preferably greater than or equal to 0.2 μm and less than 4 μm, still further preferably greater than or equal to 0.2 μm and less than 3.5 μm, yet still further preferably greater than or equal to 0.2 μm and less than 3 μm, yet still further preferably greater than or equal to 0.2 μm and less than 2.5 μm, yet still further preferably greater than or equal to 0.2 μm and less than 2 μm, yet still further preferably greater than or equal to 0.2 μm and less than 1.5 μm, yet still further preferably greater than or equal to 0.3 μm and less than or equal to 1.5 μm, yet still further preferably greater than or equal to 0.3 μm and less than or equal to 1.2 μm, yet still further preferably greater than or equal to 0.4 μm and less than or equal to 1.2 μm, yet still further preferably greater than or equal to 0.4 μm and less than or equal to 1 μm, yet still further preferably greater than or equal to 0.5 μm and less than or equal to 1 μm. Note that when the top-view shape of the opening 143 is circular, the width D143 corresponds to the diameter of the opening 143, and the channel width W100 can be calculated to be “D143×π”. The channel length and the channel width of the transistor 200 will be described with reference to FIG. 6A and FIG. 6B. FIG. 6A is a top view of the transistor 200. FIG. 6B is an enlarged view of FIG. 1C.

In the semiconductor layer 208, a region in contact with the conductive layer 112b functions as one of the source region and the drain region, a region in contact with the conductive layer 212b functions as the other of the source region and the drain region, and a region between the source region and the drain region functions as a channel formation region.

In FIG. 6B, a channel length L200 of the transistor 200 is indicated by a dashed double-headed arrow. In the cross-sectional view, the channel length L200 is a distance between an end portion of the region where the semiconductor layer 208 is in contact with the conductive layer 112b and an end portion of the region where the semiconductor layer 208 is in contact with the conductive layer 212b.

Here, the channel length L200 of the transistor 200 corresponds to the sum of the length of the side surface of the insulating layer 106 on the opening 241 side and the length of the side surface of the insulating layer 210 on the opening 241 side in the cross-sectional view. In other words, the channel length L200 depends on a thickness T210 of the insulating layer 210, a thickness T106 of the insulating layer 106, and an angle θ106 formed by the side surface of the insulating layer 106 on the opening 241 side and the formation surface of the insulating layer 106 (here, the top surface of the conductive layer 112b). In FIG. 6B, the thickness T106 of the insulating layer 106 is indicated by a dashed-dotted arrow, and the thickness T210 of the insulating layer 210 is indicated by a dashed-dotted double-headed arrow. The channel length L200 is preferably within the range of the channel length L100. By adjusting the thickness T106 and the angle θ106 of the insulating layer 106 and the thickness T210 of the insulating layer 210, the channel length L200 can be controlled.

The sum of the thickness T106 of the insulating layer 106 and the thickness T210 of the insulating layer 210 is preferably within the range of the thickness T110 of the insulating layer 110.

The side surfaces of the insulating layer 106 and the insulating layer 210 on the opening 241 side preferably have tapered shapes. In particular, the angle θ106 formed by the side surface of the insulating layer 106 on the opening 241 side and the formation surface of the insulating layer 106 (here, the top surface of the conductive layer 112b) is preferably smaller than 90°. The angle θ106 is preferably within the range of the angle θ110 of the insulating layer 110.

The sum of the thickness T106 of the insulating layer 106 and the thickness T210 of the insulating layer 210 may be equal to or different from the thickness T110 of the insulating layer 110. The angle θ106 of the insulating layer 106 may be equal to or different from the angle θ110 of the insulating layer 110. When the sum of the thickness T106 and the thickness T210 is equal to or substantially equal to the thickness T110 and the angle θ106 is equal to or substantially equal to the angle θ110, the channel length L100 of the transistor 100 and the channel length L200 of the transistor 200 can be equal to or substantially equal to each other. When the sum of the thickness T106 and the thickness T210 is different from the thickness T110 or the angle θ106 is different from the angle θ110, the channel length L100 of the transistor 100 and the channel length L200 of the transistor 200 can be different from each other.

Although FIG. 6B and the like illustrate the structure in which the side surfaces of the insulating layer 106 and the insulating layer 210 on the opening 241 side are linear in the cross-sectional view, one embodiment of the present invention is not limited thereto.

It is preferable that the conductive layer 212b not be provided inside the opening 241. Specifically, it is preferable that the conductive layer 212b not include a region in contact with the side surfaces of the insulating layer 106 and the insulating layer 210 on the opening 241 side. If the conductive layer 212b is also provided inside the opening 241, the channel length L200 of the transistor 200 is shorter than the total length of the side surface of the insulating layer 210 and the side surface of the insulating layer 106 and the channel length L200 is difficult to control in some cases. Accordingly, it is preferable that the top-view shape of the opening 243 be the same as the top-view shape of the opening 241 or the opening 243 cover the opening 241 completely in the top view.

In FIG. 6A and FIG. 6B, a channel width W200 of the transistor 200 is indicated by a solid double-headed arrow. In the top view, the channel width W200 is the length of the end portion of the bottom surface of the conductive layer 212b on the opening 243 side.

The channel width W200 is determined depending on the top-view shape of the opening 243. In FIG. 6A and FIG. 6B, a width D243 of the opening 243 is denoted by a dashed double-dotted double-headed arrow. In the top view, the width D243 refers to the short side of the smallest rectangle that is circumscribed around the opening 243. The width D243 of the opening 243 is preferably within the range of the width D143 of the opening 143. The width D243 of the opening 243 may be different from the width D143 of the opening 143. Note that when the top-view shape of the opening 243 is circular, the width D243 corresponds to the diameter of the opening 243, and the channel width W200 can be calculated to be “D243×π”. The width D243 of the opening 243 may be equal to or different from the width D143 of the opening 143. When the opening 143 and the opening 243 have the same top-view shape and have the same or substantially the same width, the channel width W100 of the transistor 100 and the channel width W200 of the transistor 200 can be equal to or substantially equal to each other. When one or both of a top-view shape and a width are different between the opening 143 and the opening 243, the channel width W100 of the transistor 100 and the channel width W200 of the transistor 200 can be different from each other.

An insulating layer 195 is provided over the transistor 100 and the transistor 200. The insulating layer 195 functions as a protective layer of the semiconductor device 10.

It is preferable to use a material that does not easily allow diffusion of impurities for the insulating layer 195 functioning as a protective layer of the semiconductor device 10. Provision of the insulating layer 195 can effectively inhibit diffusion of impurities into the transistors from the outside and increase the reliability of the semiconductor device. Examples of the impurities include water and hydrogen. The insulating layer 195 can be an insulating layer including an inorganic material or an insulating layer including an organic material. For example, an inorganic material such as an oxide or a nitride can be suitably used for the insulating layer 195. More specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or both of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

Components included in the semiconductor device of this embodiment will be described below.

### [Components of Semiconductor Device]

### [Semiconductor Layer 108 and Semiconductor Layer 208]

A semiconductor material that can be used for the semiconductor layer 108 is not particularly limited. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials may contain an impurity as a dopant.

There is no particular limitation on the crystallinity of a semiconductor material used for the semiconductor layer 108, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case deterioration of the transistor characteristics can be inhibited.

Silicon can be used for the semiconductor layer 108. As silicon, single crystal silicon, polycrystalline silicon, microcrystalline silicon, and amorphous silicon can be given. As the polycrystalline silicon, low-temperature polysilicon (LTPS) can be given, for example.

The transistor including amorphous silicon in the semiconductor layer 108 can be formed over a large glass substrate, and can be manufactured at low cost. The transistor including polycrystalline silicon in the semiconductor layer 108 has high field-effect mobility and enables high-speed operation. The transistor including microcrystalline silicon in the semiconductor layer 108 has higher field-effect mobility and enables higher speed operation than the transistor including amorphous silicon.

The semiconductor layer 108 preferably includes a metal oxide having semiconductor characteristics (an oxide semiconductor). Examples of the metal oxide that can be used for the semiconductor layer 108 include indium oxide, gallium oxide, and zinc oxide. The metal oxide preferably contains at least indium (In) or zinc (Zn). The metal oxide preferably contains two or three kinds selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more kinds selected from aluminum, gallium, yttrium, and tin. The element M is further preferably gallium.

For the semiconductor layer 108, for example, any of indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), and indium gallium aluminum zinc oxide (In—Ga—Al—Zn oxide, also referred to as IGAZO or IAGZO) can be used. Alternatively, indium tin oxide containing silicon, or the like can also be used.

Here, the composition of the metal oxide included in the semiconductor layer 108 greatly affects the electrical characteristics and reliability of the transistor 100.

By increasing the proportion of the number of indium atoms in the total number of atoms of all the metal elements contained in the metal oxide, a transistor having a high on-state current can be provided.

In the case of using In—Zn oxide for the semiconductor layer 108, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case of using In—Sn oxide for the semiconductor layer 108, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case of using In—Sn—Zn oxide for the semiconductor layer 108, a metal oxide in which the atomic proportion of indium is higher than the atomic proportion of tin can be used. It is further preferable to use a metal oxide in which the atomic proportion of zinc is higher than the atomic proportion of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case of using In—Al—Zn oxide for the semiconductor layer 108, a metal oxide in which the atomic proportion of indium is higher than the atomic proportion of aluminum can be used. It is further preferable to use a metal oxide in which the atomic proportion of zinc is higher than the atomic proportion of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case of using In—Ga—Zn oxide for the semiconductor layer 108, a metal oxide in which the proportion of the number of indium atoms in the total number of atoms of all the contained metal elements is higher than the proportion of the number of gallium atoms can be used. It is further preferable to use a metal oxide in which the proportion of the number of zinc atoms is higher than the proportion of the number of gallium atoms. For example, a metal oxide having any of the following atomic ratios of metal elements can be used for the semiconductor layer 108: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

In the case of using In-M-Zn oxide for the semiconductor layer 108, a metal oxide in which the proportion of the number of indium atoms in the total number of atoms of all the contained metal elements is higher than the proportion of the number of element M atoms can be used. It is further preferable to use a metal oxide in which the proportion of the number of zinc atoms is higher than the proportion of the number of element M atoms. For example, a metal oxide having any of the following atomic ratios of metal elements can be used for the semiconductor layer 108: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and the neighborhood thereof.

In the case where a plurality of metal elements are contained as the element M, the sum of the proportions of the numbers of atoms of the metal elements can be the proportion of the number of element M atoms. In the case of In—Ga—Al—Zn oxide in which gallium and aluminum are contained as the element M, for example, the sum of the proportion of the number of gallium atoms and the proportion of the number of aluminum atoms can be the proportion of the number of element M atoms. The atomic ratio of indium to the element M to zinc is preferably within the ranges given above. In the case of In—Ga—Sn—Zn oxide in which gallium and tin are contained as the element M, for example, the sum of the proportion of the number of gallium atoms and the proportion of the number of tin atoms can be the proportion of the number of element M atoms. The atomic ratio of indium to the element M to zinc is preferably within the ranges given above.

It is preferable to use a metal oxide in which the proportion of the number of indium atoms in the total number of atoms of all the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case of using In—Ga—Zn oxide for the semiconductor layer 108, the proportion of the number of indium atoms in the sum of the numbers of atoms of indium, the element M, and zinc is preferably within the ranges given above.

In this specification and the like, the proportion of the number of indium atoms in the total number of atoms of all the contained metal elements is sometimes referred to as indium content percentage. The same applies to other metal elements.

A higher indium content percentage in the metal oxide enables the transistor to have a high on-state current. By using such a transistor as a transistor requiring a high on-state current, a semiconductor device having excellent electrical characteristics can be provided.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

Note that a composition in the neighborhood in this specification and the like includes the range of ±30% of an intended atomic ratio. For example, when the atomic ratio is described as In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. When the atomic ratio is described as In:M:Zn=5:1:6 or a composition in the neighborhood thereof, the case is included where the atomic ratio of the element M is greater than 0.1 and less than or equal to 2 and the atomic ratio of zinc is greater than or equal to 5 and less than or equal to 7 with the atomic ratio of indium being 5. When the atomic ratio is described as In:M:Zn=1:1:1 or a composition in the neighborhood thereof, the case is included where the atomic ratio of the element M is greater than 0.1 and less than or equal to 2 and the atomic ratio of zinc is greater than 0.1 and less than or equal to 2 with the atomic ratio of indium being 1.

A sputtering method or an atomic layer deposition (ALD) method can be suitably used to form the metal oxide. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where current flows); thus, the amount of change in threshold voltage in the PBTS test is one important item to be focused on as an indicator of the reliability of the transistor.

With use of a metal oxide that does not contain gallium or has a low gallium content percentage in the semiconductor layer 108, the transistor can be highly reliable against positive bias application. In other words, the amount of change in the threshold voltage of the transistor in the PBTS test can be small. Meanwhile, with use of a metal oxide that contains gallium, the gallium content percentage is preferably lower than the indium content percentage. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide film containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case where In—Ga—Zn oxide is used for the semiconductor layer 108, a metal oxide in which the atomic proportion of indium is higher than the atomic proportion of gallium can be used for the semiconductor layer 108. It is further preferable to use a metal oxide in which the atomic proportion of zinc is higher than the atomic proportion of gallium. In other words, a metal oxide in which the atomic proportions of metal elements satisfy In>Ga and Zn>Ga is preferably used for the semiconductor layer 108.

For example, a metal oxide having any of the following atomic ratios of metal elements can be used for the semiconductor layer 108: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

The semiconductor layer 108 is preferably formed using a metal oxide having the following compositions; the proportion of the number of gallium atoms in the total number of atoms of all the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content percentage in the semiconductor layer enables the transistor to be highly resistant to the PBTS test. Note that oxygen vacancy (V_{O}) is less likely to be generated in the metal oxide when the metal oxide contains gallium.

A metal oxide not containing gallium may be used for the semiconductor layer 108. For example, In—Zn oxide can be used for the semiconductor layer 108. In this case, when the ratio of the number of indium atoms in the total number of atoms of all the metal elements contained in the metal oxide is increased, the field-effect mobility of the transistor can be increased. By contrast, when the ratio of the number of zinc atoms in the total number of atoms of all the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer 108. The use of a metal oxide not containing gallium can make a change in the threshold voltage particularly in the PBTS test extremely small.

For example, an oxide containing indium and zinc can be used for the semiconductor layer 108. In that case, for example, a metal oxide where the atomic ratio of metal elements is In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element M is preferably used for the semiconductor layer 108. Furthermore, a metal oxide in which the atomic proportion of zinc is higher than the atomic proportion of the element M is preferably used.

The use of a metal oxide having a low content percentage of the element M for the semiconductor layer 108 enables the transistor to be highly reliable against positive bias application. With use of the transistor as a transistor that is required to have high reliability against positive bias application, a highly reliable semiconductor device can be provided.

Next, the reliability of a transistor against light is described.

Light irradiation on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content percentage of the element M in the metal oxide enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide included in the semiconductor layer 108 is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, the semiconductor layer 108 can include a metal oxide having any of the following atomic ratios: In:M:Zn=1:1:1, In:M:Zn=1:1:1.2, In:M:Zn=1:3:2, In:M:Zn=1:3:3, In:M:Zn=1:3:4, and the neighborhood thereof.

For the semiconductor layer 108, in particular, it is preferable to use a metal oxide in which the proportion of the number of element M atoms in the total number of atoms of all the contained metal elements is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic %.

In the case where In—Ga—Zn oxide is used for the semiconductor layer 108, a metal oxide in which the ratio of the number of indium atoms in the total number of atoms of all the contained metal elements is lower than or equal to the ratio of the number of gallium atoms can be used. For example, it is possible to use a metal oxide having any of the following atomic ratios: In:Ga:Zn=1:1:1, In:Ga:Zn=1:1:1.2, In:Ga:Zn=1:3:2, In:Ga:Zn=1:3:3, In:Ga:Zn=1:3:4, and the neighborhood thereof.

For the semiconductor layer 108, in particular, it is preferable to use a metal oxide in which the proportion of the number of gallium atoms in the total number of atoms of all the contained metal elements is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, further preferably higher than or equal to 40 atomic % and lower than or equal to 60 atomic %, further preferably higher than or equal to 50 atomic % and lower than or equal to 60 atomic %.

The use of a metal oxide having a high content percentage of the element M for the semiconductor layer 108 enables the transistor to be highly reliable against light. With use of the transistor as a transistor that is required to have high reliability against light, a highly reliable semiconductor device can be provided.

As described above, electrical characteristics and reliability of a transistor depend on the composition of the metal oxide used for the semiconductor layer 108. Therefore, by determining the composition of the metal oxide in accordance with the electrical characteristics and reliability required for the transistor, the semiconductor device can have both good electrical characteristics and high reliability.

The semiconductor layer 108 may have a stacked-layer structure including two or more metal oxide layers. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 108 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO,

IAGZO, and ITZO (registered trademark) may be employed, for example.

It is preferable to use a metal oxide layer having crystallinity as the semiconductor layer 108. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer 108, the density of defect states in the semiconductor layer 108 can be reduced, which enables the semiconductor device to have high reliability.

The higher the crystallinity of the metal oxide layer used as the semiconductor layer 108 is, the lower the density of defect states in the semiconductor layer 108 can be. By contrast, the use of a metal oxide layer having low crystallinity enables a transistor to flow a large amount of current.

In the case where the metal oxide layer is formed by a sputtering method, the crystallinity of the formed metal oxide layer can be increased as the substrate temperature at the time of formation is higher. For example, the substrate temperature at the time of formation can be adjusted by the temperature of the stage on which the substrate is placed. The crystallinity of the formed metal oxide layer can be increased with a higher proportion of the flow rate of an oxygen gas to the total flow rate of the film formation gas used at the time of formation (hereinafter also referred to as a higher oxygen flow rate ratio) or with higher oxygen partial pressure in a processing chamber of a film formation apparatus.

The semiconductor layer 108 may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios or different oxygen partial pressures, a stacked-layer structure of two or more metal oxide layers having different crystallinities can be formed. The two or more metal oxide layers included in the semiconductor layer 108 may have different compositions.

The thickness of the semiconductor layer 108 is preferably larger than or equal to 3 nm and smaller than or equal to 100 nm, further preferably larger than or equal to 5 nm and smaller than or equal to 100 nm, further preferably larger than or equal to 10 nm and smaller than or equal to 100 nm, further preferably larger than or equal to 10 nm and smaller than or equal to 70 nm, further preferably larger than or equal to 15 nm and smaller than or equal to 70 nm, further preferably larger than or equal to 15 nm and smaller than or equal to 50 nm, further preferably larger than or equal to 20 nm and smaller than or equal to 50 nm, further preferably larger than or equal to 20 nm and smaller than or equal to 40 nm, further preferably larger than or equal to 25 nm and smaller than or equal to 40 nm.

The substrate temperature at the time of forming the semiconductor layer 108 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancy that might be formed in the semiconductor layer 108 will be described.

In the case where an oxide semiconductor is used for the semiconductor layer 108, hydrogen contained in the oxide semiconductor reacts with oxygen bonded to a metal atom to be water, and thus sometimes forms oxygen vacancy (V_{O}) in the oxide semiconductor. In some cases, a defect where hydrogen enters oxygen vacancy (hereinafter referred to as V_{O}H) functions as a donor and generates an electron serving as a carrier. In other cases, bonding of part of hydrogen to oxygen bonded to a metal atom generates an electron serving as a carrier. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen contained in an oxide semiconductor might reduce the reliability of a transistor.

V_{O}H can function as a donor of the oxide semiconductor. However, it is difficult to evaluate the defect quantitatively. Thus, the oxide semiconductor is sometimes evaluated by not its donor concentration but its carrier concentration. Therefore, in this specification and the like, the carrier concentration on the assumption that the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used for the semiconductor layer 108, the amount of V_{O}H in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to fill oxygen vacancy (V_{O}). When an oxide semiconductor with sufficiently reduced impurities such as V_{O}H is used for a channel formation region of a transistor, the transistor can have stable electrical characteristics. Supplying oxygen to the oxide semiconductor to fill oxygen vacancy (V_{O}) is sometimes referred to as oxygen adding treatment.

When an oxide semiconductor is used for the semiconductor layer 108, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

The description of the semiconductor layer 108 can be referred to for the semiconductor layer 208; thus, the detailed description thereof is omitted. The same materials may be used for the semiconductor layer 108 and the semiconductor layer 208. When the same materials are used for the semiconductor layer 108 and the semiconductor layer 208, for example, the semiconductor layer 108 and the semiconductor layer 208 can be formed using the same sputtering target, reducing the manufacturing cost.

Since the semiconductor layer 108 and the semiconductor layer 208 are formed in different steps, different materials can be used for the semiconductor layer 108 and the semiconductor layer 208. As described above, electrical characteristics and reliability of a transistor depend on the composition of the metal oxide used for the semiconductor layer. Therefore, by determining the composition of the metal oxide in accordance with the electrical characteristics and reliability required for the transistor, the semiconductor device can have both good electrical characteristics and high reliability.

An example where the transistor 200 is used as a transistor requiring a high on-state current is described. In the case where In—Ga—Zn oxide is used for both the semiconductor layer 108 and the semiconductor layer 208, a metal oxide used for the semiconductor layer 208 can have a higher proportion of the number of indium atoms in the total number of atoms of all the contained metal elements (a higher indium content percentage) than a metal oxide used for the semiconductor layer 108, for example.

A difference in indium content percentage between the semiconductor layer 108 and the semiconductor layer 208 can be confirmed by EDX, for example. In EDX, the atomic proportion of each element contained in the metal oxide can be calculated. The proportion of the number of indium atoms in the calculated total number of atoms of all the metal elements (indium content percentage) is compared between the semiconductor layer 108 and the semiconductor layer 208, whereby the difference in indium content percentage can be confirmed. In EDX, the number of counts (the detected value) of characteristic X-rays corresponds to the proportion of an element contained in a metal oxide. Thus, from the peak heights of indium in the semiconductor layer 108 and the semiconductor layer 208, the difference in indium content percentage can be confirmed. For example, in the case where the indium content percentage in the semiconductor layer 208 is higher than the indium content percentage in the semiconductor layer 108, the number of counts of characteristic X-rays derived from indium in the semiconductor layer 208 is higher than the number of counts of characteristic X-rays derived from indium in the semiconductor layer 108. Note that in EDX, the peak of a certain element refers to a point at which the number of counts of the element reaches a local maximum value in a spectrum where the horizontal axis represents the energy of characteristic X-rays and the vertical axis represents the number of counts of characteristic X-rays. Alternatively, the number of counts at an energy of a characteristic X-ray unique to the element may be used to confirm a difference in content percentage. For example, the number of counts at 3.287 keV (In-Lα) can be used for indium, the number of counts at 9.243 keV (Ga-Kα) can be used for gallium, and the number of counts at 8.632 keV (Zn-Kα) can be used for zinc. Although the difference in indium content percentage is described here as an example, a difference in content percentage of other elements can be observed in a similar manner. Also in the case where In—Ga—Zn oxide is used for the semiconductor layer 108 and a metal oxide containing indium, other than the In—Ga—Zn oxide, is used for the semiconductor layer 208, a metal oxide used for the semiconductor layer 208 can have a higher proportion of the number of indium atoms in the total number of atoms of all the contained metal elements than a metal oxide used for the semiconductor layer 108, for example. For example, In—Ga—Zn oxide can be used for the semiconductor layer 108, and In—Zn oxide having a higher proportion of the number of indium atoms in the total number of atoms of all the contained metal elements than a metal oxide used for the semiconductor layer 108 can be suitably used for the semiconductor layer 208.

A metal oxide containing indium, other than the In—Ga—Zn oxide, can be used for the semiconductor layer 108. Also in that case, a metal oxide used for the semiconductor layer 208 can have a higher proportion of the number of indium atoms in the total number of atoms of all the contained metal elements than a metal oxide used for the semiconductor layer 108.

When the semiconductor device of one embodiment of the present invention is used for a display apparatus, for example, a transistor in which the semiconductor layer 208 includes a metal oxide having a high indium content percentage is suitably used for a source driver (also referred to as a source line driver circuit or a signal line driver circuit) or a demultiplexer circuit requiring high-speed switching operation.

Alternatively, a metal oxide used for the semiconductor layer 108 may have a higher proportion of the number of indium atoms in the total number of atoms of all the contained metal elements than a metal oxide used for the semiconductor layer 208.

An example where the transistor 200 is used as a transistor requiring high reliability against positive bias application is described. In the case where In—Ga—Zn oxide is used for both the semiconductor layer 108 and the semiconductor layer 208, a metal oxide used for the semiconductor layer 208 can have a lower proportion of the number of gallium atoms in the total number of atoms of all the contained metal elements than a metal oxide used for the semiconductor layer 108, for example. For example, In—Ga—Zn oxide may be used for the semiconductor layer 108, and a metal oxide not containing gallium (e.g., In—Zn oxide) may be used for the semiconductor layer 208.

A metal oxide used for the semiconductor layer 208 may have a higher proportion of the number of indium atoms and a lower proportion of the number of element M atoms in the total number of atoms of all the contained metal elements than a metal oxide used for the semiconductor layer 108. With such a structure, the transistor 200 enables the on-state current and reliability against positive bias application to be increased.

Alternatively, a metal oxide used for the semiconductor layer 108 may have a lower proportion of the number of element M atoms in the total number of atoms of all the contained metal elements than a metal oxide used for the semiconductor layer 208. Further alternatively, a metal oxide used for the semiconductor layer 108 may have a higher proportion of the number of indium atoms and a lower proportion of the number of element M atoms in the total number of atoms of all the contained metal elements than a metal oxide used for the semiconductor layer 208.

An example where the transistor 200 is used as a transistor requiring high reliability against light is described. A metal oxide used for the semiconductor layer 208 can have a higher proportion of the number of element M atoms in the total number of atoms of all the contained metal elements than a metal oxide used for the semiconductor layer 108. For example, In—Ga—Zn oxide may be used for the semiconductor layer 208, and a metal oxide not containing gallium (e.g., In—Zn oxide) may be used for the semiconductor layer 108.

Alternatively, a metal oxide used for the semiconductor layer 108 may have a higher proportion of the number of element M atoms in the total number of atoms of all the contained metal elements than a metal oxide used for the semiconductor layer 208.

An example where the transistor 100 is used as a transistor requiring high reliability against light and the transistor 200 is used as a transistor requiring a high on-state current is described. A metal oxide used for the semiconductor layer 108 can have a higher proportion of the number of element M atoms in the total number of atoms of all the contained metal elements than a metal oxide used for the semiconductor layer 208. A metal oxide used for the semiconductor layer 208 can have a higher proportion of the number of indium atoms in the total number of atoms of all the contained metal elements than a metal oxide used for the semiconductor layer 108.

Metal oxides that can be used for the semiconductor layer 108 and the semiconductor layer 208 are different in at least one of the thickness, crystallinity, carrier concentration, and film quality as well as the composition. For example, in addition to the composition difference, the thickness or the film formation condition of the metal oxides may be varied between the semiconductor layer 108 and the semiconductor layer 208 so that the on-state current of the transistor 200 is higher than the on-state current of the transistor 100.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter also referred to as off-state current), and charge accumulated in a capacitor that is connected in series with the transistor can be held for a long period. Furthermore, the power consumption of the semiconductor device can be reduced with the OS transistor.

The semiconductor device of one embodiment of the present invention can be used for a display apparatus, for example. To increase the emission luminance of a light-emitting device included in a pixel circuit in the display apparatus, it is necessary to increase the amount of current flowing through the light-emitting device. To increase the amount of current, the source-drain voltage of a driving transistor included in the pixel circuit needs to be increased. Since the OS transistor has higher breakdown voltage between a source and a drain than a transistor including silicon (hereinafter referred to as a Si transistor), high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be finely set by a change in gate-source voltage; thus, the amount of current flowing through the light-emitting device can be controlled. Therefore, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through the OS transistor than through a Si transistor. Thus, with use of an OS transistor as a driving transistor, current can be made flow stably to the light-emitting device, for example, even when a variation in current-voltage characteristics of the light-emitting device occurs. In other words, when the OS transistor operates in the saturation region, the source-drain current hardly changes even with an increase in the source-drain voltage; thus, the emission luminance of the light-emitting device can be stable. In this specification and the like, the state where the change in current is small in the saturation region of the Id-Vd characteristics of a transistor is sometimes described using the expression “favorable saturation”.

As described above, with use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

A change in electrical characteristics of an OS transistor due to irradiation with radiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

### [Insulating Layer 110 and Insulating Layer 210]

For the insulating layer 110, an inorganic insulating material or an organic insulating material can be used. The insulating layer 110 may have a stacked-layer structure of an inorganic insulating material and an organic insulating material.

For the insulating layer 110, an inorganic insulating material can be suitably used. As the inorganic insulating material, one or more of an oxide, an oxynitride, a nitride oxide, and a nitride can be used. For the insulating layer 110, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The oxygen content and the nitrogen content can be analyzed by secondary ion mass spectrometry (SIMS) or X-ray photoelectron spectroscopy (XPS). When the content percentage of a target element is high (e.g., higher than or equal to 0.5 atomic %, or higher than or equal to 1 atomic %), XPS is suitable. In contrast, when the content percentage of a target element is low (e.g., lower than 0.5 atomic %, or lower than 1 atomic %), SIMS is suitable. To compare the contents of elements, analysis with a combination of SIMS and XPS is preferably used.

The insulating layer 110 may have a stacked-layer structure of two or more layers. FIG. 1C and the like illustrate a structure in which the insulating layer 110 has a stacked-layer structure of an insulating layer 110a, an insulating layer 110b over the insulating layer 110a, and an insulating layer 110c over the insulating layer 110b. For each of the insulating layer 110a, the insulating layer 110b, and the insulating layer 110c, the material that can be used for the insulating layer 110 can be used. For the insulating layer 110a, the insulating layer 110b, and the insulating layer 110c, the same material or different materials may be used. Note that the insulating layer 110a, the insulating layer 110b, and the insulating layer 110c may each have a stacked-layer structure of two or more layers.

The thickness of the insulating layer 110b can be larger than the thickness of the insulating layer 110a. The thickness of the insulating layer 110b can be larger than the thickness of the insulating layer 110c. The formation speed of the insulating layer 110b is preferably high. In particular, the formation speed of the insulating layer 110b is preferably high in the case where the thickness of the insulating layer 110b is large. By increasing the formation speed of the insulating layer 110b, the productivity can be increased. For example, by increasing power at the time of forming the insulating layer 110b, the formation speed can be increased.

The insulating layer 110b may have a stacked-layer structure of two or more layers. For example, the insulating layer 110b has high stress when the insulating layer 110b has a large thickness, which might cause warpage of the substrate. In some cases, the formation of the insulating layer 110b in a plurality of steps can inhibit occurrence of problems during the process caused by stress. Note that in a cross-sectional transmission electron microscopy (TEM) image or the like, a boundary between the layers included in the insulating layer 110b is unclear in some cases.

The stress of the insulating layer 110b is preferably low. The insulating layer 110b has high stress when the insulating layer 110b has a large thickness, which might cause warpage of the substrate. The low stress of the insulating layer 110b can inhibit occurrence of problems during the process caused by stress such as warpage of the substrate.

The insulating layer 110a and the insulating layer 110c function as blocking films that inhibit release of gas from the insulating layer 110b. For each of the insulating layer 110a and the insulating layer 110c, a material in which gas is hardly diffused is preferably used. The insulating layer 110a and the insulating layer 110c each preferably include a region having a higher film density than the insulating layer 110b. The insulating layer 110a and the insulating layer 110c having high film densities can have a high blocking property. Note that the insulating layer 110a and the insulating layer 110c may have different film densities. For each of the insulating layer 110a and the insulating layer 110c, a material containing more nitrogen than the insulating layer 110b can be used, for example. The insulating layer 110a and the insulating layer 110c in each of which the nitrogen content is high can have a high blocking property. Note that the insulating layer 110a and the insulating layer 110c may have different nitrogen contents.

The insulating layer 110a and the insulating layer 110c have thicknesses with which the insulating layers function as blocking films that inhibit release of gas from the insulating layer 110b, and can be thinner than the insulating layer 110b. Note that the insulating layer 110a and the insulating layer 110c may have different thicknesses. The formation speeds of the insulating layer 110a and the insulating layer 110c are preferably lower than the formation speed of the insulating layer 110b. Note that each of the insulating layer 110a and the insulating layer 110c formed at a low speed has a high film density and can have a high blocking property. Similarly, each of the insulating layer 110a and the insulating layer 110c formed at a high substrate temperature has a high film density and can have a high blocking property.

The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Therefore, in a transmission electron (TE) image, the insulating layer 110a and the insulating layer 110c are each sometimes shown as a dark-colored (dark) image compared to the insulating layer 110b. Note that since the insulating layer 110a, the insulating layer 110b, and the insulating layer 110c have different film densities even when including the same materials, it is sometimes possible to identify the boundary between the insulating layers by a difference in contrast in a TEM image of a cross section.

A difference in nitrogen content between the insulating layer 110a, the insulating layer 110b, and the insulating layer 110c can be confirmed by EDX, for example. In the case where silicon nitride is used for the insulating layer 110a and silicon oxynitride is used for the insulating layer 110b, for example, the ratio of the peak height of nitrogen to the peak height of silicon in the insulating layer 110a is higher than the ratio of the peak height of nitrogen to the peak height of silicon in the insulating layer 110b. In the case where silicon nitride is used for the insulating layer 110c and silicon oxynitride is used for the insulating layer 110b, the ratio of the peak height of nitrogen to the peak height of silicon in the insulating layer 110c is higher than the ratio of the peak height of nitrogen to the peak height of silicon in the insulating layer 110b. Note that in EDX, the peak of a certain element refers to a point at which the number of counts of the element reaches a local maximum value in a spectrum where the horizontal axis represents the energy of characteristic X-rays and the vertical axis represents the number of counts (the detected value) of characteristic X-rays. Alternatively, the number of counts at an energy of a characteristic X-ray unique to the element may be used to confirm a difference in nitrogen content with the ratio of the number of counts of nitrogen to the number of counts of silicon. For example, the number of counts at 1.739 keV (Si-Kα) can be used for silicon, and the number of counts at 0.392 keV (N-Kα) can be used for nitrogen. The ratio of the number of counts of nitrogen to the number of counts of silicon in the insulating layer 110a is higher than the ratio of the number of counts of nitrogen to the number of counts of silicon in the insulating layer 110b. The ratio of the number of counts of nitrogen to the number of counts of silicon in the insulating layer 110c is higher than the ratio of the number of counts of nitrogen to the number of counts of silicon in the insulating layer 110b.

The insulating layer 110a and the insulating layer 110c may each include a region having a lower hydrogen concentration in the film than the insulating layer 110b. The difference in hydrogen concentration between the insulating layer 110a, the insulating layer 110b, and the insulating layer 110c can be examined by secondary ion mass spectrometry (SIMS), for example.

Here, the insulating layer 110 will be described in detail with use of a structure in which a metal oxide is used for the semiconductor layer 108 as an example.

In the case where an oxide semiconductor is used for the semiconductor layer 108, an inorganic insulating material can be suitably used for each of the insulating layer 110a, the insulating layer 110b, and the insulating layer 110c.

It is preferable to use an oxide or an oxynitride for the insulating layer 110b. A film from which oxygen is released by heating is preferably used as the insulating layer 110b. For example, silicon oxide or silicon oxynitride can be suitably used for the insulating layer 110b.

Oxygen released from the insulating layer 110b can be supplied to the semiconductor layer 108. Supplying oxygen from the insulating layer 110b to the semiconductor layer 108, particularly to the channel formation region in the semiconductor layer 108, can allow the amount of oxygen vacancy (V_{O}) and V_{O}H to be reduced in the semiconductor layer 108, so that a highly reliable transistor having favorable electrical characteristics can be obtained. The insulating layer 110b preferably has a high oxygen diffusion coefficient. When the insulating layer 110b has a high oxygen diffusion coefficient, oxygen is easily diffused in the insulating layer 110b, so that oxygen can be efficiently supplied from the insulating layer 110b to the semiconductor layer 108.

Examples of treatment for supplying oxygen to the semiconductor layer 108 include heat treatment in an oxygen-containing atmosphere and plasma treatment in an oxygen-containing atmosphere.

It is preferable that the amount of oxygen vacancy (V_{O}) and V_{O}H be small in the channel formation region of the transistor 100. Particularly in the case where the channel length L100 is short, oxygen vacancy (V_{O}) and V_{O}H in the channel formation region greatly affect electrical characteristics and reliability. For example, diffusion of V_{O}H from the source region or the drain region into the channel formation region increases the carrier concentration in the channel formation region, which might cause a change in the threshold voltage or a reduction in the reliability in the transistor 100. As the channel length L100 of the transistor 100 is shorter, such diffusion of V_{O}H greatly affects electrical characteristics and reliability. Supplying oxygen from the insulating layer 110b to the semiconductor layer 108, particularly to the channel formation region in the semiconductor layer 108, can allow the amount of oxygen vacancy (V_{O}) and V_{O}H to be reduced. Thus, the transistor with a short channel length can have favorable electrical characteristics and high reliability.

The amount of impurities (e.g., water and hydrogen) released from the insulating layer 110b itself is preferably small. With the insulating layer 110b from which a small amount of impurities is released, diffusion of impurities into the semiconductor layer 108 is inhibited, and the transistor can have favorable electrical characteristics and high reliability.

For example, silicon oxide or silicon oxynitride formed by a PECVD method can be suitably used for the insulating layer 110b. In that case, a mixed gas including a gas containing silicon and a gas containing oxygen is preferably used as a source gas. As the gas containing silicon, one or more of silane, disilane, trisilane, and silane fluoride can be used, for example. As the gas containing oxygen, one or more of oxygen (O₂), ozone (O₃), nitrous oxide (N₂O), nitric oxide (NO), and nitrogen dioxide (NO₂) can be used, for example. Note that by increasing power at the time of forming the insulating layer 110b, the amount of impurities (e.g., water and hydrogen) released from the insulating layer 110b can be reduced.

The insulating layer 110a and the insulating layer 110c are preferably less likely to transmit oxygen. The insulating layer 110a and the insulating layer 110c function as blocking films that inhibit release of oxygen from the insulating layer 110b. Moreover, the insulating layer 110a and the insulating layer 110c are preferably less likely to transmit hydrogen. The insulating layer 110a and the insulating layer 110c function as blocking films that inhibit diffusion of hydrogen into the semiconductor layer 108 from the outside of the transistor through the insulating layer 110. The insulating layer 110a and the insulating layer 110c preferably have high film densities. The insulating layer 110a and the insulating layer 110c having high film densities can have a high blocking property against oxygen and hydrogen. The film densities of the insulating layer 110a and the insulating layer 110c are preferably higher than the film density of the insulating layer 110b. In the case where silicon oxide or silicon oxynitride is used for the insulating layer 110b, silicon nitride, silicon nitride oxide, or aluminum oxide can be suitably used for each of the insulating layer 110a and the insulating layer 110c, for example. The insulating layer 110a and the insulating layer 110c each preferably include a region containing more nitrogen than the insulating layer 110b. A material containing more nitrogen than the insulating layer 110b can be used for each of the insulating layer 110a and the insulating layer 110c. A nitride or a nitride oxide is preferably used for each of the insulating layer 110a and the insulating layer 110c. For example, silicon nitride or silicon nitride oxide can be suitably used for each of the insulating layer 110a and the insulating layer 110c.

When oxygen contained in the insulating layer 110b is diffused upward from a region of the insulating layer 110b that is not in contact with the semiconductor layer 108 (e.g., the top surface of the insulating layer 110b), the amount of oxygen supplied from the insulating layer 110b to the semiconductor layer 108 might be reduced. Provision of the insulating layer 110c over the insulating layer 110b can inhibit diffusion of oxygen contained in the insulating layer 110b from the region of the insulating layer 110b that is not in contact with the semiconductor layer 108. Similarly, provision of the insulating layer 110a under the insulating layer 110b can inhibit downward diffusion of oxygen contained in the insulating layer 110b from the region of the insulating layer 110b that is not in contact with the semiconductor layer 108. Accordingly, the amount of oxygen supplied from the insulating layer 110b to the semiconductor layer 108 is increased, whereby the amount of oxygen vacancy (V_{O}) and V_{O}H in the semiconductor layer 108 can be reduced. Consequently, the transistor can have favorable electrical characteristics and high reliability.

The conductive layer 112a and the conductive layer 112b are oxidized by oxygen contained in the insulating layer 110b and have high resistance in some cases. Moreover, when the conductive layer 112a and the conductive layer 112b are oxidized by oxygen contained in the insulating layer 110b, the amount of oxygen supplied from the insulating layer 110b to the semiconductor layer 108 might be reduced. Provision of the insulating layer 110a between the insulating layer 110b and the conductive layer 112a can inhibit the conductive layer 112a from being oxidized and having high resistance. Similarly, provision of the insulating layer 110c between the insulating layer 110b and the conductive layer 112b can inhibit the conductive layer 112b from being oxidized and having high resistance. In addition, the amount of oxygen supplied from the insulating layer 110b to the semiconductor layer 108 is increased and the amount of oxygen vacancy (V_{O}) and V_{O}H in the semiconductor layer 108 can be reduced, whereby the transistor can have favorable electric characteristics and high reliability.

Hydrogen diffused in the semiconductor layer 108 reacts with an oxygen atom contained in an oxide semiconductor to be water, and thus sometimes forms oxygen vacancy (V_{O}). Furthermore, V_{O}H is formed and the carrier concentration is increased in some cases. Provision of the insulating layer 110a and the insulating layer 110c can allow the amount of oxygen vacancy (V_{O}) and V_{O}H to be reduced in the semiconductor layer 108, whereby the transistor can have favorable electric characteristics and high reliability.

The insulating layer 110a and the insulating layer 110c preferably have thicknesses with which the insulating layers function as blocking films against oxygen and hydrogen. When the insulating layer 110a and the insulating layer 110c are thin, the function of a blocking film might deteriorate. Meanwhile, when the insulating layer 110a and the insulating layer 110c are thick, a region where the semiconductor layer 108 is in contact with the insulating layer 110b is narrowed and the amount of oxygen supplied from the insulating layer 110b to the semiconductor layer 108 might be reduced. The insulating layer 110a and the insulating layer 110c may each be thinner than the insulating layer 110b. The thicknesses of the insulating layer 110a and the insulating layer 110c are each preferably larger than or equal to 5 nm and smaller than or equal to 100 nm, further preferably larger than or equal to 5 nm and smaller than or equal to 70 nm, further preferably larger than or equal to 10 nm and smaller than or equal to 70 nm, further preferably larger than or equal to 10 nm and smaller than or equal to 50 nm, further preferably larger than or equal to 20 nm and smaller than or equal to 50 nm, further preferably larger than or equal to 20 nm and smaller than or equal to 40 nm. The thicknesses of the insulating layer 110a and the insulating layer 110c in the above range can allow the amount of oxygen vacancy (V_{O}) and V_{O}H to be reduced in the semiconductor layer 108, particularly in the channel formation region, whereby the transistor can have favorable electric characteristics and high reliability.

The amount of impurities (e.g., water and hydrogen) released from the insulating layer 110a and the insulating layer 110c themselves is preferably small. With the insulating layer 110a and the insulating layer 110c from which a small amount of impurities is released, diffusion of impurities into the semiconductor layer 108 is inhibited, and the transistor can have favorable electrical characteristics and high reliability.

By reducing the amount of impurities (e.g., water and hydrogen) released from the insulating layer 110a and the insulating layer 110c, the semiconductor layer 108 in a region in contact with the insulating layer 110a and the semiconductor layer 108 in a region in contact with the insulating layer 110c can each also function as the channel formation region. Note that when a material that releases impurities (e.g., water and hydrogen) is used for the insulating layer 110a, the semiconductor layer 108 in the region in contact with the insulating layer 110a can function as the source region or the drain region. The same applies to the insulating layer 110c.

In the transistor 100, oxygen is supplied from the insulating layer 110 to the semiconductor layer 108, whereby the amount of oxygen vacancy (V_{O}) and V_{O}H in the channel formation region is reduced. Consequently, the transistor can have favorable electrical characteristics and high reliability.

Due to heat applied in a step after the formation of the semiconductor layer 108, oxygen might be released from the semiconductor layer 108. However, supply of oxygen from the insulating layer 110 to the semiconductor layer 108 can inhibit an increase in the amount of oxygen vacancy (V_{O}) and V_{O}H. Furthermore, in a step after the formation of the semiconductor layer 108, the flexibility of the treatment temperature can be increased. Specifically, also in a step after the formation of the semiconductor layer 108, the treatment temperature can be high. Consequently, the transistor 100 and the transistor 200 can be formed to have favorable electrical characteristics and high reliability.

The description of the insulating layer 110 can be referred to for the insulating layer 210; thus, the detailed description thereof is omitted. The description of the insulating layer 110a can be referred to for the insulating layer 210a, the description of the insulating layer 110b can be referred to for the insulating layer 210b, and the description of the insulating layer 110c can be referred to for the insulating layer 210c.

In the transistor 200, oxygen is supplied from the insulating layer 210 to the semiconductor layer 208, whereby the amount of oxygen vacancy (V_{O}) and V_{O}H in the channel formation region is reduced. Consequently, the transistor can have favorable electrical characteristics and high reliability.

Note that a structure may be employed in which one or more of the insulating layer 110a, the insulating layer 110c, the insulating layer 210a, and the insulating layer 210c are not provided. A structure may be employed in which neither the insulating layer 110a, the insulating layer 110c, the insulating layer 210a, nor the insulating layer 210c is provided.

[Conductive layer 112a, conductive layer 112b, conductive layer 104, conductive layer 212b, and conductive layer 204]

The conductive layer 112a, the conductive layer 112b, the conductive layer 104, the conductive layer 212b, and the conductive layer 204 functioning as a source electrode, a drain electrode, and gate electrodes can each be formed using one or more of chromium, copper, aluminum, gold, silver, zinc, tantalum, titanium, tungsten, manganese, nickel, iron, cobalt, molybdenum, and niobium; or an alloy including one or more of these metals as its components. For each of the conductive layer 112a, the conductive layer 112b, the conductive layer 104, the conductive layer 212b, and the conductive layer 204, a conductive material with low electrical resistivity that contains one or more of copper, silver, gold, and aluminum can be suitably used. Copper or aluminum is particularly preferable because of its high mass-productivity. As the conductive layer 112a, the conductive layer 112b, the conductive layer 104, the conductive layer 212b, and the conductive layer 204, metal oxide films (also referred to as oxide conductors) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when oxygen vacancy is formed in a metal oxide having semiconductor characteristics and hydrogen is added to the oxygen vacancy, a donor level is formed in the vicinity of the conduction band. As a result, the conductivity of the metal oxide is increased, so that the metal oxide becomes a conductor. The metal oxide having become a conductor can be referred to as an oxide conductor.

Each of the conductive layer 112a, the conductive layer 112b, the conductive layer 104, the conductive layer 212b, and the conductive layer 204 may have a stacked-layer structure of a conductive film containing the oxide conductor (the metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 104, the conductive layer 212b, and the conductive layer 204. The use of a Cu—X alloy film enables the manufacturing cost to be reduced because a wet etching method can be used in the processing.

Note that the conductive layer 112a, the conductive layer 112b, the conductive layer 104, the conductive layer 212b, and the conductive layer 204 may be formed using the same material or different materials.

Here, the conductive layer 112a, the conductive layer 112b, and the conductive layer 212b will be described in detail with use of a structure in which a metal oxide is used for each of the semiconductor layer 108 and the semiconductor layer 208 as an example.

When an oxide semiconductor is used for the semiconductor layer 108, the conductive layer 112a and the conductive layer 112b are oxidized by oxygen contained in the semiconductor layer 108 and have high resistance in some cases. The conductive layer 112a and the conductive layer 112b are oxidized by oxygen contained in the insulating layer 110b and have high resistance in some cases. Moreover, when the conductive layer 112a and the conductive layer 112b are oxidized by oxygen contained in the semiconductor layer 108, the amount of oxygen vacancy (V_{O}) in the semiconductor layer 108 is increased in some cases. When the conductive layer 112a and the conductive layer 112b are oxidized by oxygen contained in the insulating layer 110b, the amount of oxygen supplied from the insulating layer 110b to the semiconductor layer 108 might be reduced.

Similarly, when an oxide semiconductor is used for the semiconductor layer 208, the conductive layer 112b and the conductive layer 212b are oxidized by oxygen contained in the semiconductor layer 208 and have high resistance in some cases. The conductive layer 112b and the conductive layer 212b are oxidized by oxygen contained in the insulating layer 210b and have high resistance in some cases. Moreover, when the conductive layer 112b and the conductive layer 212b are oxidized by oxygen contained in the semiconductor layer 208, the amount of oxygen vacancy (V_{O}) in the semiconductor layer 208 is increased in some cases. When the conductive layer 112b and the conductive layer 212b are oxidized by oxygen contained in the insulating layer 210b, the amount of oxygen supplied from the insulating layer 210b to the semiconductor layer 208 might be reduced.

A material that is less likely to be oxidized is preferably used for each of the conductive layer 112a, the conductive layer 112b, and the conductive layer 212b. An oxide conductor is preferably used for each of the conductive layer 112a and the conductive layer 112b. For example, In—Sn oxide (ITO) or In—Sn—Si oxide (ITSO) can be suitably used. A nitride conductor may be used for each of the conductive layer 112a, the conductive layer 112b, and the conductive layer 212b. Examples of the nitride conductor include tantalum nitride and titanium nitride. The conductive layer 112a, the conductive layer 112b, and the conductive layer 212b may each have a stacked-layer structure of the above-described materials.

The conductive layer 112a and the conductive layer 112b each containing a material that is less likely to be oxidized can be inhibited from being oxidized by oxygen contained in the semiconductor layer 108 or oxygen contained in the insulating layer 110b and having high resistance. Furthermore, it is possible to increase the amount of oxygen supplied from the insulating layer 110b to the semiconductor layer 108 while an increase in the amount of oxygen vacancy (V_{O}) in the semiconductor layer 108 is inhibited. Accordingly, the amount of oxygen vacancy (V_{O}) and V_{O}H in the semiconductor layer 108 can be reduced, whereby the transistor can have favorable electric characteristics and high reliability.

Similarly, the conductive layer 112b and the conductive layer 212b each containing a material that is less likely to be oxidized can be inhibited from having high resistance. Furthermore, it is possible to increase the amount of oxygen supplied from the insulating layer 210b to the semiconductor layer 208 while an increase in the amount of oxygen vacancy (V_{O}) in the semiconductor layer 208 is inhibited. Accordingly, the amount of oxygen vacancy (V_{O}) and V_{O}H in the semiconductor layer 208 can be reduced, whereby the transistor can have favorable electric characteristics and high reliability. Note that the conductive layer 112a, the conductive layer 112b, and the conductive layer 212b may be formed using the same material or different materials.

The conductive layer 112b includes a region in contact with the transistor 100 and a region in contact with the transistor 200. When a material that is less likely to be oxidized is used for the conductive layer 112b, the amount of oxygen vacancy (V_{O}) and V_{O}H in the semiconductor layer 108 can be reduced, and the amount of oxygen vacancy (V_{O}) and V_{O}H in the semiconductor layer 208 can be reduced. Consequently, the transistor can have favorable electrical characteristics and high reliability.

As described above, a material that is less likely to be oxidized is preferably used for each of the conductive layer 112a and the conductive layer 112b in contact with the semiconductor layer 108. However, the use of a material that is less likely to be oxidized might increase resistance. The conductive layer 112a and the conductive layer 112b function as wirings and thus preferably have low resistance. In view of this, a material that is less likely to be oxidized is used for the conductive layer 112a_1 including a region in contact with the semiconductor layer 108, and a material with low electrical resistivity is used for the conductive layer 112a_2 not including a region in contact with the semiconductor layer 108, whereby the resistance of the conductive layer 112a can be reduced. Furthermore, the amount of oxygen vacancy (V_{O}) and V_{O}H in the semiconductor layer 108 can be reduced, whereby the transistor can have favorable electric characteristics and high reliability.

In particular, in the case where the channel length L100 is short, oxygen vacancy (V_{O}) and V_{O}H in the channel formation region greatly affect electrical characteristics and reliability, as described above. When a material that is less likely to be oxidized is used for the conductive layer 112a_1, an increase in the amount of oxygen vacancy (V_{O}) and V_{O}H in the semiconductor layer 108 can be inhibited. Thus, the transistor with a short channel length can have favorable electrical characteristics and high reliability.

One or more of an oxide conductor and a nitride conductor can be suitably used for the conductive layer 112a_1. For the conductive layer 112a_2, a material having lower electrical resistivity than the conductive layer 112a_1 is preferably used. For the conductive layer 112a_2, one or more of copper, aluminum, titanium, tungsten, and molybdenum or an alloy containing one or more of these metals as its components can be suitably used, for example. Specifically, In—Sn—Si oxide (ITSO) and tungsten can be suitably used for the conductive layer 112a_1 and the conductive layer 112a_2, respectively.

Note that the structure of the conductive layer 112a is determined in accordance with wiring resistance required for the conductive layer 112a. For example, when the wiring (the conductive layer 112a) is short and requires relatively high wiring resistance, the conductive layer 112a may have a single-layer structure using a material that is less likely to be oxidized. Meanwhile, when the wiring (the conductive layer 112a) is long and requires relatively low wiring resistance, the conductive layer 112a preferably has a stacked-layer structure using a material that is less likely to be oxidized and a material with low electrical resistivity.

The structure of the conductive layer 112a can be employed for another conductive layer. For example, the conductive layer 112b has a stacked-layer structure of a first conductive layer and a second conductive layer over the first conductive layer, and an opening is provided in a region in contact with the semiconductor layer 208 of the second conductive layer. The conductive layer 212b may have a similar structure.

### [Insulating Layer 106 and Insulating Layer 206]

The insulating layer 106 functioning as the gate insulating layer preferably has low defect density. With the insulating layer 106 having low defect density, the transistor can have favorable electrical characteristics. In addition, the insulating layer 106 preferably has high withstand voltage. With the insulating layer 106 having high withstand voltage, the transistor can have high reliability.

For the insulating layer 106, one or more of an insulating oxide, an insulating oxynitride, an insulating nitride oxide, and an insulating nitride can be used, for example. For the insulating layer 106, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 106 may be either a single layer or a stacked layer. The insulating layer 106 may have a stacked-layer structure of an oxide and a nitride.

A transistor having a minute size and including a thin gate insulating layer may have a large leakage current. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 106 itself is preferably small. With the insulating layer 106 from which a small amount of impurities is released, diffusion of impurities into the semiconductor layer 108 is inhibited, and the transistor can have favorable electrical characteristics and high reliability.

In the transistor 200, the insulating layer 106 includes a region in contact with the semiconductor layer 208. By reducing the amount of impurities (e.g., water and hydrogen) released from the insulating layer 106, the semiconductor layer 208 in a region in contact with the insulating layer 106 can also function as the channel formation region.

The insulating layer 106 is formed over the semiconductor layer 108, and thus is preferably a film formed under conditions where damage to the semiconductor layer 108 is small. For example, the insulating layer 106 can be formed under conditions where the film formation speed (also referred to as film formation rate) is sufficiently low. For example, when the insulating layer 106 is formed by a plasma CVD method under a low-power condition, damage to the semiconductor layer 108 can be small.

Here, the insulating layer 106 will be described in detail with use of a structure in which a metal oxide is used for the semiconductor layer 108 as an example.

To improve the properties of the interface with the semiconductor layer 108, at least the side of a region in the insulating layer 106, which is in contact with the semiconductor layer 108, is preferably include an oxide or an oxynitride. For example, one or more of silicon oxide and silicon oxynitride can be suitably used for the insulating layer 106. A film from which oxygen is released by heating is further preferably used for the insulating layer 106.

Note that the insulating layer 106 may have a stacked-layer structure. The insulating layer 106 can have a stacked-layer structure of an oxide film or an oxynitride film on the side in contact with the semiconductor layer 108 and a nitride film or a nitride oxide film on the side in contact with the conductive layer 104. For example, one or more of silicon oxide and silicon oxynitride can be suitably used for the oxide film or the oxynitride film. Silicon nitride can be suitably used for the nitride film or the nitride oxide film.

The description of the insulating layer 106 can be referred to for the insulating layer 206; thus, the detailed description thereof is omitted. For the insulating layer 106 and the insulating layer 206, the same material or different materials may be used.

By reducing the amount of impurities (e.g., water and hydrogen) released from the insulating layer 206, the semiconductor layer 208 in a region in contact with the insulating layer 206 can also function as the channel formation region.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. Alternatively, any of these substrates over which a semiconductor element is provided may be used as the substrate 102. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. The separation layer can be used when part or the whole of a semiconductor device completed thereover is separated from the substrate 102 and transferred onto another substrate. In such a case, the transistor 100 and the like can be transferred to a substrate having low heat resistance or a flexible substrate as well.

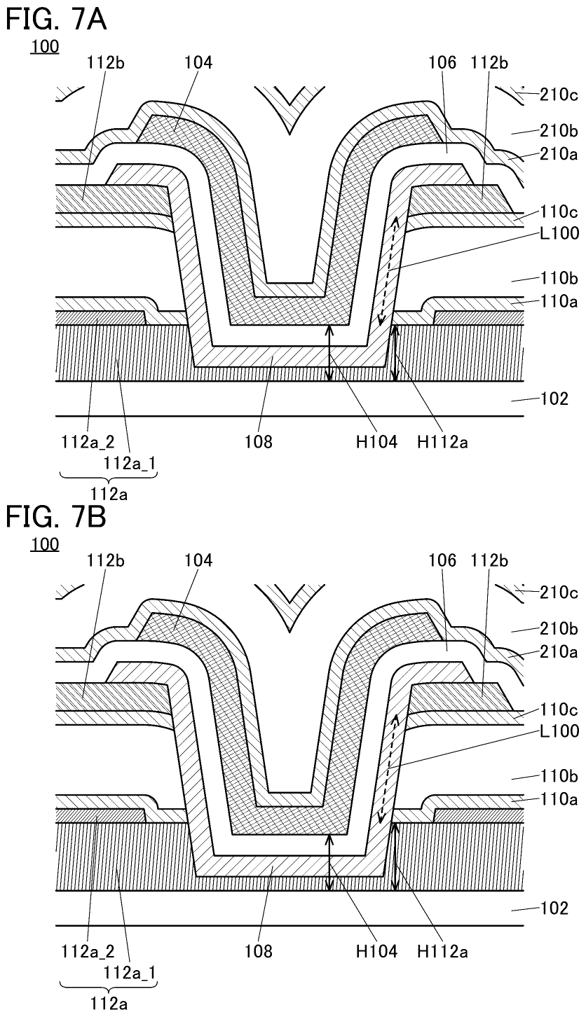

Note that FIG. 1C and the like illustrate the structure of the transistor 100 in which the thickness of the region in contact with the semiconductor layer 108 and the thickness of the region not in contact with the semiconductor layer 108 are equal to or substantially equal to each other in the conductive layer 112a (specifically, the conductive layer 112a_1); however, one embodiment of the present invention is not limited thereto. The thickness of the region in contact with the semiconductor layer 108 and the thickness of the region not in contact with the semiconductor layer 108 may be different from each other in the conductive layer 112a_1. As illustrated in FIG. 7A, the thickness of the region in contact with the semiconductor layer 108 is preferably smaller than the thickness of the region not in contact with the semiconductor layer 108 in the conductive layer 112a_1.

FIG. 7A illustrates a height H104 from the formation surface of the conductive layer 112a_1 (here, the top surface of the substrate 102) to the lowest position of the bottom surface of the conductive layer 104. FIG. 7A also illustrates a height H112a from the formation surface of the conductive layer 112a_1 (here, the top surface of the substrate 102) to the highest position of the region where the conductive layer 112a_1 and the semiconductor layer 108 are in contact with each other. As illustrated in FIG. 7A, the height H104 to the lowest position of the bottom surface of the conductive layer 104 is preferably equal to or substantially equal to the height H112a to the highest position of the region where the conductive layer 112a_1 and the semiconductor layer 108 are in contact with each other. Alternatively, as illustrated in FIG. 7B, the height H104 is preferably smaller than the height H112a. When the height H104 to the lowest position of the bottom surface of the conductive layer 104 is equal to the height H112a to the highest position of the region where the conductive layer 112a_1 and the semiconductor layer 108 are in contact with each other or smaller than the height H112a, the electric field of the gate electrode that is applied to the channel formation region in the vicinity of the conductive layer 112a can be increased and the on-state current of the transistor 100 can be increased.

When the height H104 to the lowest position of the bottom surface of the conductive layer 104 is equal to the height H112a to the highest position of the region where the conductive layer 112a_1 and the semiconductor layer 108 are in contact with each other or smaller than the height H112a, the electric field of the gate electrode applied to the channel formation region can be more uniform. Here, in the case where the electric field of the gate electrode applied to the channel formation region is not uniform, the electrical characteristics in the case where the conductive layer 112a is the source electrode and the conductive layer 112b is the drain electrode and the electrical characteristics in the case where the conductive layer 112a is the drain electrode and the conductive layer 112b is the source electrode might be different from each other. By making the electric field of the gate electrode applied to the channel formation region of the transistor 100 more uniform, the electrical characteristics in the both cases can be made equivalent to each other. Thus, the transistor 100 can be suitably used in a circuit structure in which a source and a drain are interchanged with each other.

Note that the thickness of the conductive layer 112a (specifically, the conductive layer 112a_1) is adjusted as appropriate so that the height H104 is equal to the height H112a or smaller than the height H112a.

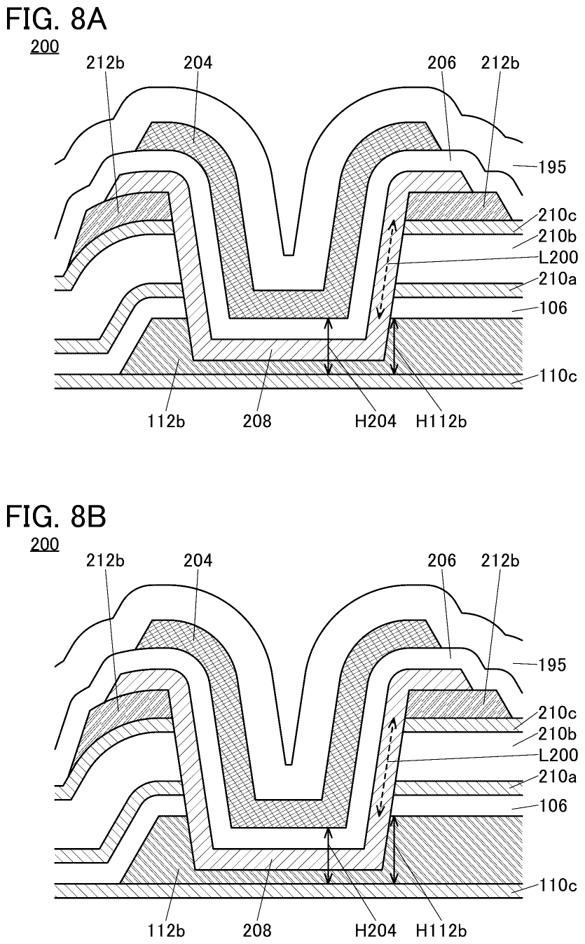

Similarly, in the transistor 200, the thickness of the region in contact with the semiconductor layer 208 and the thickness of the region not in contact with the semiconductor layer 208 may be different from each other in the conductive layer 112b. As illustrated in FIG. 8A, the thickness of the region in contact with the semiconductor layer 208 is preferably smaller than the thickness of the region not in contact with the semiconductor layer 208 in the conductive layer 112b.

FIG. 8A illustrates a height H204 from the formation surface of the conductive layer 112b (here, the top surface of the insulating layer 110c) to the lowest position of the bottom surface of the conductive layer 204. FIG. 8A also illustrates a height H112b from the formation surface of the conductive layer 112b (here, the top surface of the insulating layer 110c) to the highest position of the region where the conductive layer 112b and the semiconductor layer 208 are in contact with each other. As illustrated in FIG. 8A, the height H204 to the lowest position of the bottom surface of the conductive layer 204 is preferably equal to or substantially equal to the height H112b to the highest position of the region where the conductive layer 112b and the semiconductor layer 208 are in contact with each other. Alternatively, as illustrated in FIG. 8B, the height H204 is preferably smaller than the height H112b. When the height H204 to the lowest position of the bottom surface of the conductive layer 204 is equal to the height H112b to the highest position of the region where the conductive layer 112b and the semiconductor layer 208 are in contact with each other or smaller than the height H112b, the electric field of the gate electrode that is applied to the channel formation region in the vicinity of the conductive layer 112b can be increased and the on-state current of the transistor 200 can be increased. By making the electric field of the gate electrode applied to the channel formation region of the transistor 200 more uniform, the electrical characteristics before and after replacing the source and the drain can be made equivalent to each other. Thus, the transistor 200 can be suitably used in a circuit structure in which a source and a drain are interchanged with each other.

Note that the thickness of the conductive layer 112b is adjusted as appropriate so that the height H204 is equal to the height H112b or smaller than the height H112b.

The structures of the conductive layer 112a and the conductive layer 112b described here can be applied to other structure examples.

The above is the description of the components.

A structure example of a semiconductor device whose structure is partly different from that of Structure example 1-1 shown above will be described below. Note that description of the same portions as those in Structure example 1-1 shown above is omitted below in some cases. Furthermore, in drawings that are referred to later, the same hatching pattern is applied to portions having functions similar to those in Structure example 1-1 shown above, and the portions are not denoted by reference numerals in some cases.

### Structure Example 1-2

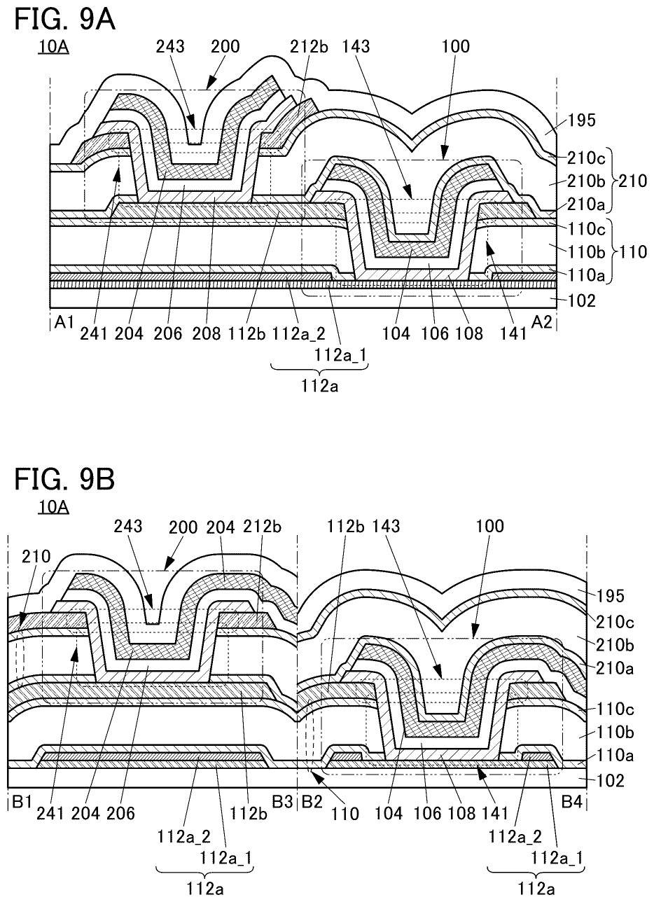

FIG. 1A can be referred to for a top view of a semiconductor device 10A. FIG. 9A is a cross-sectional view of a cross section along the dashed-dotted line A1-A2 in FIG. 1A, and FIG. 9B is a cross-sectional view of cross sections along the dashed-dotted line B1-B2 and the dashed-dotted line B3-B4 in FIG. 1A. FIG. 1B can be referred to for an equivalent circuit diagram of the semiconductor device 10A.

The semiconductor device 10A is different from the semiconductor device 10 described in Structure example 1-1 shown above mainly in the structures of the insulating layer 106 and the insulating layer 206.

An end portion of the insulating layer 106 is aligned or substantially aligned with an end portion of the conductive layer 104. That is, the insulating layer 106 is processed to have substantially the same top surface shape as the conductive layer 104. The insulating layer 106 can be formed with use of a resist mask for processing the conductive layer 104, for example. Note that the end portion of the insulating layer 106 is not necessarily aligned with the end portion of the conductive layer 104. The end portion of the insulating layer 106 may be positioned outward from the end portion of the conductive layer 104, for example.

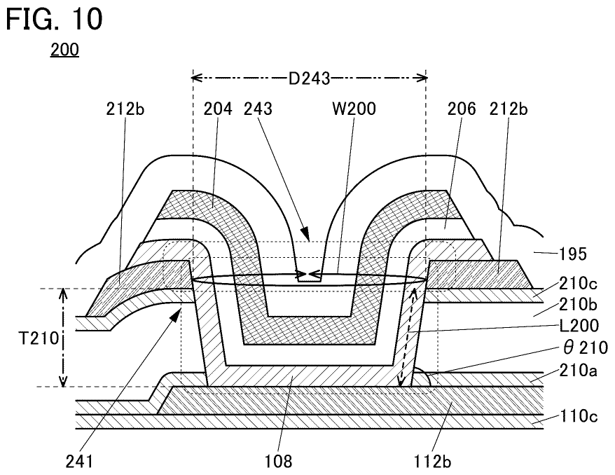

In the transistor 200, the semiconductor layer 208 is electrically connected to the conductive layer 112b through the opening 241 provided in the insulating layer 210. FIG. 10 is an enlarged view of the transistor 200. In FIG. 10, the channel length L200 of the transistor 200 is indicated by a dashed double-headed arrow. The channel length L200 of the transistor 200 corresponds to the length of the side surface of the insulating layer 210 on the opening 241 side in the cross-sectional view. In other words, the channel length L200 depends on the thickness T210 of the insulating layer 210 and an angle θ210 formed by the side surface of the insulating layer 210 on the opening 241 side and the formation surface of the insulating layer 210 (here, the top surface of the conductive layer 112b). In FIG. 10, the thickness T210 of the insulating layer 210 is indicated by a dashed-dotted double-headed arrow. By adjusting the thickness T210 and the angle θ210 of the insulating layer 210, the channel length L200 can be controlled.

Note that the structures of the insulating layer 106 and the insulating layer 206 described here can also be applied to other structure examples.

### Structure Example 1-3

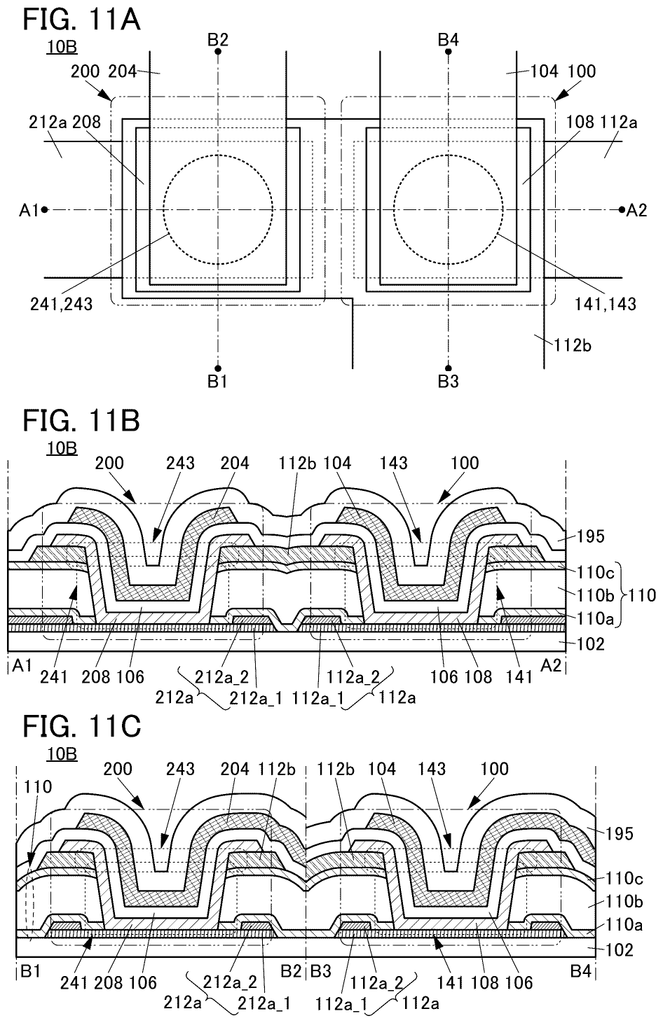

FIG. 11A is a top view of a semiconductor device 10B. FIG. 11B is a cross-sectional view of a cross section along the dashed-dotted line A1-A2 in FIG. 11A, and FIG. 11C is a cross-sectional view of cross sections along the dashed-dotted line B1-B2 and the dashed-dotted line B3-B4 in FIG. 11A. FIG. 1B can be referred to for an equivalent circuit diagram of the semiconductor device 10B.

The semiconductor device 10B is different from the semiconductor device 10 described in Structure example 1-1 shown above mainly in that the transistor 100 and the transistor 200 are formed on the same plane.

The transistor 100 and the transistor 200 are provided over the substrate 102. The transistor 100 and the transistor 200 can be formed in the same step.

The description of the transistor 100 in Structure example 1-1 shown above can be referred to for the transistor 100; thus, the detailed description thereof is omitted.

The transistor 200 includes the conductive layer 204, the insulating layer 106, the semiconductor layer 208, the conductive layer 112b, and a conductive layer 212a. The conductive layer 204 functions as the gate electrode. Part of the insulating layer 106 functions as the gate insulating layer. The conductive layer 112b functions as one of the source electrode and the drain electrode, and the conductive layer 212a functions as the other.

The conductive layer 204 can be formed in the same step as the conductive layer 104 included in the transistor 100. The semiconductor layer 208 can be formed in the same step as the semiconductor layer 108 included in the transistor 100. The conductive layer 212a can be formed in the same step as the conductive layer 112a included in the transistor 100. The conductive layer 112b is shared by the transistor 100 and the transistor 200.

As illustrated in FIG. 11B and FIG. 11C, a structure can be employed in which the conductive layer 112a_2 has an opening and the semiconductor layer 108 is in contact with the conductive layer 112a_1 through the opening. The conductive layer 212a preferably has a stacked-layer structure of a conductive layer 212a_1 and a conductive layer 212a_2 over the conductive layer 212a_1. A structure can be employed in which the conductive layer 212a_2 has an opening and the semiconductor layer 208 is in contact with the conductive layer 212a_1 through the opening.

In the insulating layer 110, the opening 141 is provided in a region overlapping with the conductive layer 112a, and the opening 241 is provided in a region overlapping with the conductive layer 212a. The opening 141 and the opening 241 can be formed in the same step. In the conductive layer 112b, the opening 143 is provided in a region overlapping with the opening 141, and the opening 243 is provided in a region overlapping with the opening 241. The opening 143 and the opening 243 can be formed in the same step.

The top surface shapes of the opening 143 and the opening 243 are preferably circular. Furthermore, the width D143 of the opening 143 is preferably equal to or substantially equal to the width D243 of the opening 243. When the opening 143 and the opening 243 have the same top surface shapes and the widths of the openings are the same or substantially the same, the processing accuracy at the time of forming the opening 143 and the opening 243 can be increased. One or both of a top surface shape and a width may be different between the opening 143 and the opening 243.

Note that in this specification and the like, the widths are substantially the same means that one of two compared widths is greater than or equal to 0.8 and less than or equal to 1.2 with respect to the other.

Note that the structures of the transistor 100 and the transistor 200 described here can also be applied to other structure examples.

### Structure Example 1-4

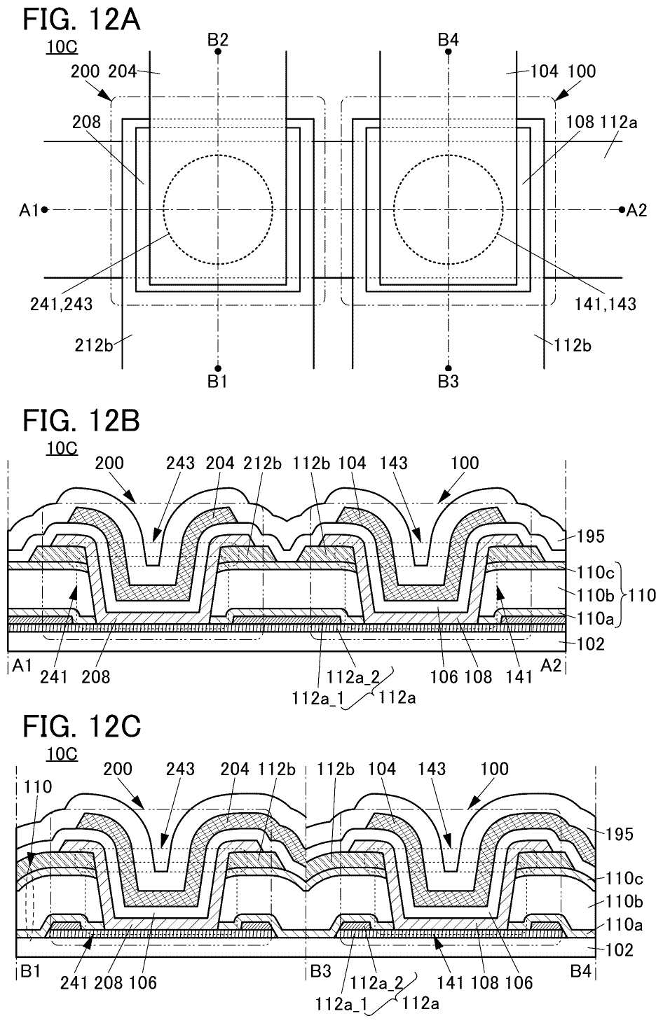

FIG. 12A is a top view of a semiconductor device 10C. FIG. 12B is a cross-sectional view of a cross section along the dashed-dotted line A1-A2 in FIG. 12A, and FIG. 12C is a cross-sectional view of cross sections along the dashed-dotted line B1-B2 and the dashed-dotted line B3-B4 in FIG. 12A. FIG. 1B can be referred to for an equivalent circuit diagram of the semiconductor device 10C.

The semiconductor device 10C is different from the semiconductor device 10B described in Structure example 1-3 shown above mainly in that the transistor 100 and the transistor 200 share the conductive layer 112a.

The description of the transistor 100 in Structure example 1-1 shown above can be referred to for the transistor 100; thus, the detailed description thereof is omitted.

The transistor 200 includes the conductive layer 204, the insulating layer 106, the semiconductor layer 208, the conductive layer 112a, and the conductive layer 212b. The conductive layer 112a functions as one of the source electrode and the drain electrode, and the conductive layer 212b functions as the other. The conductive layer 212b can be formed in the same step as the conductive layer 112b included in the transistor 100.

The structure of the conductive layer 112a described here can be applied to other structure examples.

### Structure Example 2

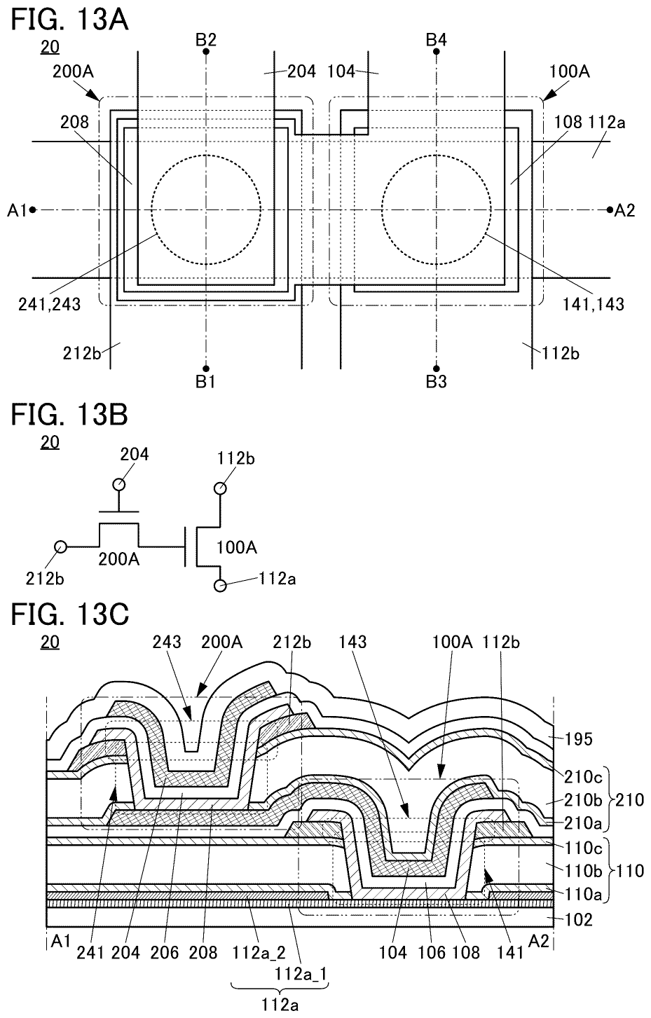

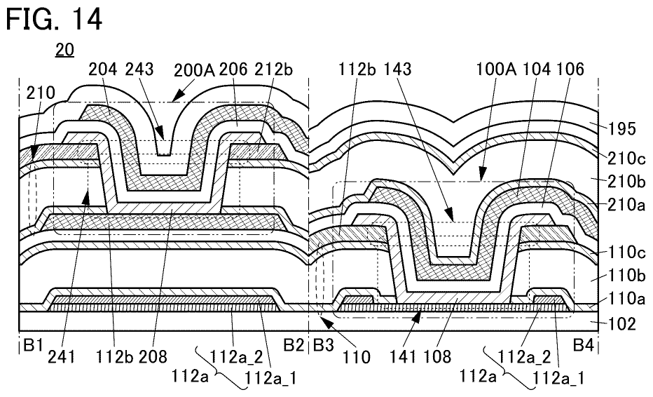

FIG. 13A is a top view of a semiconductor device 20 of one embodiment of the present invention. FIG. 13B is an equivalent circuit diagram of the semiconductor device 20. FIG. 13C is a cross-sectional view of a cross section along the dashed-dotted line A1-A2 in FIG. 13A, and FIG. 14 is a cross-sectional view of cross sections along the dashed-dotted line B1-B2 and the dashed-dotted line B3-B4 in FIG. 13A.

The semiconductor device 20 includes a transistor 100A and a transistor 200A. A gate electrode of the transistor 100A is electrically connected to one of a source electrode and a drain electrode of the transistor 200A.

Although the transistor 100A and the transistor 200A are shown as n-channel transistors in FIG. 13B, one embodiment of the present invention is not limited thereto. One or both of the transistor 100A and the transistor 200A may be a p-channel transistor(s).

For the transistor 100A, the above description of the transistor 100 can be referred to.

The transistor 200A includes the conductive layer 204, the insulating layer 206, the semiconductor layer 208, the conductive layer 104, and the conductive layer 212b. The conductive layer 204 functions as a gate electrode. Part of the insulating layer 206 functions as a gate insulating layer. The conductive layer 104 functions as one of the source electrode and the drain electrode, and the conductive layer 212b functions as the other.

The conductive layer 104 functions as the gate electrode of the transistor 100A and also functions as one of the source electrode and the drain electrode of the transistor 200A. The transistor 100A and the transistor 200A share the conductive layer 104, whereby the area occupied by the circuit can be reduced and thus a small semiconductor device can be provided.

The insulating layer 210 is provided over the conductive layer 104, and the conductive layer 212b is provided over the insulating layer 210. The insulating layer 210 includes a region interposed between the conductive layer 104 and the conductive layer 212b. The conductive layer 104 includes a region overlapping with the conductive layer 212b with the insulating layer 210 therebetween. The insulating layer 210 has an opening 241 in a region overlapping with the conductive layer 104. The conductive layer 104 is exposed in the opening 241.

Note that the conductive layer 104 may have a stacked-layer structure. The structure of the conductive layer 112a illustrated in FIG. 1C and the like can be employed for the conductive layer 104. For example, the conductive layer 104 has a stacked-layer structure of a first conductive layer and a second conductive layer over the first conductive layer, and an opening is provided in a region in contact with the semiconductor layer 208 of the second conductive layer. A material that is less likely to be oxidized is used for the first conductive layer and a material with low electrical resistivity is used for the second conductive layer. This can inhibit an increase in the resistance of the conductive layer 104. Furthermore, the amount of oxygen vacancy (V_{O}) and V_{O}H in the semiconductor layer 208 can be reduced, whereby the transistor 200A can have favorable electric characteristics and high reliability.

Note that the structures of the transistor 100A and the transistor 200A described here can also be applied to other structure examples.

### Structure Example 3

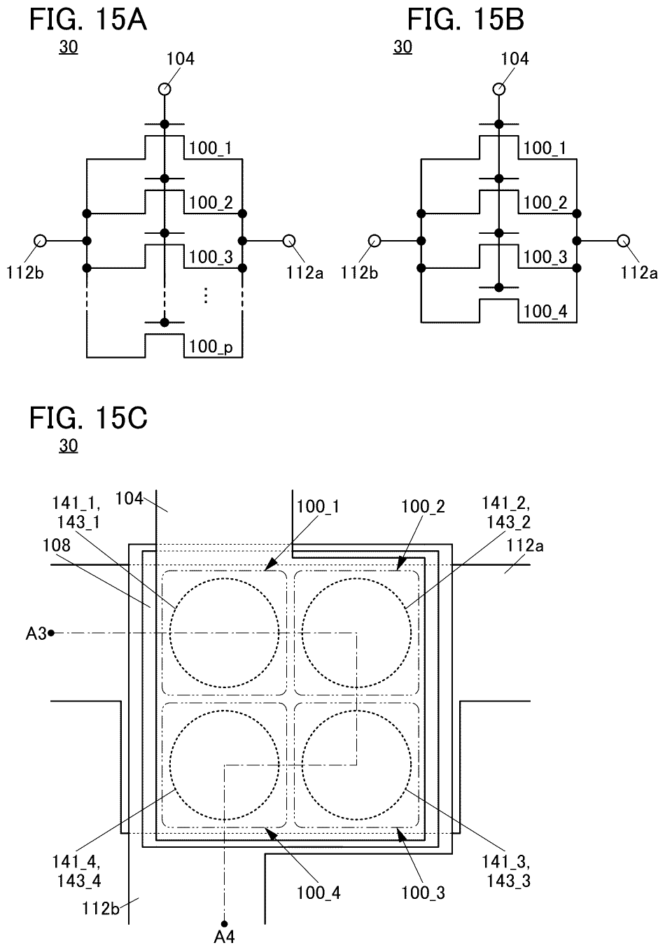

FIG. 15A is an equivalent circuit diagram of a semiconductor device 30 of one embodiment of the present invention. The semiconductor device 30 includes a transistor 100_1 to a transistor 100_p (p is an integer greater than or equal to 2). The semiconductor device 30 can be regarded as one transistor, in which the transistor 100_1 to the transistor 100_p are connected in parallel.

Gate electrodes of the transistor 100_1 to the transistor 100_p are electrically connected to each other. Source electrodes of the transistor 100_1 to the transistor 100_p are electrically connected to each other. Drain electrodes of the transistor 100_1 to the transistor 100_p are electrically connected to each other.

Although the transistor 100_1 to the transistor 100_p are shown as n-channel transistors in FIG. 15A, one embodiment of the present invention is not limited thereto. The transistor 100_1 to the transistor 100_p may be p-channel transistors.

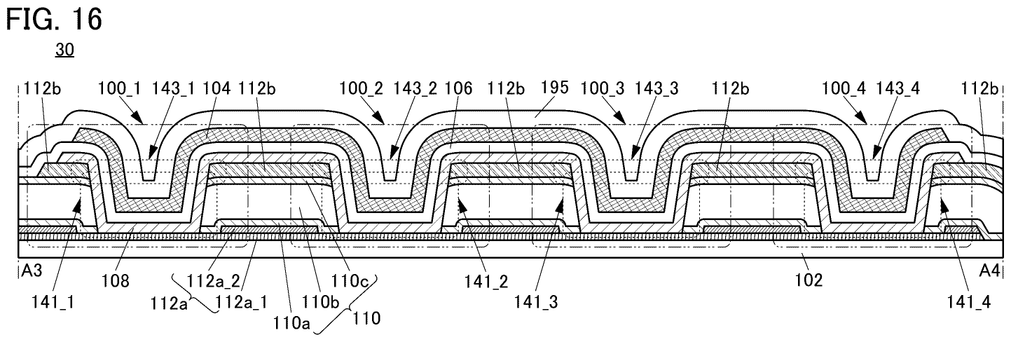

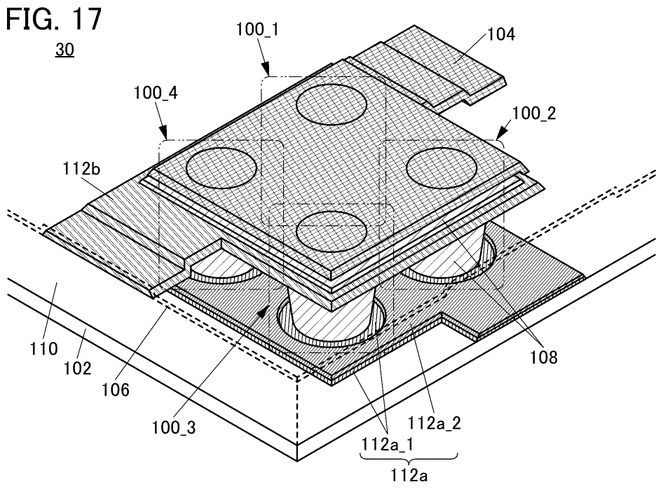

The case where p is 4 is specifically described as an example. FIG. 15B is an equivalent circuit diagram of the semiconductor device 30 of one embodiment of the present invention. FIG. 15C is a top view of the semiconductor device 30. FIG. 16 is a cross-sectional view of a cross section along the dashed-dotted line A3-A4 in FIG. 15C. FIG. 17 is a perspective view of the semiconductor device 30.

The semiconductor device 30 includes the transistor 100_1 to a transistor 100_4. The transistor 100_1 to the transistor 100_4 can each employ the above-described structure of the transistor 100.

Although the top view illustrated in FIG. 15C and the perspective view illustrated FIG. 17 each illustrate the structure in which the transistor 100_1 to the transistor 100_4 are arranged in two rows and two columns, one embodiment of the present invention is not limited thereto. For example, the transistor 100_1 to the transistor 100_4 may be arranged in one row and four columns.

The transistor 100_1 to the transistor 100_4 each include the conductive layer 104, the insulating layer 106, the semiconductor layer 108, the conductive layer 112a, and the conductive layer 112b. The conductive layer 104 functions as a gate electrode of each of the transistor 100_1 to the transistor 100_4. Part of the insulating layer 106 functions as a gate insulating layer of each of the transistor 100_1 to the transistor 100_4. The conductive layer 112a functions as the other of a source electrode and a drain electrode, and the conductive layer 112b functions as one thereof in each of the transistor 100_1 to the transistor 100_4.

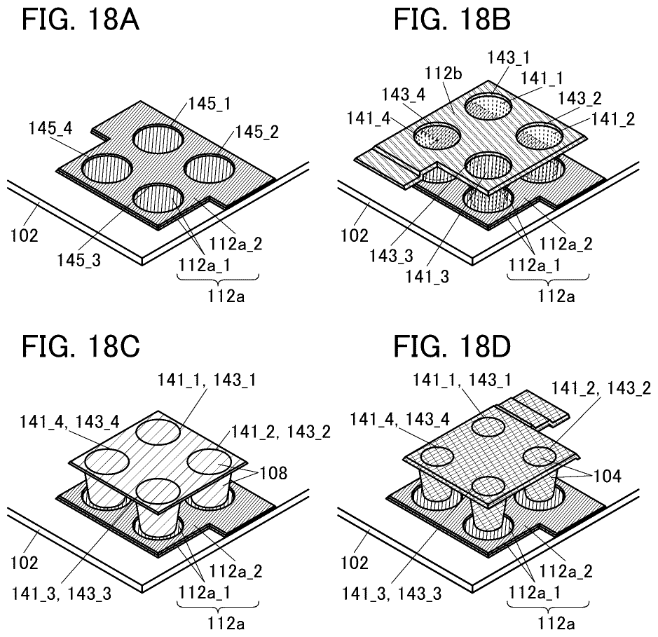

FIG. 18A is a perspective view selectively illustrating the conductive layer 112a. The conductive layer 112a has an opening 145_1 to an opening 145_4 in regions in contact with the semiconductor layer 108. The conductive layer 112a_1 is exposed in the opening 145_1 to the opening 145_4.

FIG. 18B is a perspective view selectively illustrating the conductive layer 112a, the conductive layer 112b, an opening 141_1 to the opening 141_1, and an opening 143_1 to an opening 143_4. Note that the opening 141_1 to an opening 141_4 provided in the insulating layer 110 are indicated by dashed lines. The opening 141_1 to the opening 141_4 are preferably provided in regions overlapping with the opening 145_1 to the opening 145_4. The conductive layer 112a_1 is preferably exposed in the opening 141_1 to the opening 141_4. As illustrated in FIG. 18B, the conductive layer 112b has the opening 143_1 to the opening 143_4 in regions overlapping with the conductive layer 112a.

The top surface shapes of the opening 141_1 to the opening 141_4 and the opening 143_1 to the opening 143_4 are preferably circular. Furthermore, the widths of the opening 141_1 to the opening 141_4 are preferably equal to or substantially equal to each other. Similarly, the widths of the opening 143_1 to the opening 143_4 are preferably equal to or substantially equal to each other. When the widths of the opening 141_1 to the opening 141_4 are equal to or substantially equal to each other and the widths of the opening 143_1 to the opening 143_4 are equal to or substantially equal to each other, the processing accuracy at the time of forming the opening 141_1 to the opening 141_4 and the opening 143_1 to the opening 143_4 can be increased.

In the case where the semiconductor device 30 is regarded as one transistor, the channel width of the transistor is the sum of the channel widths of the transistor 100_1 to the transistor 100_4. For example, in the case where the top-view shapes of the opening 143_1 to the opening 143_4 are circular and the width D143 corresponds to the width of each of the opening 143_1 to the opening 143_4, the semiconductor device 30 can be regarded as a transistor having a channel width of “D143×π×4” (see FIG. 5A and FIG. 5B). The semiconductor device 30 composed of p transistors can be regarded as a transistor having a channel width of “D143×π×p”. Note that the semiconductor device 30 can be regarded as a transistor having the channel length L100 (see FIG. 5B). A plurality of transistors connected in parallel can have a larger channel width and a higher on-state current. By adjusting the number (p) of transistors connected in parallel, the channel width can be changed. The number (p) of transistors connected in parallel is determined so that a desired on-state current is obtained.

FIG. 18C is a perspective view selectively illustrating the conductive layer 112a and the semiconductor layer 108. As illustrated in FIG. 18C, the semiconductor layer 108 is provided to cover the opening 141_1 to the opening 141_4 and the opening 143_1 to the opening 143_4. The semiconductor layer 108 includes regions in contact with the top surface of the conductive layer 112a in the opening 141_1 to the opening 141_4. Specifically, the semiconductor layer 108 preferably includes regions in contact with the top surface of the conductive layer 112a_1 in the opening 141_1 to the opening 141_4. Although FIG. 18C illustrates the structure in which the transistor 100_1 to the transistor 100_4 share the semiconductor layer 108, one embodiment of the present invention is not limited thereto. The semiconductor layer 108 may be divided for each of the transistor 100_1 to the transistor 100_4.

Although FIG. 18A and the like illustrate the structures in which the conductive layer 112a includes four openings 145 (the opening 145_1 to the opening 145_4), one embodiment of the present invention is not limited thereto. The conductive layer 112a may include one or more openings covering the opening 141_1 to the opening 141_4 completely. For example, the conductive layer 112a can include one opening covering the opening 141_1 to the opening 141_4 completely. In the opening, the semiconductor layers 108 of the transistor 100_1 to the transistor 100_4 may be in contact with the conductive layer 112a_1.

FIG. 18D is a perspective view selectively illustrating the conductive layer 112a and the conductive layer 104. As illustrated in FIG. 18D, the conductive layer 104 is provided to cover the opening 141_1 to the opening 141_4 and the opening 143_1 to the opening 143_4.

The semiconductor device 30 may be used as one or both of the transistor 100 and the transistor 200 included in the semiconductor device 10 illustrated in FIG. 1B and the like. Specifically, any of the transistor 100_1 to the transistor 100_p illustrated in FIG. 15A can be used as the transistor 100 included in the semiconductor device 10. Any of the transistor 100_1 to the transistor 100_p illustrated in FIG. 15A can be used as the transistor 200.

The semiconductor device 30 may be used as one or both of the transistor 100A and the transistor 200A included in the semiconductor device 20 illustrated in FIG. 13B and the like. Specifically, any of the transistor 100_1 to the transistor 100_p illustrated in FIG. 15A can be used as the transistor 100A included in the semiconductor device 20. Any of the transistor 100_1 to the transistor 100_p illustrated in FIG. 15A can be used as the transistor 200A.

Note that the parallel connection structure described here can also be applied to other structure examples.

### Structure Example 4

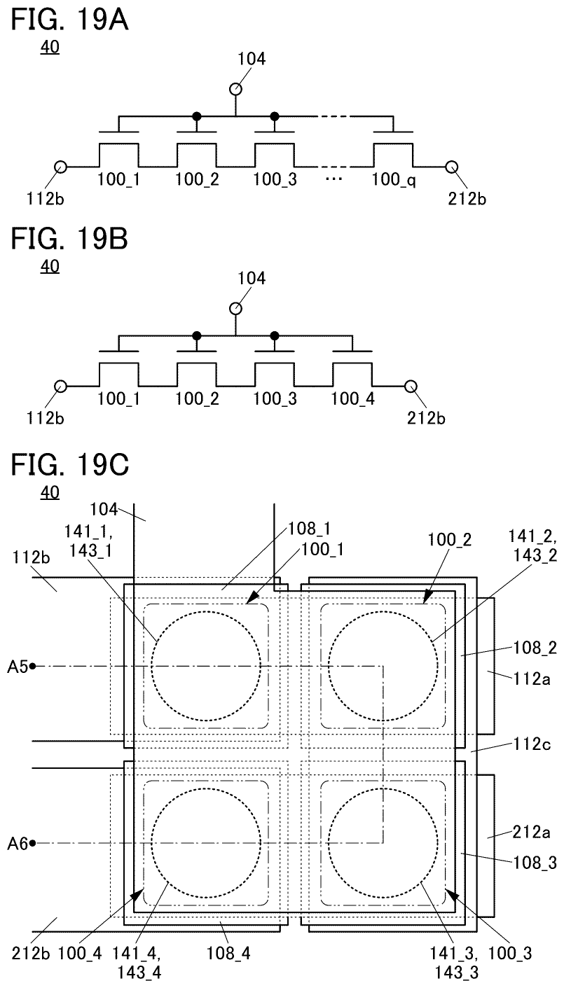

FIG. 19A is an equivalent circuit diagram of a semiconductor device 40 of one embodiment of the present invention. The semiconductor device 40 includes the transistor 100_1 to a transistor 100_q (q is an integer greater than or equal to 2). The semiconductor device 40 can be regarded as one transistor, in which the transistor 100_1 to the transistor 100_q are connected in series.

Although the transistor 100_1 to the transistor 100_q are shown as n-channel transistors in FIG. 19A, one embodiment of the present invention is not limited thereto. The transistor 100_1 to the transistor 100_q may be p-channel transistors.

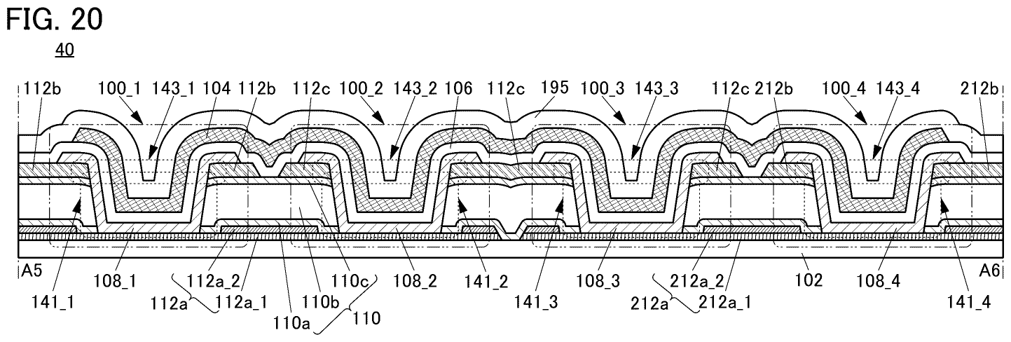

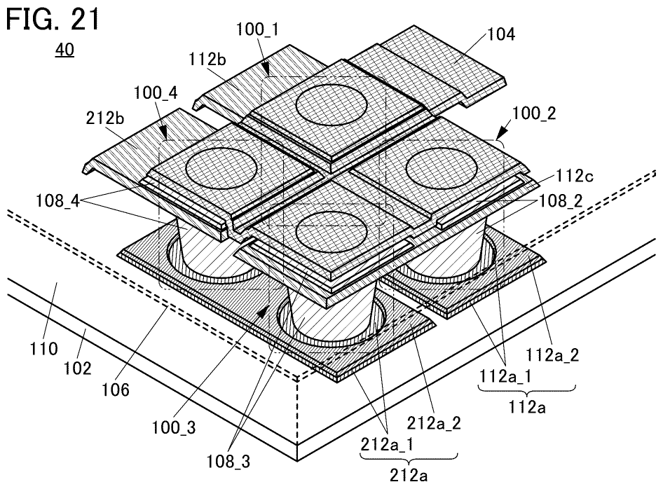

The case where q is 4 is specifically described as an example. FIG. 19B is an equivalent circuit diagram of the semiconductor device 40 of one embodiment of the present invention. FIG. 19C is a top view of the semiconductor device 40. FIG. 20 is a cross-sectional view of a cross section along the dashed-dotted line A5-A6 in FIG. 19C. FIG. 21 is a perspective view of the semiconductor device 40.

The semiconductor device 40 includes the transistor 100_1 to the transistor 100_4. The transistor 100_1 to the transistor 100_4 can each employ the above-described structure of the transistor 100.

Although the top view illustrated in FIG. 19C and the perspective view illustrated FIG. 21 each illustrate the structure in which the transistor 100_1 to the transistor 100_4 are arranged in two rows and two columns, one embodiment of the present invention is not limited thereto. For example, the transistor 100_1 to the transistor 100_4 may be arranged in one row and four columns.

The transistor 100_1 includes the conductive layer 104, the insulating layer 106, a semiconductor layer 108_1, the conductive layer 112a, and the conductive layer 112b. The conductive layer 112a functions as one of the source electrode and the drain electrode and the conductive layer 112b functions as the other thereof in the transistor 100_1.

The transistor 100_2 includes the conductive layer 104, the insulating layer 106, a semiconductor layer 108_2, the conductive layer 112a, and a conductive layer 112c. The conductive layer 112a functions as one of the source electrode and the drain electrode and the conductive layer 112c functions as the other thereof in the transistor 100_2. The conductive layer 112a is shared by the transistor 100_1 and the transistor 100_2.

The transistor 100_3 includes the conductive layer 104, the insulating layer 106, a semiconductor layer 108_3, the conductive layer 212a, and the conductive layer 112c. The conductive layer 212a functions as one of the source electrode and the drain electrode and the conductive layer 112c functions as the other thereof in the transistor 100_3. The conductive layer 112c is shared by the transistor 100_2 and the transistor 100_3.

The transistor 100_4 includes the conductive layer 104, the insulating layer 106, a semiconductor layer 108_4, the conductive layer 212a, and the conductive layer 212b. The conductive layer 212a functions as one of the source electrode and the drain electrode and the conductive layer 212b functions as the other thereof in the transistor 100_4. The conductive layer 212a is shared by the transistor 100_3 and the transistor 100_4.

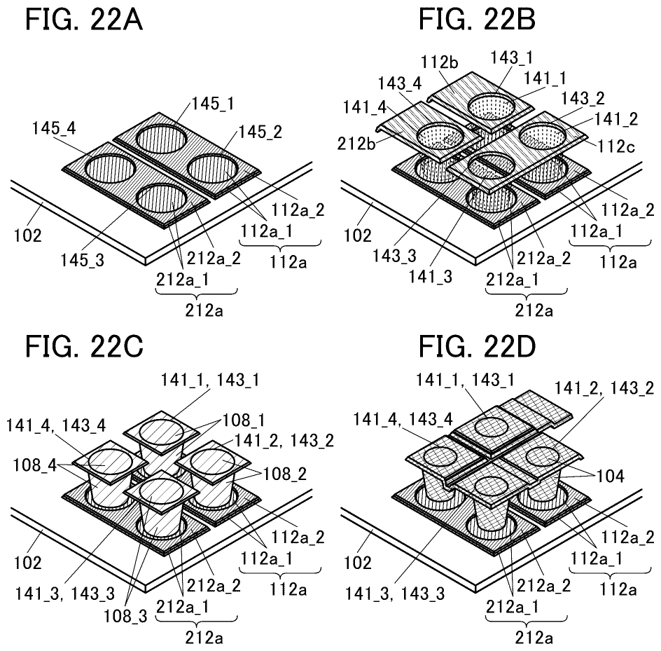

FIG. 22A is a perspective view selectively illustrating the conductive layer 112a and the conductive layer 212a. The conductive layer 112a and the conductive layer 212a can be formed in the same step. A structure can be employed in which the conductive layer 112a_2 has the opening 145_1 and the opening 145_2 and the semiconductor layer 108_1 and the semiconductor layer 108_2 are in contact with the conductive layer 112a_1 through the opening 145_1 and the opening 145_2. A structure can be employed in which the conductive layer 212a_2 has the opening 145_3 and the opening 145_4 and the semiconductor layer 108_3 and the semiconductor layer 108_4 are in contact with the conductive layer 212a_1 through the opening 145_3 and the opening 145_4.

FIG. 22B is a perspective view selectively illustrating the conductive layer 112a, the conductive layer 212a, the conductive layer 112b, the conductive layer 112c, the conductive layer 212b, the opening 141_1 to the opening 141_4, and the opening 143_1 to the opening 143_4. The conductive layer 112b, the conductive layer 112c, and the conductive layer 212b can be formed in the same step. The opening 143_1 is provided in the conductive layer 112b, the opening 143_2 and the opening 143_3 are provided in the conductive layer 112c, and the opening 143_4 is provided in the conductive layer 212b.

FIG. 22C is a perspective view selectively illustrating the conductive layer 112a, the conductive layer 212a, and the semiconductor layer 108_1 to the semiconductor layer 108_4. The semiconductor layer 108_1 to the semiconductor layer 108_4 can be formed in the same step.

FIG. 22D is a perspective view selectively illustrating the conductive layer 112a, the conductive layer 212a, and the conductive layer 104. The conductive layer 104 functions as the gate electrode of each of the transistor 100_1 to the transistor 100_4.

One of the source electrode and the drain electrode of the transistor 100_1 is electrically connected to one of the source electrode and the drain electrode of the transistor 100_2. The other of the source electrode and the drain electrode of the transistor 100_2 is electrically connected to the other of the source electrode and the drain electrode of the transistor 100_3. One of the source electrode and the drain electrode of the transistor 100_3 is electrically connected to one of the source electrode and the drain electrode of the transistor 100_4.

In the case where the semiconductor device 40 is regarded as one transistor, the channel width of the transistor is the sum of the channel lengths of the transistor 100_1 to the transistor 100_4. For example, in the case where the channel length L100 corresponds to the channel length of each of the transistor 100_1 to the transistor 100_4, the semiconductor device 40 can be regarded as a transistor having a channel length of “L100×4” (see FIG. 5B). The semiconductor device 40 composed of q transistors can be regarded as a transistor having a channel length of “L100×q”. Note that the semiconductor device 40 can be regarded as a transistor having the channel width W100 (see FIG. 5A and FIG. 5B). A plurality of transistors connected in series can have a larger channel length and favorable saturation. By adjusting the number (q) of transistors connected in series, the channel length can be changed. The number (q) of transistors connected in series is determined so that desired saturation is obtained.

The semiconductor device 40 may be used as one or both of the transistor 100 and the transistor 200 included in the semiconductor device 10 illustrated in FIG. 1B and the like. Specifically, any of the transistor 100_1 to the transistor 100_q illustrated in FIG. 19A can be used as the transistor 100 included in the semiconductor device 10. Any of the transistor 100_1 to the transistor 100_q illustrated in FIG. 19A can be used as the transistor 200.

The semiconductor device 40 may be used as one or both of the transistor 100A and the transistor 200A included in the semiconductor device 20 illustrated in FIG. 13B and the like. Specifically, any of the transistor 100_1 to the transistor 100_q illustrated in FIG. 19A can be used as the transistor 100A included in the semiconductor device 20. Any of the transistor 100_1 to the transistor 100_q illustrated in FIG. 19A can be used as the transistor 200A.

The semiconductor device 40 may be used as each of the transistors included in the semiconductor device 30. That is, the groups of transistors connected in parallel can further be connected in series (hereinafter also referred to as series-parallel connection).

Note that the structures of series connection and series-parallel connection described here can also be applied to other structure examples.

### Manufacturing Method Example

A method for manufacturing the semiconductor device of one embodiment of the present invention will be described below with reference to drawings. Here, a structure in which an oxide semiconductor is used for each of the semiconductor layer 108 and the semiconductor layer 208 of the semiconductor device 10 illustrated in FIG. 1C and the like is described as an example.

Note that thin films that form the semiconductor device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method. An example of the thermal CVD method is a metal organic chemical vapor deposition (MOCVD: Metal Organic CVD) method.

The thin films that form the semiconductor device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that form the semiconductor device are processed, a photolithography method or the like can be used. Alternatively, a nanoimprinting method, a sandblasting method, a lift-off method, or the like may be used for the processing of the thin films. Island-shaped thin films may be directly formed by a film formation method using a blocking mask such as a metal mask.

There are the following two typical examples of a photolithography method. In one of the methods, a resist mask is formed over a thin film that is to be processed, the thin film is processed by etching or the like, and the resist mask is removed. In the other method, a photosensitive thin film is formed and then the thin film is processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. In addition, light exposure may be performed by liquid immersion exposure technique. As the light used for the light exposure, extreme ultraviolet (EUV) light, X-rays, or the like may be used. Instead of the light used for light exposure, an electron beam can be used. It is preferable to use extreme ultraviolet light, X-rays, or an electron beam because extremely minute processing can be performed. Note that in the case of performing light exposure by scanning of a beam such as an electron beam, a photomask is not needed.

For etching of the thin film, a dry etching method, a wet etching method, or a sandblasting method can be used, for example.

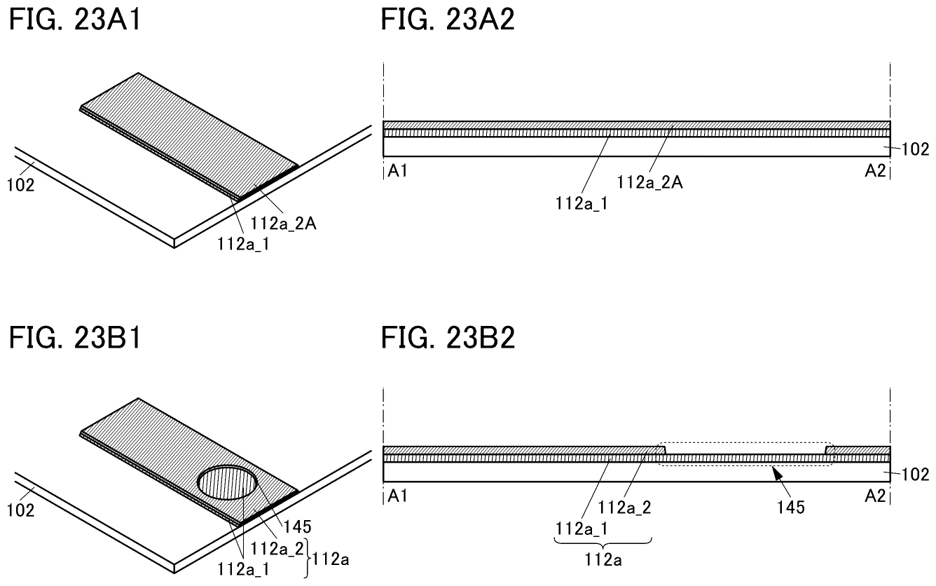

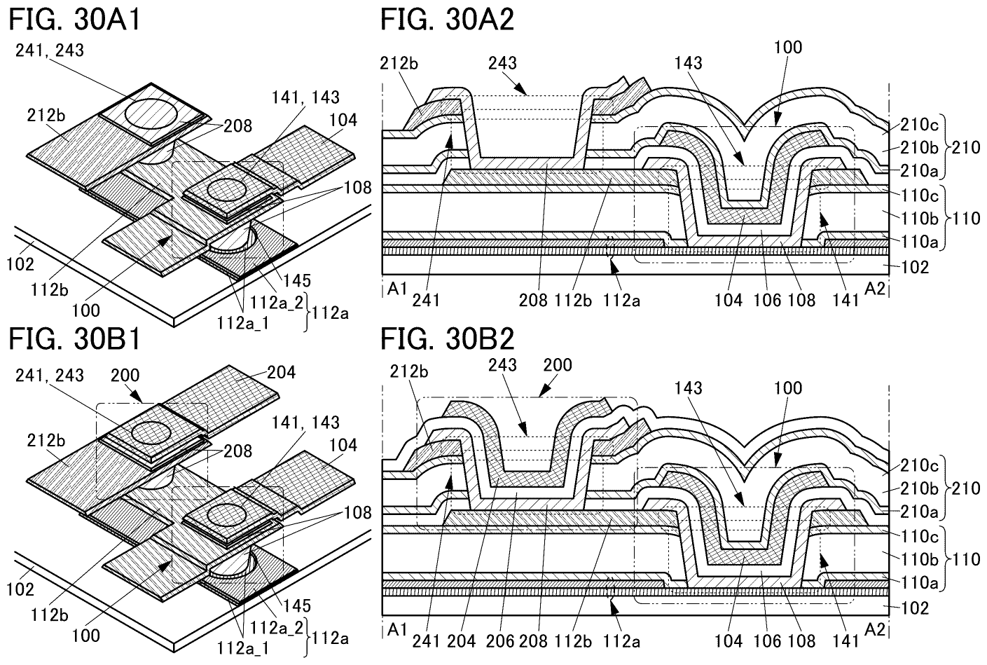

FIG. 23A1 to FIG. 30B2 are drawings illustrating a method for manufacturing the transistor 100A. In each drawing, A1 and B1 are perspective views, and A2 and B2 are a cross-sectional view of a cross section along the dashed-dotted line A1-A2 and a cross-sectional view of a cross section along the dashed-dotted line B1-B2, respectively. In A1 and B1 of each drawing, the insulating layer 110, the insulating layer 106, the insulating layer 210, and the insulating layer 206 are not illustrated.

[Formation of Conductive Layer 112a]

A conductive film to be the conductive layer 112a_1 and the conductive layer 112a_2 is formed over the substrate 102. For the formation of the conductive film, a sputtering method can be suitably used, for example. After a resist mask is formed over the conductive film in a photolithography process, the conductive film is processed, whereby the conductive layer 112a_1 and a conductive layer 112a_2A are formed (FIG. 23A1 and FIG. 23A2). For the processing of the conductive film, one or both of a wet etching method and a dry etching method are used.

Subsequently, after a resist mask is formed over the conductive layer 112a_2A in a photolithography process, the conductive layer 112a_2A is processed, whereby the conductive layer 112a_2 having the opening 145 is formed (FIG. 23B1 and FIG. 23B2). Accordingly, the conductive layer 112a functioning as one of the source electrode and the drain electrode of the transistor 100 is formed.

[Formation of Insulating Film 110af and Insulating Film 110bf]

Next, an insulating film 110af to be the insulating layer 110a and an insulating film 110bf to be the insulating layer 110b are formed over the substrate 102 and the conductive layer 112a.

For the formation of the insulating film 110af and the insulating film 110bf, a PECVD method can suitably used. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating layer 110af can be inhibited. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, impurities (e.g., water and hydrogen) released from the insulating films themselves can be reduced, which inhibits diffusion of the impurities to the semiconductor layer 108. Consequently, the transistor can have favorable electrical characteristics and high reliability.

Note that since the insulating film 110af and the insulating film 110bf are formed earlier than the semiconductor layer 108, there is no need to consider the probability of oxygen release from the semiconductor layer 108 due to heat applied thereto at the time of forming the insulating film 110af and the insulating film 110bf.

After the insulating film 110af and the insulating film 110bf are formed, heat treatment may be performed. By performing the heat treatment, water and hydrogen can be released from the surface and inside of each of the insulating film 110af and the insulating film 110bf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven or a rapid thermal annealing (RTA) apparatus can be used for the heat treatment, for example. The use of the RTA apparatus can shorten the heat treatment time.

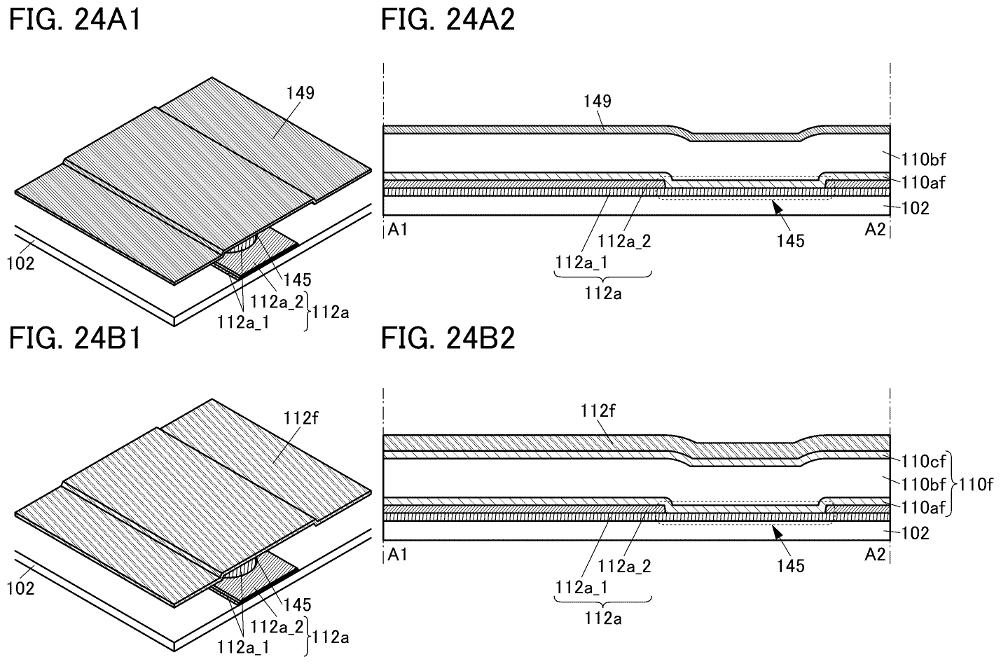

Next, a metal oxide layer 149 is formed over the insulating film 110bf (FIG. 24A1 and FIG. 24A2).

The metal oxide layer 149 is an insulating layer or a conductive layer. For the metal oxide layer 149, aluminum oxide, hafnium oxide, hafnium aluminate, indium oxide, indium tin oxide (ITO), or indium tin oxide containing silicon (ITSO) can be used, for example.

An oxide material containing one or more kinds of elements that are the same as those in the semiconductor layer 108 or the semiconductor layer 208 is preferably used for the metal oxide layer 149. It is particularly preferable to use an oxide semiconductor material that can be used for the semiconductor layer 108 or the semiconductor layer 208.

A metal oxide film formed using a sputtering target having the same composition as the semiconductor layer 108 or the semiconductor layer 208 can be used as the metal oxide layer 149. The sputtering target having the same composition as the semiconductor layer 108 or the semiconductor layer 208 is preferably used, in which case the same manufacturing apparatus and the same sputtering target can be used.

When a metal oxide material containing indium and gallium is used for each of the semiconductor layer 108 and the metal oxide layer 149, a material whose composition (content percentage) of gallium is higher than that in the semiconductor layer 108 can be used for the metal oxide layer 149. It is preferable to use a material whose composition (content percentage) of gallium is high for the metal oxide layer 149, in which case an oxygen blocking property can be further increased.

The metal oxide layer 149 is preferably formed in an oxygen-containing atmosphere, for example. It is particularly preferable that the metal oxide layer 149 be formed by a sputtering method in an oxygen-containing atmosphere. In that case, oxygen can be suitably supplied to the insulating film 110bf at the time of forming the metal oxide layer 149.

For example, the metal oxide layer 149 may be formed by a reactive sputtering method with a metal target using oxygen as a film formation gas. When aluminum is used for the metal target, for example, an aluminum oxide film can be formed.

At the time of forming the metal oxide layer 149, the amount of oxygen supplied into the insulating film 110bf can be increased with a higher proportion of the flow rate of an oxygen gas to the total flow rate of the film formation gas introduced into a processing chamber of a film formation apparatus (a higher oxygen flow rate ratio) or with higher oxygen partial pressure in the processing chamber. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 149 is formed by a sputtering method in an oxygen-containing atmosphere in the above manner, oxygen can be supplied to the insulating film 110bf and release of oxygen from the insulating film 110bf can be prevented during the formation of the metal oxide layer 149. As a result, a large amount of oxygen can be enclosed in the insulating film 110bf. Moreover, a large amount of oxygen can be supplied to the semiconductor layer 108 by heat treatment performed later. As a result, the amount of oxygen vacancy (V_{O}) and V_{O}H in the semiconductor layer 108 can be reduced, so that a highly reliable transistor exhibiting favorable electrical characteristics can be obtained.

After the metal oxide layer 149 is formed, heat treatment may be performed. The above description can be referred to for the heat treatment; thus, the detailed description thereof is omitted. By the heat treatment performed after the formation of the metal oxide layer 149, oxygen can be effectively supplied from the metal oxide layer 149 to the insulating film 110bf.

After the formation of the metal oxide layer 149 or after the above-described heat treatment, oxygen may be further supplied to the insulating film 110bf through the metal oxide layer 149. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a plasma etching apparatus and a plasma ashing apparatus.

Then, the metal oxide layer 149 is removed.

There is no particular limitation on a method for removing the metal oxide layer 149, and a wet etching method can be suitably used. With use of a wet etching method, the insulating film 110bf can be inhibited from being etched during the removal of the metal oxide layer 149. This can inhibit a reduction in the thickness of the insulating film 110bf and the thickness of the insulating layer 110b can be uniform.

The treatment for supplying oxygen to the insulating film 110bf is not necessarily performed in the above-described manner. An oxygen radical, an oxygen atom, an oxygen atomic ion, an oxygen molecular ion, or the like is supplied to the insulating film 110bf by an ion doping method, an ion implantation method, plasma treatment, or the like. Alternatively, a film that inhibits oxygen release may be formed over the insulating film 110bf, and then oxygen may be supplied to the insulating film 110bf through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

[Formation of Insulating Film 110cf and Formation of Conductive Film 112f]

Next, an insulating film 110cf to be the insulating layer 110c is formed over the insulating film 110bf. The description of the formation of the insulating film 110af and the insulating film 110bf can be referred to for the formation of the insulating film 110cf; thus, the detailed description thereof is omitted.

Then, a conductive film 112f to be the conductive layer 112b is formed over the insulating film 110cf (FIG. 24B1 and FIG. 24B2). For the formation of the conductive film 112f, a sputtering method can be suitably used, for example.

### [Formation of Opening 141 and Formation of Opening 143]

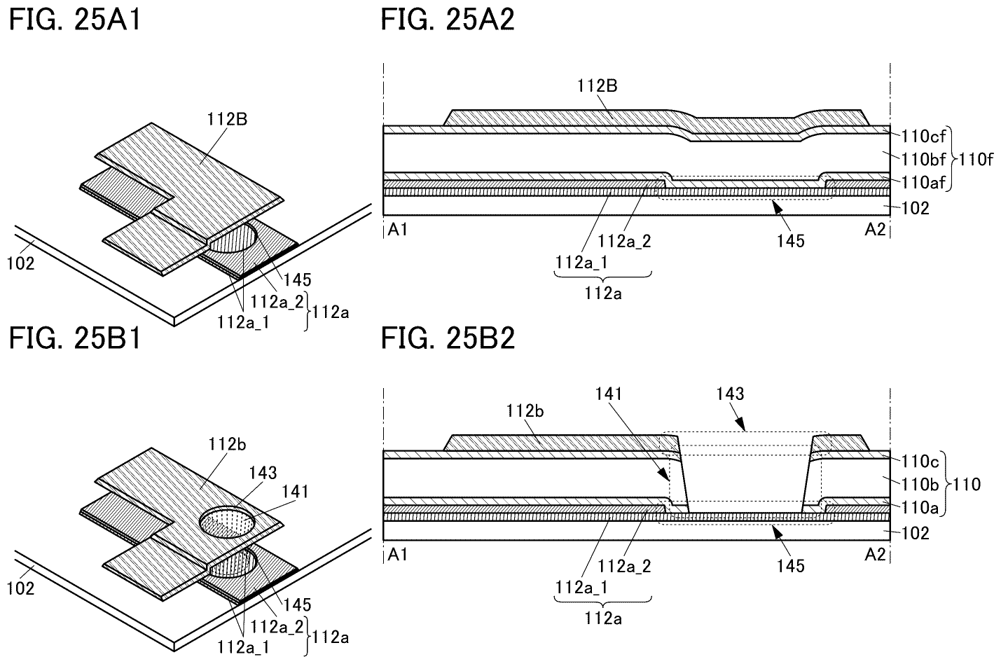

Next, the conductive film 112f is processed to form a conductive layer 112B (FIG. 25A1 and FIG. 25A2). For the formation of the conductive layer 112B, one or both of a wet etching method and a dry etching method can be used. For the formation of the conductive layer 112B, a wet etching method can be suitably used, for example.

Next, the conductive layer 112B in a region overlapping with the opening 145 is removed, whereby the conductive layer 112b having the opening 143 is formed. For the formation of the opening 143, one or both of a wet etching method and a dry etching method can be used. For the formation of the opening 143, a wet etching method can be suitably used, for example.

Next, the insulating film 110f (the insulating film 110af, the insulating film 110bf, and the insulating film 110cf) in a region overlapping with the opening 143 is removed, whereby the insulating layer 110 having the opening 141 is formed (FIG. 25B1 and FIG. 25B2). For the formation of the opening 141, one or both of a wet etching method and a dry etching method can be used. For the formation of the opening 141, a dry etching method can be suitably used, for example. Note that the opening 141 provided in the insulating layer 110 is indicated by dashed lines in FIG. 25B1. The opening 141 is provided in a region overlapping with the opening 145. The conductive layer 112a_1 is exposed in the opening 145.

The opening 141 can be formed using a resist mask used for the formation of the opening 143, for example. Specifically, a resist mask is formed over the conductive film 112f, the conductive film 112f is removed with use of the resist mask to form the opening 143, and the insulating film 110f is removed with use of the resist mask, whereby the opening 141 can be formed. The opening 143 may be formed using a resist mask that is different from the resist mask used for the formation of the opening 141.

Note that in the formation of the opening 141 or after the formation of the opening 141, part of the conductive layer 112a (specifically, the conductive layer 112a_1) in a region overlapping with the opening 141 may be removed. By removing part of the conductive layer 112a_1, the structure illustrated in FIG. 7A and FIG. 7B can be obtained.

### [Formation of Semiconductor Layer 108]

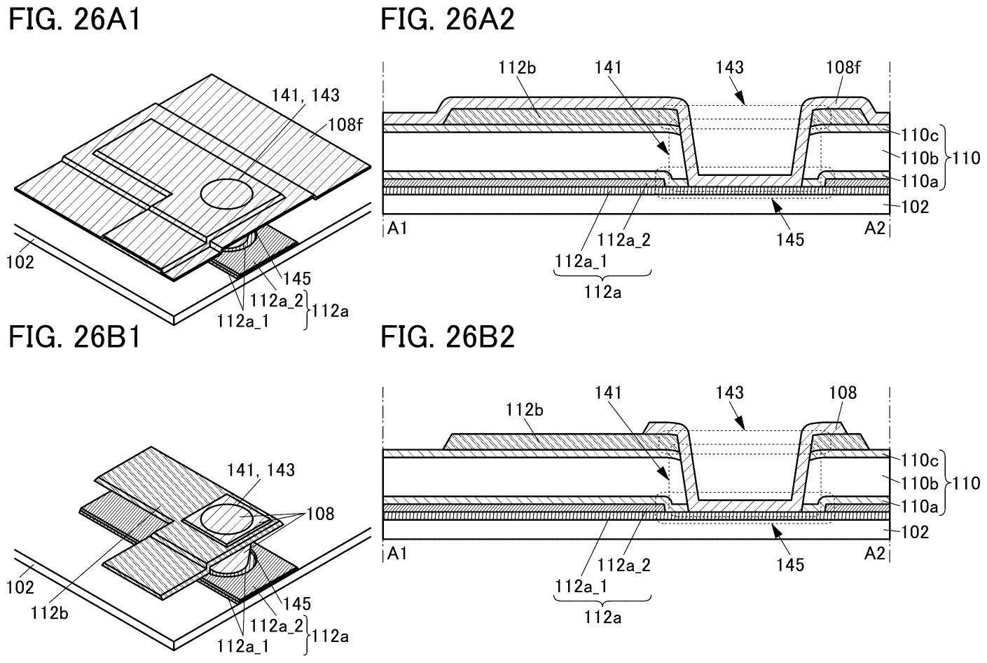

Subsequently, a metal oxide film 108f to be the semiconductor layer 108 is formed to cover the opening 141 and the opening 143 (FIG. 26A1 and FIG. 26A2). The metal oxide film 108f is provided in contact with the top surface and the side surface of the conductive layer 112b, the top surface and the side surface of the insulating layer 110, and the top surface of the conductive layer 112a_1.

The metal oxide film 108f is preferably formed by a sputtering method using a metal oxide target.

The metal oxide film 108f is preferably a dense film with as few defects as possible. The metal oxide film 108f is preferably a highly purified film in which impurities including a hydrogen element are reduced as much as possible. It is particularly preferable to use a metal oxide film having crystallinity as the metal oxide film 108f.

In forming the metal oxide film 108f, an oxygen gas is preferably used. In the case of using an oxygen gas at the time of forming the metal oxide film 108f, oxygen can be suitably supplied into the insulating layer 110. For example, in the case of using an oxide or an oxynitride for the insulating layer 110b, oxygen can be suitably supplied into the insulating layer 110b.

By the supply of oxygen to the insulating layer 110b, oxygen is supplied to the semiconductor layer 108 in a later step, so that the amount of oxygen vacancy (V_{O}) and V_{O}H in the semiconductor layer 108 can be reduced.

In forming the metal oxide film 108f, an inert gas (e.g., a helium gas, an argon gas, or a xenon gas) may be mixed in addition to the oxygen gas. Note that when the oxygen flow rate ratio or the oxygen partial pressure at the time of forming the metal oxide film 108f is higher, the crystallinity of the metal oxide film 108f can be higher and a transistor with higher reliability can be obtained. On the other hand, when the oxygen flow rate ratio or the oxygen partial pressure is lower, the crystallinity of the metal oxide film 108f is lower and a transistor with a high on-state current can be obtained.

In forming the metal oxide film 108f, as the substrate temperature is higher, a denser metal oxide film having higher crystallinity can be formed. On the other hand, as the substrate temperature is lower, the metal oxide film 108f having lower crystallinity and higher electric conductivity can be formed.

The substrate temperature at the time of forming the metal oxide film 108f is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than or equal to 140° C., high productivity is achieved, which is preferable. Furthermore, when the metal oxide film 108f is formed with the substrate temperature set at room temperature or without heating the substrate, the crystallinity can be made low.

It is preferable to perform at least one of treatment for desorbing water, hydrogen, an organic substance, and the like adsorbed onto the surface of the insulating layer 110 and treatment for supplying oxygen into the insulating layer 110 before the formation of the metal oxide film 108f. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 110 by plasma treatment in an atmosphere containing an oxidizing gas such as dinitrogen monoxide (N₂O). Performing plasma treatment containing a dinitrogen monoxide gas can supply oxygen while suitably removing an organic substance on the surface of the insulating layer 110. It is preferable that the metal oxide film 108f be formed successively after such treatment, without exposure of the surface of the insulating layer 110 to the air.

Note that in the case where the semiconductor layer 108 has a stacked-layer structure, an upper metal oxide film is preferably formed successively after the formation of a lower metal oxide film without exposure of the surface of the lower metal oxide layer to the air.

Next, the metal oxide film 108f is processed into an island shape, so that the semiconductor layer 108 is formed (FIG. 26B1 and FIG. 26B2).

For the formation of the semiconductor layer 108, one or both of a wet etching method and a dry etching method can be used. For the formation of the semiconductor layer 108, a wet etching method can be suitably used, for example. At this time, part of the insulating layer 112b in a region not overlapping with the semiconductor layer 108 is etched and thinned in some cases. In a similar manner, part of the insulating layer 110 in a region overlapping with neither the semiconductor layer 108 nor the conductive layer 112b is etched and thinned in some cases. For example, in the insulating layer 110, the insulating layer 110c is removed by etching and the surface of the insulating layer 110b is exposed, in some cases. Note that in etching of the metal oxide film 108f, a reduction in the thickness of the insulating layer 110c can be inhibited when a material having high selectivity is used for the insulating layer 110c.

It is preferable that heat treatment be performed after the metal oxide film 108f is formed or the metal oxide film 108f is processed into the semiconductor layer 108. By the heat treatment, hydrogen or water contained in the metal oxide film 108f or the semiconductor layer 108 or adsorbed onto a surface of the metal oxide film 108f or the semiconductor layer 108 can be removed. Furthermore, the film quality of the metal oxide film 108f or the semiconductor layer 108 is improved (e.g., the number of defects is reduced or crystallinity is increased) by the heat treatment in some cases.

Oxygen can be supplied from the insulating layer 110b to the metal oxide film 108f or the semiconductor layer 108 by heat treatment. In this case, it is further preferable that the heat treatment be performed before the semiconductor film 108f is processed into the semiconductor layer 108. The above description can be referred to for the heat treatment; thus, the detailed description thereof is omitted.

Note that the heat treatment is not necessarily performed. The heat treatment in this step may be omitted, and heat treatment performed in a later step may also serve as the heat treatment in this step. In some cases, treatment at a high temperature in a later step (e.g., a film formation step) or the like can serve as the heat treatment in this step.

### [Formation of Insulating Layer 106]

Then, the insulating layer 106 is formed to cover the semiconductor layer 108, the conductive layer 112b, and the insulating layer 110. For the formation of the insulating layer 106, a PECVD method can be favorably used.

In the case of using an oxide semiconductor for the insulating layer 108, the insulating layer 106 preferably functions as a barrier film that inhibits diffusion of oxygen. The insulating layer 106 having a function of inhibiting diffusion of oxygen inhibits diffusion of oxygen into the conductive layer 104 from above the insulating layer 106 and thus can inhibit oxidation of the conductive layer 104. Consequently, the transistor can have favorable electrical characteristics and high reliability.

By increasing the temperature at the time of forming the insulating layer 106 functioning as the gate insulating layer, the insulating layer including a small number of defects can be obtained. However, the high temperature at the time of forming the insulating layer 106 sometimes allows release of oxygen from the semiconductor layer 108, which increases the amount of oxygen vacancy (V_{O}) and V_{O}H in the semiconductor layer 108 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, the transistor can have favorable electrical characteristics and high reliability.

It is preferable to perform plasma treatment on the surface of the semiconductor layer 108 before the formation of the insulating layer 106. By the plasma treatment, an impurity adsorbed onto the surface of the semiconductor layer 108, such as water, can be reduced. Therefore, impurities at the interface between the semiconductor layer 108 and the insulating layer 106 can be reduced, achieving a highly reliable transistor. The plasma treatment is particularly suitable in the case where the surface of the semiconductor layer 108 is exposed to the air after the formation of the semiconductor layer 108 and before the formation of the insulating layer 106. For example, plasma treatment can be performed in an atmosphere containing oxygen, ozone, nitrogen, dinitrogen monoxide, argon, or the like. The plasma treatment and the formation of the insulating layer 106 are preferably performed successively without exposure to the air.

### [Formation of Conductive Layer 104]

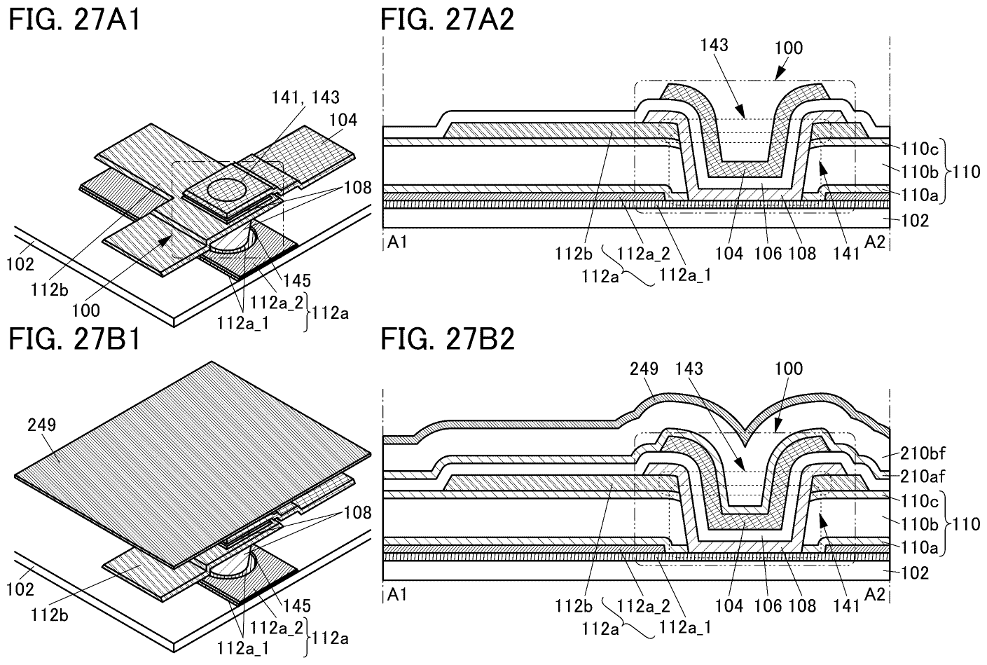

Subsequently, a conductive film to be the conductive layer 104 is formed over the insulating layer 106. For the formation of the conductive film, a sputtering method can be suitably used, for example. After a resist mask is formed over the conductive film in a photolithography process, the conductive film is processed, whereby the conductive layer 104 functioning as the gate electrode is formed (FIG. 27A1 and FIG. 27A2).

Through the above process, the transistor 100 can be manufactured.

[Formation of Insulating Film 210af and Insulating Film 210bf]

Next, an insulating film 210af to be the insulating layer 210a and an insulating film 210bf to be the insulating layer 210b are formed over the transistor 100.

The description of the formation of the insulating film 110af and the insulating film 110bf can be referred to for the formation of the insulating film 210af and the insulating film 210bf; thus, the detailed description thereof is omitted.

The substrate temperatures at the time of forming the insulating film 210af and the insulating film 210bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 210af and the insulating film 210bf are in the above range, impurities (e.g., water and hydrogen) released from the insulating films themselves can be reduced, which inhibits diffusion of the impurities to the semiconductor layer 208. Consequently, the transistor can have favorable electrical characteristics and high reliability.

Heat treatment may be performed after the insulating film 210af and the insulating film 210bf are formed. By performing the heat treatment, water and hydrogen can be released from the surface and inside of each of the insulating film 210af and the insulating film 210bf. For the heat treatment, the description of the heat treatment after the formation of the insulating film 110af and the insulating film 110bf can be referred to; thus, the detailed description thereof is omitted.

Next, a metal oxide layer 249 is formed over the insulating film 210bf (FIG. 27B1 and FIG. 27B2). The description of the metal oxide layer 149 can be referred to for the formation of the metal oxide layer 249; thus, the detailed description thereof is omitted.

After the metal oxide layer 249 is formed, heat treatment may be performed. The above description can be referred to for the heat treatment; thus, the detailed description thereof is omitted.

Then, the metal oxide layer 249 is removed. The description of the removal of the metal oxide layer 149 can be referred to for the removal of the metal oxide layer 249; thus, the detailed description thereof is omitted.

[Formation of Insulating Film 210cf and Formation of Conductive Film 212f]

Next, an insulating film 210cf to be the insulating layer 210c is formed over the insulating film 210bf. The description of the formation of the insulating film 110af and the insulating film 110bf can be referred to for the formation of the insulating film 210cf; thus, the detailed description thereof is omitted.

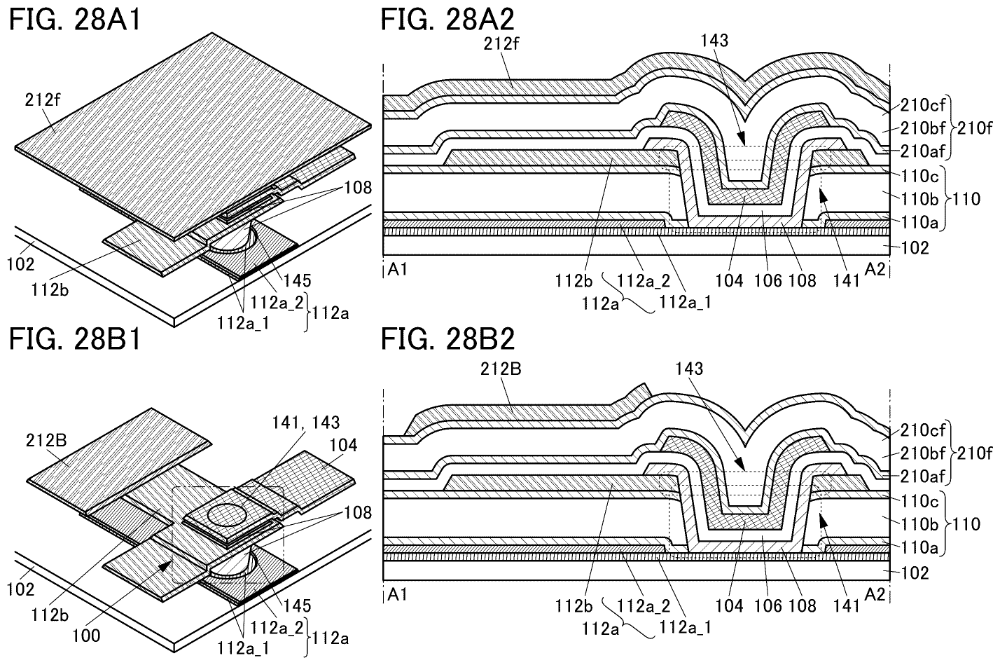

Then, a conductive film 212f to be the conductive layer 212b is formed over the insulating film 210cf (FIG. 28A1 and FIG. 28A2). The description of the formation of the conductive film 112f can be referred to for the formation of the conductive film 212f; thus, the detailed description thereof is omitted.

### [Formation of Opening 241 and Formation of Opening 243]

Next, the conductive film 212f is processed to form a conductive layer 212B (FIG. 28B1 and FIG. 28B2). The description of the formation of the conductive layer 112B can be referred to for the formation of the conductive layer 212B; thus, the detailed description thereof is omitted.

Next, the conductive layer 212B in a region overlapping with the conductive layer 112b is removed, whereby the conductive layer 212b having the opening 243 is formed. The description of the formation of the opening 143 can be referred to for the formation of the opening 243; thus, the detailed description thereof is omitted.

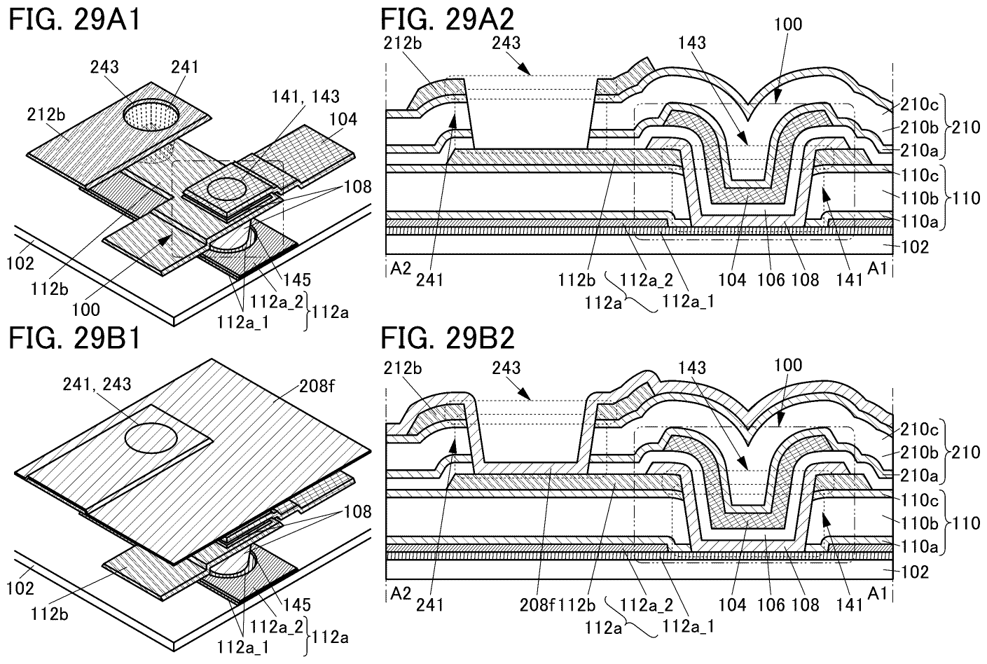

Next, the insulating layer 106 and the insulating film 210f (the insulating film 210af, the insulating film 210bf, and the insulating film 210cf) in a region overlapping with the opening 243 are removed, whereby the insulating layer 106 and the insulating layer 210 that have the opening 241 are formed (FIG. 29A1 and FIG. 29A2). The description of the formation of the opening 141 can be referred to for the formation of the opening 241; thus, the detailed description thereof is omitted. Note that the opening 241 provided in the insulating layer 106 and the insulating layer 210 is indicated by dashed lines in FIG. 29A1. The conductive layer 112b is exposed in the opening 241.

Note that in the formation of the opening 241 or after the formation of the opening 241, part of the conductive layer 112b in a region overlapping with the opening 241 may be removed. By removing part of the conductive layer 112b, the structure illustrated in FIG. 8A and FIG. 8B can be obtained.

### [Formation of Semiconductor Layer 208]

Subsequently, a metal oxide film 208f to be the semiconductor layer 208 is formed to cover the opening 241 and the opening 243 (FIG. 29B1 and FIG. 29B2). The metal oxide film 208f is provided in contact with the top surface and the side surface of the conductive layer 212b, the top surface and the side surface of the insulating layer 210, the side surface of the insulating layer 106, and the top surface of the conductive layer 112b.

The description of the formation of the metal oxide film 108f can be referred to for the formation of the metal oxide film 208f; thus, the detailed description thereof is omitted.

Note that in the case where the semiconductor layer 208 has a stacked-layer structure, an upper metal oxide film is preferably formed successively after the formation of a lower metal oxide film without exposure of the surface of the lower metal oxide layer to the air.

Next, the metal oxide film 208f is processed into an island shape, so that the semiconductor layer 208 is formed (FIG. 30A1 and FIG. 30A2). The description of the formation of the semiconductor layer 108 can be referred to for the formation of the semiconductor layer 208; thus, the detailed description thereof is omitted.

It is preferable that heat treatment be performed after the metal oxide film 208f is formed or the metal oxide film 208f is processed into the semiconductor layer 208. By the heat treatment, hydrogen or water contained in the metal oxide film 208f or the semiconductor layer 108 or adsorbed onto a surface of the metal oxide film 208f or the semiconductor layer 108 can be removed. Furthermore, the film quality of the metal oxide film 208f or the semiconductor layer 208 is improved (e.g., the number of defects is reduced or crystallinity is increased) by the heat treatment in some cases.

Oxygen can be supplied from the insulating layer 210b to the metal oxide film 208f or the semiconductor layer 208 by heat treatment. In this case, it is further preferable that the heat treatment be performed before the semiconductor film 208f is processed into the semiconductor layer 208. The above description can be referred to for the heat treatment; thus, the detailed description thereof is omitted.

### [Formation of Insulating Layer 206]

Then, the insulating layer 206 is formed to cover the semiconductor layer 208, the conductive layer 212b, and the insulating layer 210. The description of the formation of the insulating layer 106 can be referred to for the description of the formation of the insulating layer 206; thus, the detailed description thereof is omitted.

It is preferable to perform plasma treatment on the surface of the semiconductor layer 208 before the formation of the insulating layer 206. By the plasma treatment, an impurity adsorbed onto the surface of the semiconductor layer 208, such as water, can be reduced. Therefore, impurities at the interface between the semiconductor layer 208 and the insulating layer 206 can be reduced, achieving a highly reliable transistor. The plasma treatment is particularly suitable in the case where the surface of the semiconductor layer 208 is exposed to the air after the formation of the semiconductor layer 208 and before the formation of the insulating layer 206. The above description can be referred to for the plasma treatment; thus, the detailed description thereof is omitted.

### [Formation of Conductive Layer 204]

Next, a conductive film to be the conductive layer 204 is formed over the insulating layer 206 and the conductive film is processed, whereby the conductive layer 204 functioning as the gate electrode of the transistor 200 is formed (FIG. 30B1 and FIG. 30B2).

Through the above process, the transistor 200 can be manufactured.

### [Formation of Insulating Layer 195]

Next, the insulating layer 195 is formed over the transistor 200 (FIG. 1C). For the formation of the insulating layer 195, a PECVD method can be favorably used.

Through the above process, the semiconductor device 10 can be manufactured.

This embodiment can be combined with the other embodiments as appropriate. In this specification, in the case where a plurality of structure examples are shown in one embodiment, the structure examples can be combined as appropriate.

### Embodiment 2

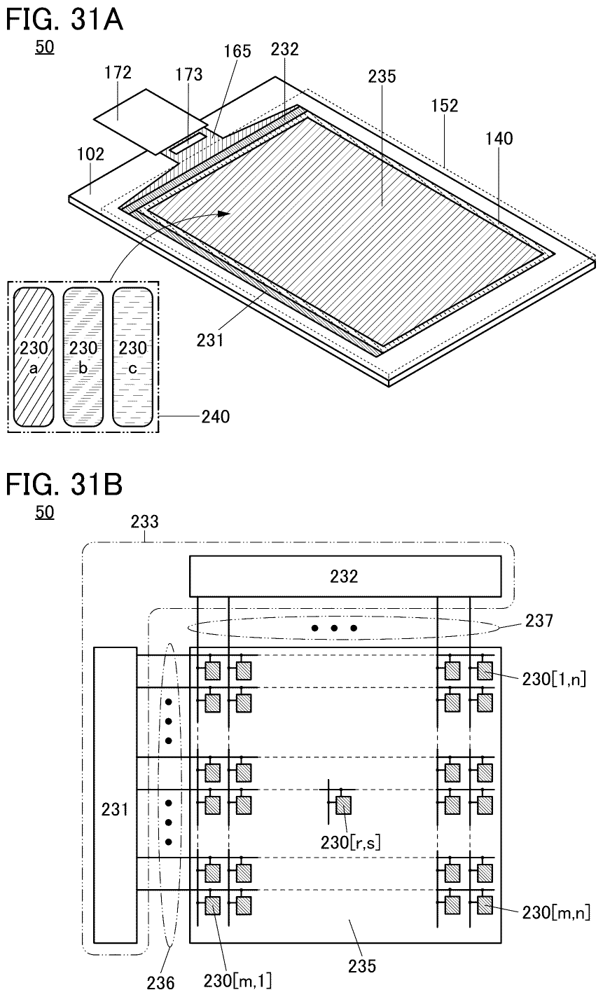

In this embodiment, a structure example of a display apparatus for which the semiconductor device of one embodiment of the present invention can be used will be described. FIG. 31A is a schematic view of a display apparatus 50 of one embodiment of the present invention. In the display apparatus 50, a substrate 152 and the substrate 102 are bonded to each other. In FIG. 31A, the substrate 152 is denoted by a dashed line.

The display apparatus 50 includes a display portion 235, a connection portion 140, a first driver circuit portion 231, a second driver circuit portion 232, and a wiring 165. FIG. 31A illustrates an example in which an IC 173 and an FPC 172 are mounted on the display apparatus 50. Thus, the structure illustrated in FIG. 31A can also be regarded as a display module including the display apparatus 50, the IC (integrated circuit), and the FPC.

The connection portion 140 is provided outside the display portion 235. The connection portion 140 can be provided along one or more sides of the display portion 235. The number of the connection portions 140 can be one or more. FIG. 31A illustrates an example in which the connection portion 140 is provided to surround the four sides of the display portion 235. A common electrode of a light-emitting device is electrically connected to a conductive layer in the connection portion 140, so that a potential can be supplied to the common electrode.

The wiring 165 has a function of supplying a signal and electric power to the display portion 235, the first driver circuit portion 231, and the second driver circuit portion 232. The signal and electric power are input to the wiring 165 from the outside through the FPC 172 or input to the wiring 165 from the IC 173.

FIG. 31A illustrates an example in which the IC 173 is provided over the substrate 102 by a COG (Chip On Glass) method, a COF (Chip on Film) method, or the like. The IC 173 may include a scan line driver circuit or a signal line driver circuit, for example. Note that the display apparatus 50 and the display module are not necessarily provided with an IC. The IC may be mounted on the FPC by a COF method or the like.

The display portion 235 includes a plurality of pixels 230 arranged in a matrix. As the pixels 230, three kinds of pixels, a pixel 230a, a pixel 230b, and a pixel 230c, can be used, for example. The pixel 230a, the pixel 230b, and the pixel 230c each include a display device (also referred to as a display element). Examples of the display device include a liquid crystal device (also referred to as a liquid crystal element) and a light-emitting device. As the light-emitting device, an OLED (Organic Light Emitting Diode) or a QLED (Quantum-dot Light Emitting Diode) is preferably used, for example. Examples of a light-emitting substance included in the light-emitting device include a substance that emits fluorescent light (a fluorescent material), a substance that emits phosphorescent light (a phosphorescent material), a substance exhibiting thermally activated delayed fluorescence (a thermally activated delayed fluorescent (TADF) material), and an inorganic compound (e.g., a quantum dot material). An LED (Light Emitting Diode) such as a micro-LED can also be used as the light-emitting device.

The pixel 230a, the pixel 230b, and the pixel 230c have a function of emitting light of different colors. For example, the pixel 230a may have a function of emitting red (R) light, the pixel 230b may have a function of emitting green (G) light, and the pixel 230c may have a function of emitting blue (B) light. Alternatively, for example, the pixel 230a may have a function of emitting yellow (Y) light, the pixel 230b may have a function of emitting cyan (C) light, and the pixel 230c may have a function of emitting magenta (M) light.

One pixel 230a, one pixel 230b, and one pixel 230c form one pixel 240, which achieves full-color display. Thus, the pixel 230 functions as a subpixel. The display apparatus 50 illustrated in FIG. 31A shows an example in which the pixels 230 each functioning as a subpixel are arranged in a stripe pattern. The number of subpixels for forming one pixel 240 is not limited to three, and may be four or more. For example, four subpixels which emit light of R, G, B, and white (W) may be included. Alternatively, four subpixels which emit light of four colors, R, G, B, and Y, may be included.

FIG. 31B is a block diagram illustrating the display apparatus 50. The display apparatus 50 includes the display portion 235, the first driver circuit portion 231, and the second driver circuit portion 232. The display portion 235 includes the plurality of pixels 230 arranged in a matrix.

A circuit included in the first driver circuit portion 231 functions as, for example, a scan line driver circuit. A circuit included in the second driver circuit portion 232 functions as, for example, a signal line driver circuit. Note that some sort of circuit may be provided at a position facing the first driver circuit portion 231 with the display portion 235 positioned therebetween. Some sort of circuit may be provided at a position facing the second driver circuit portion 232 with the display portion 235 positioned therebetween. Note that circuits included in the first driver circuit portion 231 and the second driver circuit portion 232 are collectively referred to as a peripheral driver circuit.

Any of various circuits such as a shift register circuit, a level shifter circuit, an inverter circuit, a latch circuit, an analog switch circuit, a demultiplexer circuit, and a logic circuit can be used as a peripheral driver circuit 233. In the peripheral driver circuit 233, a transistor, a capacitor, and the like can be used. Transistors included in the peripheral driver circuit 233 may be formed in the same step as the transistors included in the pixels 230.

The display apparatus 50 includes m (m is an integer greater than or equal to 1) wirings 236 which are arranged substantially parallel to each other and whose potentials are controlled by the circuit included in the first driver circuit portion 231, and n (n is an integer greater than or equal to 1) wirings 237 which are arranged substantially parallel to each other and whose potentials are controlled by the circuit included in the second driver circuit portion 232.

FIG. 31B illustrates an example in which the wiring 236 and the wiring 237 are connected to the pixel 230. Note that the wiring 236 and the wiring 237 are examples, and the wirings connected to the pixel 230 are not limited to the wiring 236 and the wiring 237.

### <Structure Example of Peripheral Driver Circuit>

Using a latch circuit as an example, a structure example of a circuit that can be used as a peripheral driver circuit will be described.

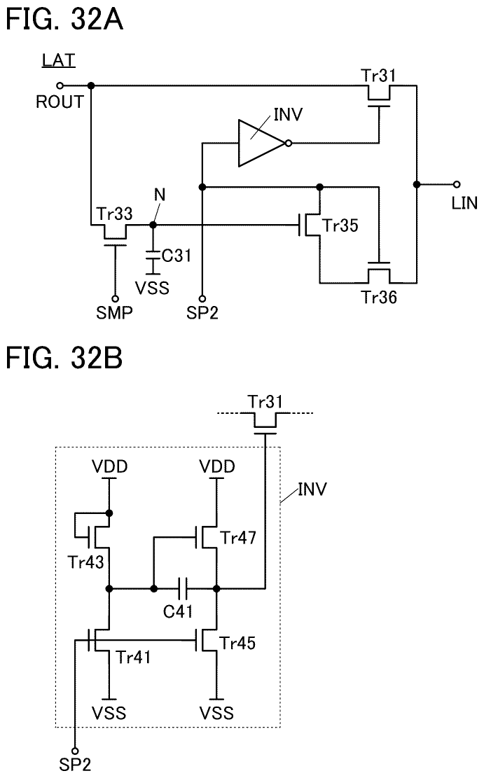

FIG. 32A is a circuit diagram illustrating a structure example of a latch circuit LAT. The latch circuit LAT illustrated in FIG. 32A includes a transistor Tr31, a transistor Tr33, a transistor Tr35, a transistor Tr36, a capacitor C31, and an inverter circuit INV. In FIG. 32A, a node that is electrically connected to one of a source and a drain of the transistor Tr33, a gate of the transistor Tr35, and one electrode of the capacitor C31 is referred to as a node N.

In the latch circuit LAT illustrated in FIG. 32A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is held and the data written to the latch circuit LAT is held. Specifically, when the potential of the node N is a low potential, data “0” is held in the latch circuit LAT and when the potential of the node Nis a high potential, data “1” is held in the latch circuit LAT, for example.

A transistor with a low off-state current is preferably used as the transistor Tr33. An OS transistor can be suitably used as the transistor Tr33. Thus, the latch circuit LAT can hold data for a long period. Thus, the frequency of rewriting data in the latch circuit LAT can be lowered.

In this specification and the like, data that allows a signal input from a terminal SP2 to be output to a terminal LIN is written to the latch circuit LAT, which is referred to simply as “writing data to the latch circuit LAT” in some cases. That is, for example, data “1” is written to the latch circuit LAT, which is referred to simply as “writing data to the latch circuit LAT” in some cases.

The semiconductor device of one embodiment of the present invention can be suitably used for the latch circuit LAT. For example, the semiconductor device 10 illustrated in FIG. 1B and the like can be used as each of the transistor Tr31 and the transistor Tr36 in the latch circuit LAT. The transistor Tr31 corresponds to the transistor 100 illustrated in FIG. 1B and the like, and the transistor Tr36 corresponds to the transistor 200. For example, the semiconductor device 20 illustrated in FIG. 13B and the like can be used as each of the transistor Tr35 and the transistor Tr33 in the latch circuit LAT. The transistor Tr35 corresponds to the transistor 100A illustrated in FIG. 13B and the like, and the transistor Tr33 corresponds to the transistor 200A.

FIG. 32B illustrates a structure example of the inverter circuit INV. The inverter circuit INV includes a transistor Tr41, a transistor Tr43, a transistor Tr45, a transistor Tr47, and a capacitor C41.

The latch circuit LAT has the structure illustrated in FIG. 32A and the inverter circuit INV has the structure illustrated in FIG. 32B, in which case all the transistors included in the latch circuit LAT can be transistors having the same polarity, for example, n-channel transistors. Thus, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same step.

The semiconductor device of one embodiment of the present invention can be suitably used for the inverter circuit INV. For example, the semiconductor device 10 illustrated in FIG. 1B and the like can be used as each of the transistor Tr41 and the transistor Tr43 in the inverter circuit INV. The transistor Tr41 corresponds to the transistor 100 illustrated in FIG. 1B and the like, and the transistor Tr43 corresponds to the transistor 200. For example, the semiconductor device 10 illustrated in FIG. 1B and the like can be used as each of the transistor Tr45 and the transistor Tr47 in the inverter circuit INV. The transistor Tr45 corresponds to the transistor 100 illustrated in FIG. 1B and the like, and the transistor Tr47 corresponds to the transistor 200.

### <Structure Example of Pixel Circuit>

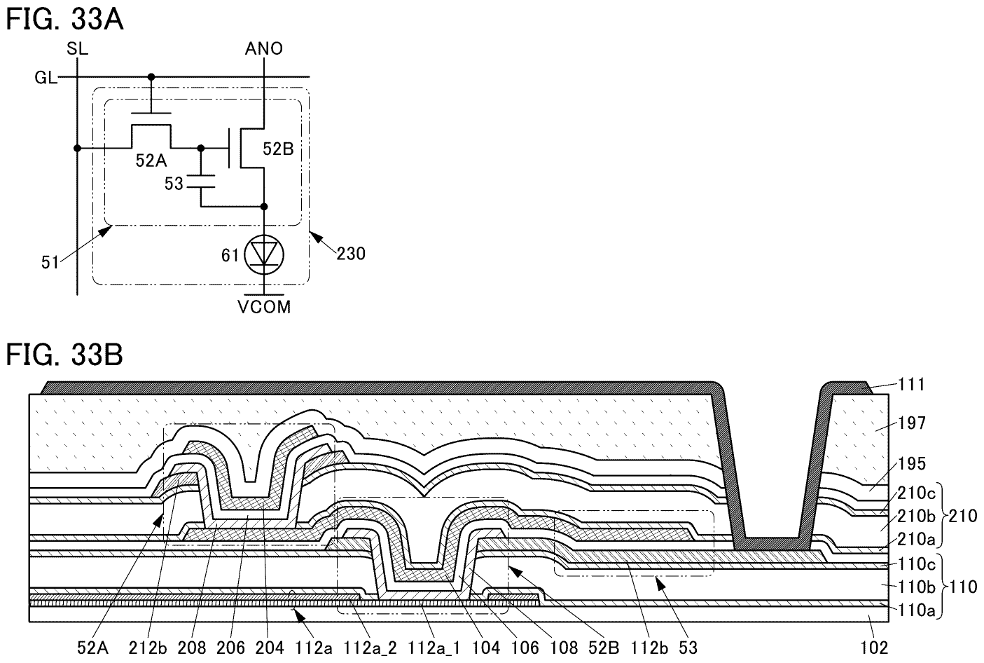

FIG. 33A illustrates a structure example of the pixel 230. The pixel 230 includes a pixel circuit 51 and a light-emitting device 61.

The pixel circuit 51 illustrated in FIG. 33A is a 2Tr1C-type pixel circuit including a transistor 52A, a transistor 52B, and a capacitor 53.

One of a source and a drain of the transistor 52A is electrically connected to a gate of the transistor 52B and one terminal of the capacitor 53, and the other of the source and the drain is electrically connected to a wiring SL. A gate of the transistor 52A is electrically connected to a wiring GL. One of a source and a drain of the transistor 52B and the other terminal of the capacitor 53 are electrically connected to an anode of the light-emitting device 61. The other of the source and the drain of the transistor 52B is electrically connected to a wiring ANO. A cathode of the light-emitting device 61 is electrically connected to a wiring VCOM.

The wiring GL corresponds to the wiring 236, and the wiring SL corresponds to the wiring 237. The wiring VCOM is a wiring for supplying a potential for supplying current to the light-emitting device 61. The transistor 52A has a function of controlling the conduction state and the non-conduction state between the wiring SL and the gate of the transistor 52B in accordance with the potential of the wiring GL. For example, VDD is supplied to the wiring ANO, and VSS is supplied to the wiring VCOM.

The transistor 52B has a function of controlling the amount of current flowing through the light-emitting device 61. The capacitor 53 has a function of holding a gate potential of the transistor 52B. The intensity of light emitted by the light-emitting device 61 is controlled in accordance with an image signal supplied to the gate of the transistor 52B.

In the structure of the pixel circuit 51 illustrated in FIG. 33A, n-channel transistors are used as the transistor 52A and the transistor 52B. A p-channel transistor may be used as the transistor 52B. When a p-channel transistor is used as the transistor 52B, the other terminal of the capacitor 53 is electrically connected to the other of the source and the drain of the transistor 52B. Note that there is no particular limitation on the pixel circuit that can be used for the display apparatus of one embodiment of the present invention.

For example, the semiconductor device 20 described in Embodiment 1 can be used for the pixel circuit 51. The transistor 52A corresponds to the transistor 200A illustrated in FIG. 13B and the like, and the transistor 52B corresponds to the transistor 100A.

FIG. 33B illustrates a structure example of the pixel circuit 51. FIG. 33B is a cross-sectional view of the pixel circuit 51.

The description of the transistor 200A and the transistor 100A illustrated in FIG. 13B and the like can be referred to for the transistor 52A and the transistor 52B; thus, the detailed description thereof is omitted. FIG. 33B illustrates an example in which the insulating layer 106 is interposed between the conductive layer 104 functioning as one of the source electrode and the drain electrode of the transistor 52A and the gate electrode of the transistor 52B and the conductive layer 112b functioning as one of the source electrode and the drain electrode of the transistor 52B, whereby the capacitor 53 is formed. Note that there is no particular limitation on the structure of the capacitor 53.

The transistor 52B functioning as a driving transistor that controls a current flowing through the light-emitting device 61 preferably has a higher on-state current than the transistor 52A functioning as a selection transistor for controlling a selection state of the pixel 230. The semiconductor layer of the transistor 52B preferably includes a metal oxide having a higher indium content percentage than that of the semiconductor layer of the transistor 52A. A display apparatus with such a structure can have high luminance.

The semiconductor layer of the transistor 52B functioning as a driving transistor may include a metal oxide having a lower indium content percentage than that of the semiconductor layer of the transistor 52A. When the semiconductor layer of the transistor 52B includes a metal oxide having a low indium content percentage, the transistor 52B has favorable saturation, whereby a display apparatus having high reliability can be provided.

Alternatively, the content percentage of the element M (e.g., gallium) may be different between the semiconductor layer of the transistor 52A and the semiconductor layer of the transistor 52B. Since a positive potential is supplied to the gate of the transistor 52B functioning as a driving transistor, it is preferable to use a transistor with a small amount of change in threshold voltage in a PBTS test. Meanwhile, as the transistor 52A, it is preferable to use a transistor with a small amount of change in threshold voltage in a NBTIS test. The semiconductor layer of the transistor 52B preferably includes a metal oxide containing no gallium or a metal oxide having a lower gallium content percentage than that of the semiconductor layer of the transistor 52A. The semiconductor layer of the transistor 52A preferably includes a metal oxide having a higher gallium content percentage than that of the semiconductor layer of the transistor 52B. A display apparatus with such a structure can have high reliability.

The insulating layer 195 is provided to cover the transistor 52A, the transistor 52B, and the capacitor 53, and an insulating layer 197 is provided to cover the insulating layer 195. The light-emitting device 61 can be provided over the insulating layer 197. FIG. 33B illustrates a pixel electrode 111 functioning as one electrode of the light-emitting device 61. The above description can be referred to for the insulating layer 195; thus, the detailed description thereof is omitted. The insulating layer 197 has a function of reducing unevenness due to the transistor 52A, the transistor 52B, and the capacitor 53 and making the formation surface of the light-emitting device 61 flatter. Note that in this specification and the like, the insulating layer 197 is referred to as a planarization layer in some cases.

As the insulating layer 197, an insulating layer including an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 197, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the insulating layer 197, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive organic resin. As the photosensitive organic resin, either a positive material or a negative material may be used.

The insulating layer 197 may have a stacked-layer structure of an organic insulating layer and an inorganic insulating layer. For example, the insulating layer 197 can have a stacked-layer structure of an organic insulating layer and an inorganic insulating layer over the organic insulating layer. An inorganic insulating layer provided on the outermost surface of the insulating layer 197 can function as an etching protective layer. This can inhibit a decrease in the flatness of the insulating layer 197, which is caused by etching of part of the insulating layer 197 in the formation of the pixel electrode 111.

The pixel electrode 111 is electrically connected to the conductive layer 112b through an opening provided in the insulating layer 197, the insulating layer 195, the insulating layer 206, the insulating layer 210, and the insulating layer 106.

The display apparatus of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

### <Structure Example of Display Apparatus>

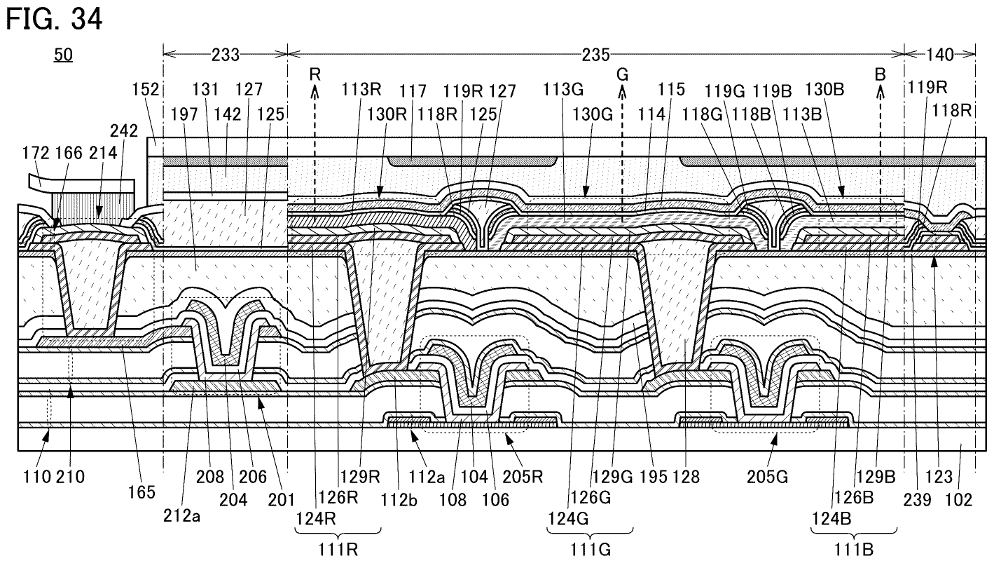

FIG. 34 illustrates an example of cross sections of part of a region including the FPC 172, part of the peripheral driver circuit 233, part of the display portion 235, part of the connection portion 140, and part of a region including an end portion of the display apparatus 50.

In the display apparatus 50, transistors are provided over the substrate 102; an insulating layer is provided over the transistors; a light-emitting device 130R, a light-emitting device 130G, and a light-emitting device 130B are provided over the insulating layer; and a protective layer 131 is provided to cover these light-emitting devices. The substrate 152 is attached onto the protective layer 131 with an adhesive layer 142.

Note that in the case of describing matters common to the light-emitting device 130R, the light-emitting device 130G, and the light-emitting device 130B, these light-emitting devices are sometimes referred to as a light-emitting device 130 by omitting the alphabets that distinguish them from each other. In the same manner, in the description common to the components that are distinguished by alphabets, reference numerals without alphabets are sometimes used. Transistors that control the light-emitting device 130R, the light-emitting device 130G, and the light-emitting device 130B can be provided in the display portion 235. FIG. 34 illustrates a transistor 205R that controls the light-emitting device 130R and a transistor 205G that controls the light-emitting device 130G. FIG. 34 also illustrates a transistor 201 provided in the peripheral driver circuit 233. The transistor described in Embodiment 1 can be suitably used as each of the transistor 205R, the transistor 205G, and the transistor 201. Note that FIG. 34 does not illustrate electrical connection between the transistors.

The transistor provided in the peripheral driver circuit 233 is sometimes required to have a higher on-state current than the transistor provided in the display portion 235. The semiconductor layer of the transistor provided in the peripheral driver circuit 233 (e.g., the semiconductor layer 208 of the transistor 201) can suitably include a metal oxide having a higher proportion of the number of indium atoms in the total number of atoms of all the contained metal elements than that of the semiconductor layer of the transistor provided in the display portion 235 (e.g., the semiconductor layer 108 of the transistor 205R). For example, In—Ga—Zn oxide is used for the semiconductor layer 108, and the semiconductor layer 208 can suitably include In—Zn oxide having a higher proportion of the number of indium atoms in the total number of atoms of all the contained metal elements than that of the semiconductor layer 108.

A structure can be employed in which the light-emitting device 130R emits red (R) light, the light-emitting device 130G emits green (G) light, and the light-emitting device 130B emits blue (B) light.

One of pair of electrodes included in the light-emitting device functions as an anode, and the other electrode functions as a cathode. The case where the pixel electrode functions as an anode and the common electrode functions as a cathode is described below as an example in some cases.

The light-emitting device 130R includes a pixel electrode 111R, an island-shaped layer 113R over the pixel electrode 111R, a common layer 114 over the island-shaped layer 113R, and a common electrode 115 over the common layer 114. In the light-emitting device 130R, the layer 113R and the common layer 114 can be collectively referred to as an EL layer.

The light-emitting device 130G includes a pixel electrode 111G, an island-shaped layer 113G over the pixel electrode 111G, the common layer 114 over the island-shaped layer 113G, and the common electrode 115 over the common layer 114. In the light-emitting device 130G, the layer 113G and the common layer 114 can be collectively referred to as an EL layer.

The light-emitting device 130B includes a pixel electrode 111B, an island-shaped layer 113B over the pixel electrode 111B, the common layer 114 over the island-shaped layer 113B, and the common electrode 115 over the common layer 114. In the light-emitting device 130B, the layer 113B and the common layer 114 can be collectively referred to as an EL layer.

In this specification and the like, in the EL layers included in the light-emitting devices, the island-shaped layer provided in each light-emitting device is referred to as the layer 113R, the layer 113G, or the layer 113B, and the layer shared by the plurality of light-emitting devices is referred to as the common layer 114. Note that in this specification and the like, the layer 113R, the layer 113G, and the layer 113B are sometimes referred to as island-shaped EL layers, EL layers formed in an island shape, or the like, in which case the common layer 114 is not included.

The layer 113R, the layer 113G, and the layer 113B are separated from one another. When the EL layer is provided in an island shape for each light-emitting device, a leakage current between adjacent light-emitting devices can be inhibited. This can prevent unintended light emission due to crosstalk, so that a display apparatus with extremely high contrast can be obtained. Specifically, a display apparatus having high current efficiency at low luminance can be obtained.

In FIG. 34, an insulating layer (also referred to as an embankment, a partition wall, a bank, or a spacer) covering an end portion of the top surface of the pixel electrode 111R is not provided between the pixel electrode 111R and the layer 113R. An insulating layer covering an end portion of the top surface of the pixel electrode 111G is not provided between the pixel electrode 111G and the layer 113G. Thus, the distance between adjacent light-emitting devices can be extremely short. Accordingly, the display apparatus can have a high definition or a high resolution. In addition, a mask for forming the insulating layer is not needed, which leads to a reduction in manufacturing cost of the display apparatus. With a structure in which an insulating layer covering the end portion of the pixel electrode is not provided, light emitted from the EL layer can be extracted efficiently. Therefore, the display apparatus of one embodiment of the present invention can significantly reduce the viewing angle dependence.

The layer 113R, the layer 113G, and the layer 113B each include at least a light-emitting layer. The layer 113R includes a light-emitting layer emitting red light, the layer 113G includes a light-emitting layer emitting green light, and the layer 113B includes a light-emitting layer emitting blue light. In other words, the layer 113R contains a light-emitting material emitting red light, the layer 113G contains a light-emitting material emitting green light, and the layer 113B contains a light-emitting material emitting blue light. The layer 113R, the layer 113G, and the layer 113B may each include one or more of a hole-injection layer, a hole-transport layer, a hole-blocking layer, a charge-generation layer, an electron-blocking layer, an electron-transport layer, and an electron-injection layer.

As illustrated in FIG. 34, an end portion of the layer 113G is preferably positioned outward from an end portion of the pixel electrode 111G. Note that although description is made using the pixel electrode 111G and the layer 113G as an example, the same applies to the pixel electrode 111R and the layer 113R, and the pixel electrode 111B and the layer 113B.

In FIG. 34, the layer 113G is formed to cover the end portion of the pixel electrode 111G. Such a structure enables the entire top surface of the pixel electrode to be a light-emitting region, and the aperture ratio can be easily increased as compared with the structure in which the end portion of the island-shaped EL layer is positioned inward from the end portion of the pixel electrode.

Covering the side surface of the pixel electrode 111 with the EL layer can inhibit contact between the pixel electrode 111 and the common electrode 115, thereby inhibiting a short circuit of the light-emitting device. Furthermore, the distance between the light-emitting region (i.e., the region overlapping with the pixel electrode) in the EL layer and the end portion of the EL layer can be increased. Since the end portion of the EL layer might be damaged by processing, the use of a region away from the end portion of the EL layer as a light-emitting region can improve the reliability of the light-emitting device in some cases.

Although FIG. 34 illustrates the layer 113R, the layer 113G, and the layer 113B that have the same thickness, one embodiment of the present invention is not limited thereto. The layer 113R, the layer 113G, and the layer 113B may have different thicknesses. For example, the thickness is preferably set to match an optical path length that intensifies light emitted from the layer 113R, the layer 113G, and the layer 113B. A microcavity structure can be achieved in this manner, and the color purity of light from each light-emitting device can be increased. The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. The common electrode 115 shared by the plurality of light-emitting devices is electrically connected to a conductive layer 123 provided in the connection portion 140. The conductive layer 123 can be formed in the same step as the pixel electrode 111R, the pixel electrode 111G, and the pixel electrode 111B.

The display apparatus 50 illustrated in FIG. 34 has a top-emission structure. Light emitted by the light-emitting device is emitted toward the substrate 152. For the substrate 152, a material having a high visible-light-transmitting property is preferably used. The pixel electrode 111 contains a material reflecting visible light, and the common electrode 115 contains a material transmitting visible light. In FIG. 34, arrows with broken lines indicate light R, light G, and light B, which are emitted toward the substrate 152 from the light-emitting device 130R, the light-emitting device 130G, and the light-emitting device 130B, respectively.

The protective layer 131 is provided over the light-emitting device 130R, the light-emitting device 130G, and the light-emitting device 130B. The protective layer 131 and the substrate 152 are bonded to each other with the adhesive layer 142. The substrate 152 is provided with a light-blocking layer 117. A solid sealing structure, a hollow sealing structure, or the like can be employed to seal the light-emitting devices. In FIG. 34, a solid sealing structure is employed in which a space between the substrate 152 and the substrate 102 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting device. The space may be filled with a resin different from that of the frame-like adhesive layer 142.

The protective layer 131 is preferably provided over the light-emitting device 130R, the light-emitting device 130G, and the light-emitting device 130B. Provision of the protective layer 131 can inhibit oxidation of the common electrode 115 and entry of impurities (e.g., water and oxygen) into the light-emitting device. Accordingly, deterioration of the light-emitting device can be inhibited, and the reliability of the display apparatus can be increased. The protective layer 131 may have a single-layer structure or a stacked-layer structure including two or more layers. There is no limitation on the conductivity of the protective layer 131. As the protective layer 131, at least one of an insulating layer, a semiconductor layer, and a conductive layer can be used.

An inorganic substance can be used for the protective layer 131. For example, one or more of an oxide, an oxynitride, a nitride oxide, and a nitride can be used for the protective layer 131. Specific examples include silicon oxide, silicon oxynitride, silicon nitride oxide, silicon nitride, aluminum oxide, aluminum oxynitride, and hafnium oxide. In particular, the protective layer 131 preferably includes a nitride or a nitride oxide, and further preferably includes a nitride.

As the protective layer 131, a layer including In—Sn oxide (ITO), In—Zn oxide, Ga—Zn oxide, Al—Zn oxide, or In—Ga—Zn oxide (IGZO) can also be used. The layer preferably has high resistance, specifically, higher resistance than the common electrode 115. The layer may further contain nitrogen.

When light emitted from the light-emitting device 130 is extracted through the protective layer 131, the protective layer 131 preferably has a high visible-light-transmitting property. For example, In—Sn oxide, In—Ga—Zn oxide, and aluminum oxide are preferable because they have a high visible-light-transmitting property.

Furthermore, the protective layer 131 may include an organic film. For example, the protective layer 131 may include both an organic film and an inorganic film.

Examples of methods for forming the protective layer 131 include a vacuum evaporation method, a sputtering method, a CVD method, and an ALD method. The protective layer 131 may have a stacked-layer structure of layers which are formed by different film formation methods. The protective layer 131 is provided at least in the display portion 235, and preferably provided to cover the entire display portion 235. The protective layer 131 is preferably provided to cover not only the display portion 235 but also the connection portion 140 and the peripheral driver circuit 233. It is also preferable that the protective layer 131 be provided to extend to the end portion of the display apparatus 50.

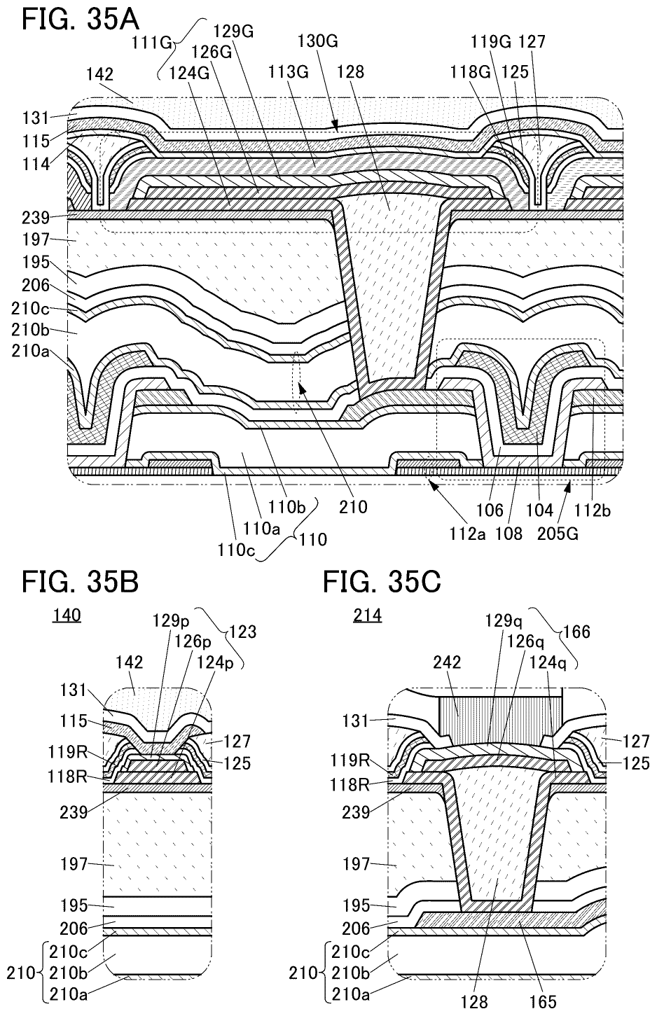

FIG. 35A is an enlarged view of the light-emitting device 130G, the transistor 205G, and the vicinity thereof.

The pixel electrode 111G included in the light-emitting device 130G includes a conductive layer 124G, a conductive layer 126G over the conductive layer 124G, and a conductive layer 129G over the conductive layer 126G.

The conductive layer 124G is electrically connected to the conductive layer 112b included in the transistor 205G through an opening provided in the insulating layer 106, the insulating layer 210, the insulating layer 206, the insulating layer 195, the insulating layer 197, and an insulating layer 239. Note that the conductive layer 124G may be electrically connected to the conductive layer 112a included in the transistor 205G through an opening provided in the insulating layer 110, the insulating layer 106, the insulating layer 210, the insulating layer 206, the insulating layer 195, the insulating layer 197, and the insulating layer 239.

An end portion of the conductive layer 124G is positioned outward from an end portion of the conductive layer 126G. The end portion of the conductive layer 126G is positioned inward from an end portion of the conductive layer 129G. The end portion of the conductive layer 124G is positioned inward from the end portion of the conductive layer 129G. In other words, the end portion of the conductive layer 126G is positioned over the conductive layer 124G. The end portion of the conductive layer 129G is positioned over the conductive layer 124G. The top surface and the side surface of the conductive layer 126G are covered with the conductive layer 129G.

For the conductive layer 124G, no particular limitations are imposed on the properties of transmitting and reflecting visible light. As the conductive layer 124G, a conductive layer having a visible-light-transmitting property or a conductive layer having a visible-light-reflecting property can be used. As the conductive layer having a visible-light-transmitting property, a conductive layer including an oxide conductor (also referred to as an oxide conductive layer) can be used, for example. Specifically, In—Si—Sn oxide (also referred to as ITSO) can be suitably used for the conductive layer 124G. Examples of the conductive layer having a visible-light-reflecting property include metal such as aluminum, titanium, chromium, nickel, copper, yttrium, zirconium, tin, zinc, silver, platinum, gold, molybdenum, tantalum, and tungsten, and an alloy containing the metal as its main component (e.g., an alloy of silver, palladium, and copper (APC: Ag—Pd—Cu)).

The conductive layer 124G may have a stacked-layer structure of a conductive layer having a visible-light-transmitting property and a conductive layer having visible-light-reflecting property over the conductive layer. For the conductive layer 124G, a material with high adhesion to the formation surface of the conductive layer 124G (here, the insulating layer 239) is preferably used. Accordingly, film separation of the conductive layer 124G can be inhibited.

As the conductive layer 126G, a conductive layer having a visible-light-reflecting property can be used. The conductive layer 126G may have a stacked-layer structure of a conductive layer having a visible-light-transmitting property and a conductive layer having a visible-light-reflecting property over the conductive layer. For the conductive layer 126G, a material that can be used for the conductive layer 124G can be used. Specifically, a stacked-layer structure of In—Si—Sn oxide (ITSO) and an alloy of silver, palladium, and copper (APC) over the In—Si—Sn oxide (ITSO) can be suitably used for the conductive layer 126G.

For the conductive layer 129G, a material that can be used for the conductive layer 124G can be used. As the conductive layer 129G, a conductive layer having a visible-light-transmitting property can be used. Specifically, In—Si—Sn oxide (ITSO) can be used for the conductive layer 129G.

In the case where a material that is easily oxidized is used for the conductive layer 126G, a material that is not easily oxidized is used for the conductive layer 129G and the conductive layer 126G is covered with the conductive layer 129G, whereby oxidation of the conductive layer 126G can be inhibited. In addition, precipitation of a metal component included in the conductive layer 126G can be inhibited. For example, in the case where a material containing silver is used for the conductive layer 126G, In—Si—Sn oxide (ITSO) can be suitably used for the conductive layer 129G. Thus, oxidation of the conductive layer 126G can be inhibited, and precipitation of silver can be inhibited.

The end portions of the conductive layer 129G, the conductive layer 126G, and the conductive layer 124G may be aligned or substantially aligned with one another. The layer 113G may be in contact with the side surface of the conductive layer 129G, the side surface of the conductive layer 126G, and the side surface of the conductive layer 124G.

For example, a first conductive film to be the conductive layer 124G, a layer 128, a second conductive film to be the conductive layer 126G, and a third conductive film to be the conductive layer 129G are formed; after that, a resist mask is formed over the third conductive film, and the first conductive film, the second conductive film, and the third conductive film are processed using the resist mask, whereby the conductive layer 124G, the conductive layer 126G, and the conductive layer 129G can be formed. The first conductive film, the second conductive film, and the third conductive film are processed in the same step to form the conductive layer 124G, the conductive layer 126G, and the conductive layer 129G, whereby the process can be simplified.

Alternatively, the side surface of the conductive layer 124G and the top surface and the side surface of the conductive layer 126G may be covered with the conductive layer 129G. The layer 113G includes a region in contact with the top surface and the side surface of the conductive layer 129G, and does not necessarily include a region in contact with the conductive layer 124G and the conductive layer 126G.

For example, the first conductive film to be the conductive layer 124G and the second conductive film to be the conductive layer 126G are formed; after that, a resist mask is formed over the second conductive film, and the first conductive film and the second conductive film are processed using the resist mask, whereby the conductive layer 124G and the conductive layer 126G are formed. After that, the third conductive film to be the conductive layer 129G is formed to cover the conductive layer 124G and the conductive layer 126G, and the third conductive film is processed, whereby the conductive layer 129G can be formed. The first conductive film and the second conductive film are processed in the same step to form the conductive layer 124G and the conductive layer 126G, whereby the process can be simplified. Even when a material that is easily diffused, such as silver, is used for the conductive layer 124G or the conductive layer 126G, diffusion can be inhibited by covering the top surfaces and the side surfaces of the conductive layer 124G and the conductive layer 126G with the conductive layer 129G.

The pixel electrode 111R in the light-emitting device 130R and the pixel electrode 111B in the light-emitting device 130B can each have a structure similar to that of the pixel electrode 111G.

Depressed portions are formed in a conductive layer 124R, the conductive layer 124G, and a conductive layer 124B to cover the openings provided in the insulating layer 106, the insulating layer 210, the insulating layer 206, the insulating layer 195, the insulating layer 197, and the insulating layer 239. The layer 128 is embedded in the depressed portions.

The layer 128 has a planarization function for the depressed portions of the conductive layer 124R, the conductive layer 124G, and the conductive layer 124B. A conductive layer 126R, the conductive layer 126G, and a conductive layer 126B electrically connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the depressed portions of the conductive layer 124R, the conductive layer 124G, and the conductive layer 124B can also function as the light-emitting regions, increasing the aperture ratio of the pixels.

The layer 128 has a planarization function for the depressed portions of the conductive layer 124R, the conductive layer 124G, and the conductive layer 124B. Provision of the layer 128 can improve the planarity of the top surfaces of the pixel electrode 111R, the pixel electrode 111G, and the pixel electrode 111B that are formation surfaces of the layer 113R, the layer 113G, and the layer 113B, respectively.

The layer 128 may be an insulating layer or a conductive layer. Any of a variety of inorganic insulating materials, organic insulating materials, and conductive materials can be used for the layer 128 as appropriate.

As the layer 128, an insulating layer including an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

For the layer 128, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. Alternatively, for an insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photoresist may be used as the photosensitive resin. As the photosensitive organic resin, either a positive material or a negative material may be used.

When the layer 128 is a conductive layer, the layer 128 can function as part of a pixel electrode. For the layer 128, for example, an organic resin in which metal particles are dispersed can be used.

Although FIG. 35A and the like illustrate a structure in which the top surface of the layer 128 has a shape in which the center and the vicinity thereof are bulged, i.e., a shape including a convex surface, in a cross-sectional view, the shape of the layer 128 is not particularly limited. The top surface of the layer 128 can have a shape in which its center and the vicinity thereof are depressed, i.e., a shape including a concave surface, in a cross-sectional view. The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 124G may be equal to or substantially equal to each other, or may be different from each other. For example, the level of the top surface of the layer 128 may be either lower or higher than the level of the top surface of the conductive layer 124G.

FIG. 35B is an enlarged view of the connection portion 140. For example, the conductive layer 123 can have a stacked-layer structure of a conductive layer 124p, a conductive layer 126p over the conductive layer 124p, and a conductive layer 129p over the conductive layer 126p. The conductive layer 124p can be formed in the same step as the conductive layer 124R, the conductive layer 124G, and the conductive layer 124B. The conductive layer 126p can be formed in the same step as the conductive layer 126R, the conductive layer 126G, and the conductive layer 126B. The conductive layer 129p can be formed in the same step as a conductive layer 129R, the conductive layer 129G, and a conductive layer 129B.

FIG. 35B and the like illustrate an example in which the common layer 114 is not provided in the connection portion 140 and the common electrode 115 is provided over the conductive layer 123. Note that an example in which the common layer 114 is provided over the conductive layer 123 and the conductive layer 123 and the common electrode 115 are electrically connected to each other through the common layer 114 may be employed. For example, by using a mask for specifying a film formation area (also referred to as an area mask, a rough metal mask, or the like to be distinguished from a fine metal mask), the common layer 114 and the common electrode 115 can be formed in different regions.

A connection portion 214 is provided in the substrate 102 in a region that does not overlap with the substrate 152. In the connection portion 214, the wiring 165 is electrically connected to the FPC 172 through a conductive layer 166 and a connection layer 242. The conductive layer 166 is exposed from the top surface of the connection portion 214. Thus, the connection portion 214 and the FPC 172 can be electrically connected to each other through the connection layer 242. Note that FIG. 34 and the like illustrate a structure in which the wiring 165 functions as a source electrode or a drain electrode of the transistor 201. Note that the conductive layer 212a of the transistor 201 may be electrically connected to the FPC 172 through the conductive layer 166 and the connection layer 242.

As the connection layer 242, an anisotropic conductive film (ACF) or an anisotropic conductive paste (ACP) can be used, for example.

Note that the connection portion 214 has a portion not provided with the protective layer 131 so that the FPC 172 and the conductive layer 166 are electrically connected to each other. For example, the protective layer 131 is formed over the entire surface of the display apparatus 50 and then a region of the protective layer 131 overlapping with the conductive layer 166 is removed, so that the conductive layer 166 can be exposed.

FIG. 35C is an enlarged view of the connection portion 214. For example, the conductive layer 166 can have a stacked-layer structure of a conductive layer 124q, a conductive layer 126q over the conductive layer 124q, and a conductive layer 129q over the conductive layer 126q. The conductive layer 124q can be formed in the same step as the conductive layer 124R, the conductive layer 124G, and the conductive layer 124B. The conductive layer 126q can be formed in the same step as the conductive layer 126R, the conductive layer 126G, and the conductive layer 126B. The conductive layer 129q can be formed in the same step as the conductive layer 129R, the conductive layer 129G, and the conductive layer 129B.

FIG. 34 and the like illustrate a structure in which the thicknesses of the conductive layer 129p and the conductive layer 129q are different from the thicknesses of the conductive layer 129R, the conductive layer 129G, and the conductive layer 129B. These thicknesses of the conductive layer 129p, the conductive layer 129q, the conductive layer 129R, the conductive layer 129G, and the conductive layer 129B may be different depending on the resistivities of materials used for these layers. In the case of making the thicknesses different, the conductive layer 129p and the conductive layer 129q may be formed in a step different from a step of forming the conductive layer 129R, the conductive layer 129G, and the conductive layer 129B. Alternatively, formation of the conductive layer 129p and the conductive layer 129q and formation of the conductive layer 129R, the conductive layer 129G, and the conductive layer 129B may share some steps. Alternatively, the conductive layer 129p and the conductive layer 129q may have different thicknesses.

The pixel electrode 111R, the pixel electrode 111G, the pixel electrode 111B, the conductive layer 123, and the conductive layer 166 illustrated in FIG. 34 and the like can also be applied to other structure examples.

In a region between the adjacent light-emitting devices, an insulating layer 125 and the insulating layer 127 over the insulating layer 125 are provided. Although FIG. 34 illustrates a plurality of cross sections of the insulating layer 125 and the insulating layer 127, the insulating layer 125 and the insulating layer 127 are each one continuous layer in a top view of the display apparatus 50. In other words, the display apparatus 50 can have a structure including one insulating layer 125 and one insulating layer 127, for example. Note that the display apparatus 50 may include a plurality of insulating layers 125 that are separated from each other, and may include a plurality of insulating layers 127 that are separated from each other.

A mask layer 118R and a mask layer 119R are positioned over the layer 113R, a mask layer 118G and a mask layer 119G are positioned over the layer 113G, and a mask layer 118B and a mask layer 119B are positioned over the layer 113B. The mask layer 118R, the mask layer 119R, the mask layer 118G, the mask layer 119G, the mask layer 118B, and the mask layer 119B have openings in portions overlapping with the light-emitting region. The mask layer 118R and the mask layer 119R are remaining parts of the mask layers provided in contact with the top surface of the layer 113R at the time of processing the layer 113R. In a similar manner, the mask layer 118G and the mask layer 119G are remaining parts of the mask layers provided at the time of forming the layer 113G, and the mask layer 118B and the mask layer 119B are remaining parts of the mask layers provided at the time of forming the layer 113B. Thus, the mask layer used to protect the EL layer in manufacture of the display apparatus may partly remain in the display apparatus of one embodiment of the present invention. For any two or all of the mask layer 118R, the mask layer 118G, and the mask layer 118B, the same material may be used or different materials may be used. For any two or all of the mask layer 119R, the mask layer 119G, and the mask layer 119B, the same material may be used or different materials may be used. Note that in the following description, in some cases, the mask layer 118R, the mask layer 118G, and the mask layer 118B are collectively referred to as a mask layer 118, and the mask layer 119R, the mask layer 119G, and the mask layer 119B are collectively referred to as a mask layer 119.

As each of the mask layer 118 and the mask layer 119, it is possible to use one or more of a metal film, an alloy film, a metal oxide film, a semiconductor film, an organic insulating film, and an inorganic insulating film, for example.

For each of the mask layer 118 and the mask layer 119, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. When a metal material capable of blocking ultraviolet rays is used for one or both of the mask layer 118 and the mask layer 119, the layer 113 can be inhibited from being irradiated with ultraviolet rays and deterioration of the layer 113 can be inhibited.

As each of the mask layer 118 and the mask layer 119, a metal oxide can be used. Examples of the metal oxide include In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), and indium tin oxide containing silicon.

Different materials can be used for the mask layer 118 and the mask layer 119. Note that a structure in which the mask layer 119 is not provided may be employed.

As illustrated in FIG. 34, one end portion of the mask layer 118R and one end portion of the mask layer 119R (outer end portions which are opposite to the light-emitting region side) are aligned or substantially aligned with the end portion of the layer 113R, and the other end portion of the mask layer 118R and the other end portion of the mask layer 119R are positioned over the layer 113R. Here, the other end portion of the mask layer 118R and the other end portion of the mask layer 119R (inner end portions which are on the light-emitting region side) preferably overlap with the layer 113R and the pixel electrode 111R. In this case, the other end portion of the mask layer 118R and the other end portion of the mask layer 119R are easily formed over a substantially flat surface of the layer 113R. Note that the same applies to the mask layer 118G, the mask layer 119G, the mask layer 118B, and the mask layer 119B. The mask layer 118 and the mask layer 119 remain between the top surface of the EL layer processed into an island shape (the layer 113R, the layer 113G, or the layer 113B) and the insulating layer 125.

In the case where end portions are aligned or substantially aligned with each other and the case where top surface shapes are the same or substantially the same, it can be said that outlines of stacked layers at least partly overlap with each other in a top view. For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions are substantially aligned with each other” or the expression “top surface shapes are substantially the same”.

The side surfaces of the layer 113R, the layer 113G, and the layer 113B are each covered with the insulating layer 125. The insulating layer 127 overlaps with the side surfaces of the layer 113R, the layer 113G, and the layer 113B with the insulating layer 125 therebetween.

The side surface and part of the top surface of each of the layer 113R, the layer 113G, and the layer 113B are covered with at least one of the insulating layer 125, the insulating layer 127, the mask layer 118, and the mask layer 119, so that the common layer 114 (or the common electrode 115) can be inhibited from being in contact with the side surfaces of the pixel electrode 111R, the pixel electrode 111G, the pixel electrode 111B, the layer 113R, the layer 113G, and the layer 113B, leading to inhibition of a short circuit of the light-emitting device. Accordingly, the reliability of the light-emitting device can be improved.

The insulating layer 125 is preferably in contact with the side surfaces of the layer 113R, the layer 113G, and the layer 113B. The insulating layer 125 is configured to be in contact with the layer 113R, the layer 113G, and the layer 113B, whereby film separation of the layer 113R, the layer 113G, and the layer 113B can be prevented. When the insulating layer 125 is in close contact with the layer 113B, the layer 113G, or the layer 113R, the layer 113B and the like that are adjacent to each other can be fixed or bonded to each other by the insulating layer.

Accordingly, the reliability of the light-emitting device can be improved. The manufacturing yield of the light-emitting device can also be improved.

Note that the insulating layer 125 and the insulating layer 127 may cover the side surface and part of the top surface of each of the layer 113R, the layer 113G, and the layer 113B. With such a structure, film separation of the EL layers can further be prevented and the reliability of the light-emitting device can be improved. The manufacturing yield of the light-emitting device can also be improved.

The insulating layer 127 is provided over the insulating layer 125 to fill a depressed portion formed in the insulating layer 125. The insulating layer 127 can be configured to overlap with the side surface and part of the top surface of each of the layer 113R, the layer 113G, and the layer 113B with the insulating layer 125 therebetween. The insulating layer 127 preferably covers at least part of the side surface of the insulating layer 125.

The insulating layer 125 and the insulating layer 127 can fill a space between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 113R, the layer 113G, the layer 113B, the mask layer 118, the mask layer 119, the insulating layer 125, and the insulating layer 127. Before the insulating layer 125 and the insulating layer 127 are provided, a step is generated due to a difference between a region where the pixel electrode and the island-shaped EL layer are provided and a region where neither the pixel electrode nor the island-shaped EL layer is provided (region between the light-emitting devices). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection can be inhibited. In addition, an increase in electric resistance, which is caused by local thinning of the common electrode 115 due to the step, can be inhibited.

The top surface of the insulating layer 127 preferably has a shape with higher flatness, but may include a projection portion, a convex surface, a concave surface, or a depressed portion. For example, the top surface of the insulating layer 127 preferably has a convex shape with a large radius of curvature.

The insulating layer 125 can be an insulating layer including an inorganic material. For the insulating layer 125, an oxide, a nitride, an oxynitride, or a nitride oxide can be used, for example. The insulating layer 125 may have a single-layer structure or a stacked-layer structure. Examples of the oxide include silicon oxide, aluminum oxide, magnesium oxide, indium-gallium-zinc oxide, gallium oxide, germanium oxide, yttrium oxide, zirconium oxide, lanthanum oxide, neodymium oxide, hafnium oxide, and tantalum oxide. Examples of the nitride include silicon nitride and aluminum nitride. Examples of the oxynitride include silicon oxynitride and aluminum oxynitride. Examples of the nitride oxide include silicon nitride oxide and aluminum nitride oxide. In particular, aluminum oxide is preferable because it has high selectivity with respect to the EL layer in etching and has a function of protecting the EL layer in forming the insulating layer 127 which is to be described later. In particular, when an aluminum oxide film, a hafnium oxide film, or a silicon oxide film formed by an atomic layer deposition (ALD) method is used as the insulating layer 125, the insulating layer 125 having few pin holes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a targeted substance (also referred to as having low permeability). Alternatively, a barrier property refers to a function of capturing or fixing (also referred to as gettering) a targeted substance.

When the insulating layer 125 has a function of a barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling large unevenness of the insulating layer 125, which is formed between the adjacent light-emitting devices. In other words, the insulating layer 127 has an effect of improving the flatness of the formation surface of the common electrode 115.

For the insulating layer 127, a material that can be used for the layer 128 can be used.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

The insulating layer 239 is provided over the insulating layer 197 and can function as an etching protective film when the layer 113, the mask layer 118, and the mask layer 119 are formed. Provision of the insulating layer 239 can prevent generation of unevenness in the insulating layer 197 caused by etching of part of the insulating layer 197 at the time when the layer 113, the mask layer 118, and the mask layer 119 are formed. Thus, steps in the formation surface of the insulating layer 125 become small, whereby the coverage with the insulating layer 125 can be increased. Consequently, the side surface of the layer 113 is covered with the insulating layer 125, which inhibits film separation of the layer 113.

The insulating layer 239 can be an insulating layer including an inorganic material. For the insulating layer 239, an oxide, a nitride, an oxynitride, or a nitride oxide can be used, for example. The insulating layer 239 may have a single-layer structure or a stacked-layer structure. Examples of the oxide include silicon oxide, aluminum oxide, magnesium oxide, indium-gallium-zinc oxide, gallium oxide, germanium oxide, yttrium oxide, zirconium oxide, lanthanum oxide, neodymium oxide, hafnium oxide, and tantalum oxide. Examples of the nitride include silicon nitride and aluminum nitride. Examples of the oxynitride include silicon oxynitride and aluminum oxynitride. Examples of the nitride oxide include silicon nitride oxide and aluminum nitride oxide. Silicon oxide or silicon oxynitride can be suitably used for the insulating layer 239, for example.

For the insulating layer 239, it is preferable to select a material having a high etching rate (also referred to as high selectivity) with respect to films to be the layer 113, the mask layer 118, and the mask layer 119 in etching of the films.

Here, the low flatness of the formation surface of the light-emitting device 130 might cause a defect such as a connection defect due to disconnection of the common electrode 115 or an increase in electric resistance due to the locally thinned regions of the common electrode 115. In addition, the processing accuracy of the layer to be formed over the formation surface might be lowered.

In the display apparatus of one embodiment of the present invention, by providing the insulating layer 239, the formation surface of the light-emitting device 130 can be flat. Accordingly, the processing accuracy of the light-emitting device 130 and the like provided over the insulating layer 239 is increased, whereby the display apparatus can have high definition. Furthermore, since a connection defect due to disconnection of the common electrode 115 and an increase in electric resistance due to the locally thinned regions of the common electrode 115 can be prevented, the display apparatus can have high display quality.

In the region that does not overlap with any of the layer 113R, the layer 113G, and the layer 113B, part of the insulating layer 239 may be removed. The thickness of the insulating layer 239 in the region that does not overlap with any of the layer 113R, the layer 113G, and the layer 113B may be smaller than the thickness of the insulating layer 239 in the region that overlaps with the layer 113R, the layer 113G, or the layer 113B.

Although the insulating layer 239 has a single-layer structure in FIG. 34 and the like, one embodiment of the present invention is not limited thereto. The insulating layer 239 may have a stacked-layer structure. Note that a structure in which the insulating layer 239 is not provided may be employed.

Note that the insulating layer 239 can be applied to other structure examples.

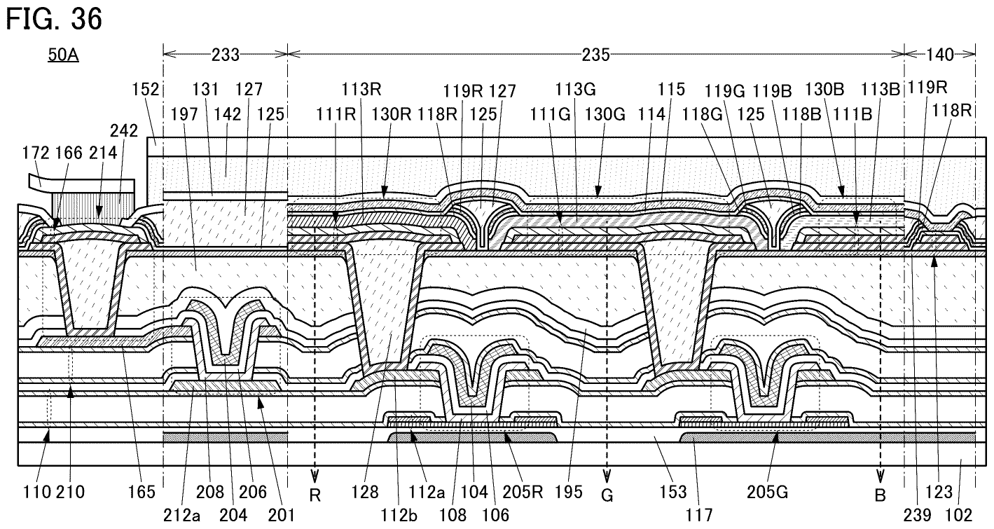

FIG. 36 illustrates a structure example of a bottom-emission display apparatus. In a display apparatus 50A illustrated in FIG. 36, light emitted by the light-emitting device 130 is emitted toward the substrate 102. For the substrate 102, a material having a high visible-light-transmitting property is preferably used. In contrast, there is no limitation on the light-transmitting property of a material used for the substrate 152.

The light-blocking layer 117 is preferably formed between the substrate 102 and the transistors 201, 205R, and 205G. FIG. 36 illustrates an example in which the light-blocking layer 117 is provided over the substrate 102, an insulating layer 153 is provided over the light-blocking layer 117, and the transistor 201, the transistor 205R, and the transistor 205G are provided over the insulating layer 153.

A material having a high visible-light-transmitting property is used for each of the layers included in the pixel electrode 111. A material reflecting visible light is preferably used for the common electrode 115.

### <Pixel Layout>

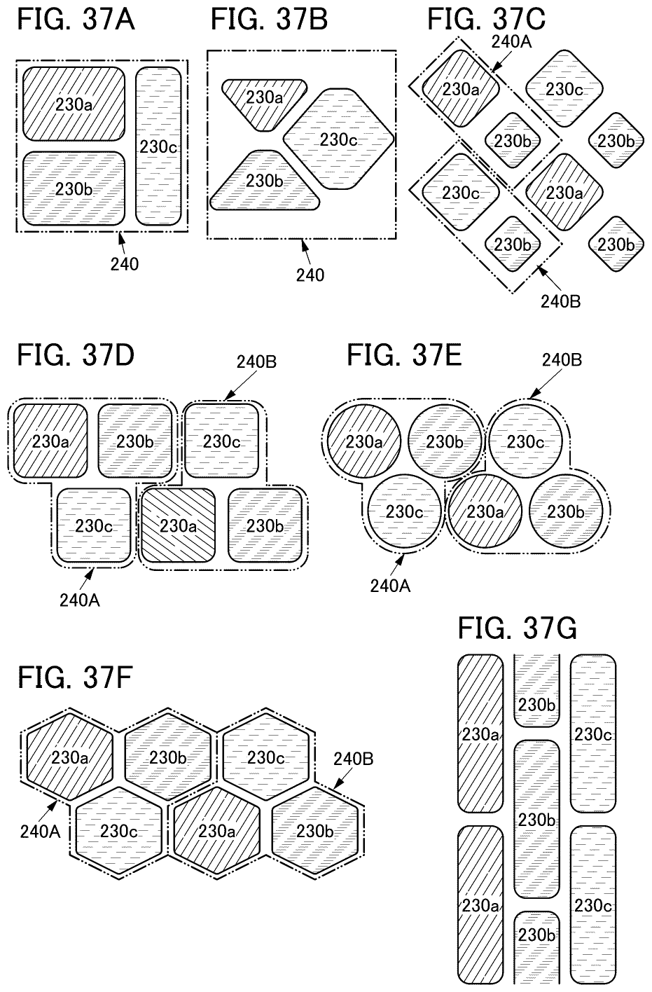

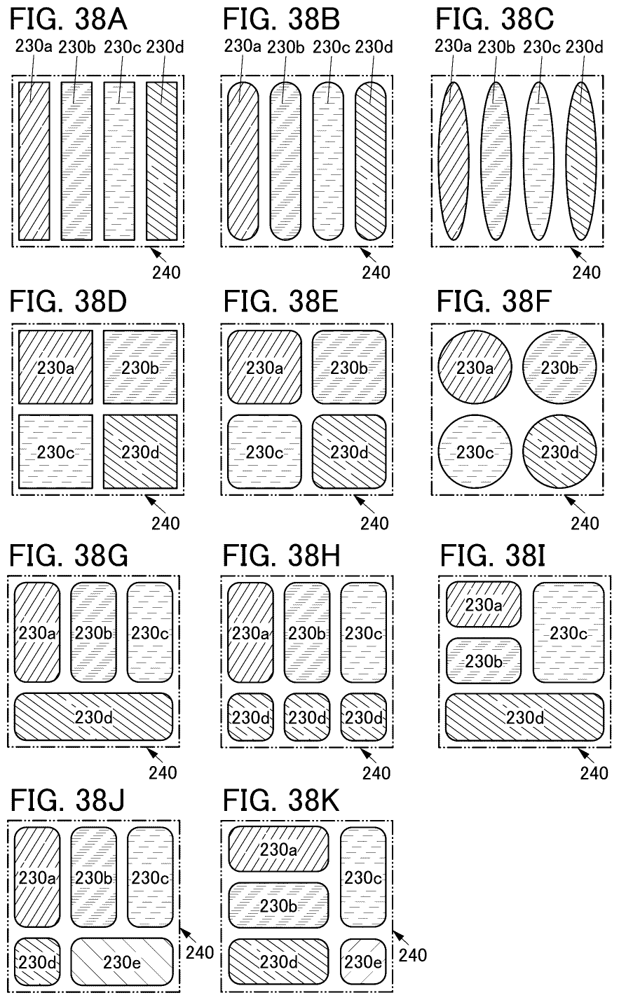

Pixel layouts different from that in FIG. 31A will be mainly described with reference to FIG. 37A to FIG. 37G and FIG. 38A to FIG. 38K. There is no particular limitation on the arrangement of subpixels, and any of a variety of pixel layouts can be employed. Examples of the arrangement of subpixels include stripe arrangement, S-stripe arrangement, matrix arrangement, delta arrangement, Bayer arrangement, and PenTile arrangement.

The top surface shapes of the subpixels illustrated in FIG. 31A, FIG. 37A to FIG. 37G, and FIG. 38A to FIG. 38K correspond to the top surface shapes of the light-emitting regions of the light-emitting devices.

Examples of a top surface shape of the subpixel include polygons such as a triangle, a tetragon (including a rectangle and a square), and a pentagon; polygons with rounded corners; an ellipse; and a circle.

The pixel circuit 51 included in the subpixel (the pixel 230) may be placed to overlap with a light-emitting region or may be placed outside the light-emitting region.

The pixel 240 illustrated in FIG. 37A employs S-stripe arrangement. The pixel 240 illustrated in FIG. 37A is composed using the pixel 230a, the pixel 230b, and the pixel 230c as subpixels.

The pixel 240 illustrated in FIG. 37B includes the pixel 230a whose top surface has a rough trapezoidal or rough triangle shape with rounded corners, the pixel 230b whose top surface has a rough trapezoidal or rough triangle shape with rounded corners, and the pixel 230c whose top surface has a rough tetragonal or rough hexagonal shape with rounded corners. The pixel 230b has a larger light-emitting area than the pixel 230a. In this manner, the shapes and sizes of the subpixels can be determined independently. For example, the size of a subpixel including a light-emitting device with higher reliability can be smaller.

A pixel 240A and a pixel 240B illustrated in FIG. 37C employ PenTile arrangement. FIG. 37C illustrates an example in which the pixels 240A including the pixel 230a and the pixel 230b and the pixels 240B including the pixel 230b and the pixel 230c are alternately arranged.

The pixel 240A and the pixel 240B illustrated in FIG. 37D to FIG. 37F employ delta arrangement. The pixel 240A includes two subpixels (the pixel 230a and the pixel 230b) in the upper row (first row) and one subpixel (the pixel 230c) in the lower row (second row). The pixel 240B includes one subpixel (the pixel 230c) in the upper row (first row) and two subpixels (the pixel 230a and the pixel 230b) in the lower row (second row).

FIG. 37D illustrates an example in which each subpixel has a rough tetragonal top surface shape with rounded corners, FIG. 37E illustrates an example in which each subpixel has a circular top surface shape, and FIG. 37F illustrates an example in which each subpixel has a rough hexagonal top surface shape with rounded corners.

In FIG. 37F, each of the subpixels is placed inside one of the closest-packed hexagonal regions. Focusing on one of the subpixels, the subpixel is placed so as to be surrounded by six subpixels. The subpixels are arranged such that subpixels that emit light of the same color are not adjacent to each other. For example, focusing on the pixel 230a, three pixels 230b and three pixels 230c are arranged to surround the pixel 230a, so that the pixel 230a, the pixel 230b, and the pixel 230c are alternately arranged.

FIG. 37G illustrates an example in which subpixels of different colors are arranged in a zigzag manner. Specifically, the positions of the top sides of two subpixels arranged in the row direction (e.g., the pixel 230a and the pixel 230b or the pixel 230b and the pixel 230c) are not aligned in a top view.

For example, in each pixel illustrated in FIG. 37A to FIG. 37G, it is preferable that the pixel 230a be a subpixel R emitting red light, the pixel 230b be a subpixel G emitting green light, and the pixel 230c be a subpixel B emitting blue light. Note that the structure of the subpixels is not limited to this, and the colors and arrangement order of the subpixels can be determined as appropriate. For example, the pixel 230b may be the subpixel R emitting red light and the pixel 230a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel has a polygonal shape with rounded corners, an elliptical shape, a circular shape, or the like, in some cases.

In the case where the EL layer is processed into an island shape using a resist mask, a resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 38A to FIG. 38I, the pixel can include four types of subpixels.

The pixels 240 illustrated in FIG. 38A to FIG. 38C employ stripe arrangement.

FIG. 38A illustrates an example in which each subpixel has a rectangular top surface shape, FIG. 38B illustrates an example in which each subpixel has a top surface shape formed by combining two half circles and a rectangle, and FIG. 38C illustrates an example in which each subpixel has an elliptical top surface shape.

The pixels 240 illustrated in FIG. 38D to FIG. 38F employ matrix arrangement.

FIG. 38D illustrates an example in which each subpixel has a square top surface shape, FIG. 38E illustrates an example in which each subpixel has a rough square top surface shape with rounded corners, and FIG. 38F illustrates an example in which each subpixel has a circular top surface shape.

FIG. 38G and FIG. 38H each illustrate an example in which one pixel 240 is composed of subpixels arranged in two rows and three columns.

The pixel 240 illustrated in FIG. 38G includes three subpixels (the pixel 230a, the pixel 230b, and the pixel 230c) in the upper row (first row) and one subpixel (a pixel 230d) in the lower row (second row) in the pixel 240. In other words, the pixel 240 includes the pixel 230a in the left column (first column), the pixel 230b in the center column (second column), the pixel 230c in the right column (third column), and the pixel 230d across these three columns.

The pixel 240 illustrated in FIG. 38H includes three subpixels (the pixel 230a, the pixel 230b, and the pixel 230c) in the upper row (first row) and three pixels 230d in the lower row (second row). In other words, the pixel 240 includes the pixel 230a and the pixel 230d in the left column (first column), the pixel 230b and the pixel 230d in the center column (second column), and the pixel 230c and the pixel 230d in the right column (third column) in the pixel 240. Matching the positions of the subpixels in the upper row and the lower row as illustrated in FIG. 38H enables efficient removal of dust and the like that would be produced in the manufacturing process. Thus, a display apparatus with high display quality can be provided.

FIG. 38I illustrates an example in which one pixel 240 is composed of subpixels arranged in three rows and two columns.

The pixel 240 illustrated in FIG. 38I includes the pixel 230a in the upper row (first row), the pixel 230b in the center row (second row), the pixel 230c across the first row and the second row, and one subpixel (the pixel 230d) in the lower row (third row) in the pixel 240. In other words, the pixel 240 includes the pixel 230a and the pixel 230b in the left column (first column), the pixel 230c in the right column (second column), and the pixel 230d across these two columns in the pixel 240.

The pixels 240 illustrated in FIG. 38A to FIG. 38I are each composed of four subpixels: the pixel 230a, the pixel 230b, the pixel 230c, and the pixel 230d.

The pixel 230a, the pixel 230b, the pixel 230c, and the pixel 230d can include light-emitting devices whose emission colors are different. The pixel 230a, the pixel 230b, the pixel 230c, and the pixel 230d are subpixels of four colors of R, G, B, and white (W), subpixels of four colors of R, G, B, and Y, or subpixels of R, G, B, and infrared light (IR).

In the pixels 240 illustrated in FIG. 38A to FIG. 381, the pixel 230a may be the subpixel R emitting red light, the pixel 230b may be the subpixel G emitting green light, the pixel 230c may be the subpixel B emitting blue light, and the pixel 230d may be any of a subpixel W emitting white light, a subpixel Y emitting yellow light, and a subpixel IR emitting near-infrared light, for example. In the case of such a structure, stripe arrangement is employed as the layout of R, G, and B in the pixels 240 illustrated in FIG. 38G and FIG. 38H, leading to higher display quality. In addition, what is called S-stripe arrangement is employed as the layout of R, G, and B in the pixel 240 illustrated in FIG. 38I, leading to higher display quality.

Note that the pixel 240 may include a subpixel including a light-receiving device.

In the pixels 240 illustrated in FIG. 38A to FIG. 38I, any one of the pixel 230a to the pixel 230d may be a subpixel including a light-receiving device.

In the pixels 240 illustrated in FIG. 38A to FIG. 381, the pixel 230a may be the subpixel R emitting red light, the pixel 230b may be the subpixel G emitting green light, the pixel 230c may be the subpixel B emitting blue light, and the pixel 230d may be a subpixel S including a light-receiving device, for example. In the case of such a structure, stripe arrangement is employed as the layout of R, G, and B in the pixels 240 illustrated in FIG. 38G and FIG. 38H, leading to higher display quality. In addition, what is called S-stripe arrangement is employed as the layout of R, G, and B in the pixel 240 illustrated in FIG. 38I, leading to higher display quality.

There is no particular limitation on the wavelength of light detected by the subpixel S including a light-receiving device. The subpixel S can have a structure in which one or both of visible light and infrared light are detected.

As illustrated in FIG. 38J and FIG. 38K, one pixel 240 may include five types of subpixels.

FIG. 38J illustrates an example in which one pixel 240 is composed of subpixels arranged in two rows and three columns.

The pixel 240 illustrated in FIG. 38J includes three subpixels (the pixel 230a, the pixel 230b, and the pixel 230c) in the upper row (first row) and two subpixels (the pixel 230d and a pixel 230e) in the lower row (second row) in the pixel 240. In other words, the pixel 240 includes the pixel 230a and the pixel 230d in the left column (first column), the pixel 230b in the center column (second column), the pixel 230c in the right column (third column), and the pixel 230e across the second column and the third column in the pixel 240.

FIG. 38K illustrates an example in which one pixel 240 is composed of subpixels arranged in three rows and two columns.

The pixel 240 illustrated in FIG. 38K includes the pixel 230a in the upper row (first row), the pixel 230b in the center row (second row), the pixel 230c across the first row and the second row, and two subpixels (the pixel 230d and the pixel 230e) in the lower row (third row) in the pixel 240. In other words, the pixel 240 includes the pixel 230a, the pixel 230b, and the pixel 230d in the left column (first column) and the pixel 230c and the pixel 230e in the right column (second column).

In the pixels 240 illustrated in FIG. 38J and FIG. 38K, it is preferable that the pixel 230a be the subpixel R emitting red light, the pixel 230b be the subpixel G emitting green light, and the pixel 230c be the subpixel B emitting blue light, for example. In the case of such a structure, stripe arrangement is employed as the layout of subpixels in the pixels 240 illustrated in FIG. 38J, leading to higher display quality. In addition, what is called S-stripe arrangement is employed as the layout of subpixels in the pixel 240 illustrated in FIG. 38K, leading to higher display quality.

In the pixels 240 illustrated in FIG. 38J and FIG. 38K, for example, the subpixel S including a light-receiving device may be used as at least one of the pixel 230d and the pixel 230e. In the case where light-receiving devices are used in both the pixel 230d and the pixel 230e, the light-receiving devices may have different structures. For example, the wavelength ranges of detected light may be different at least partly. Specifically, one of the pixel 230d and the pixel 230e may include a light-receiving device mainly detecting visible light and the other may include a light-receiving device mainly detecting infrared light.

In the pixels 240 illustrated in FIG. 38J and FIG. 38K, for example, the subpixel S including a light-receiving device may be used as one of the pixel 230d and the pixel 230e and a subpixel including a light-emitting device that can be used as a light source may be used as the other. For example, one of the pixel 230d and the pixel 230e may be the subpixel IR emitting infrared light and the other may be the subpixel S including a light-receiving device detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, in the display apparatus of one embodiment of the present invention, various layouts of the subpixels (the pixels 230) can be employed for the pixel 240. Furthermore, the pixel 240 may be configured to include both a light-emitting device and a light-receiving device. Also in this case, any of various layouts can be employed.

The structure described in this embodiment can be used in an appropriate combination with any of the structures described in the other embodiments.

### Embodiment 3

In this embodiment, a light-emitting device that can be used as the light-emitting device 61 is described.

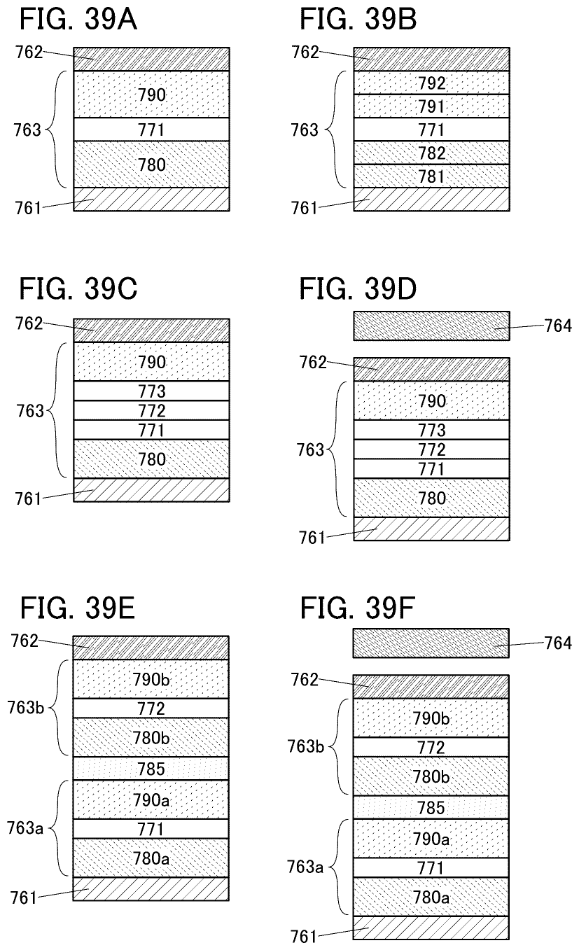

As illustrated in FIG. 39A, the light-emitting device includes an EL layer 763 between a pair of electrodes (a lower electrode 761 and an upper electrode 762). The EL layer 763 can be formed with a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer including a substance having a high hole-injection property (hole-injection layer), a layer including a substance having a high hole-transport property (hole-transport layer), and a layer including a substance having a high electron-blocking property (electron-blocking layer). Furthermore, the layer 790 includes one or more of a layer including a substance having a high electron-injection property (electron-injection layer), a layer including a substance having a high electron-transport property (electron-transport layer), and a layer including a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 39A is referred to as a single structure in this specification.

FIG. 39B is a modification example of the EL layer 763 included in the light-emitting device illustrated in FIG. 39A. Specifically, the light-emitting device illustrated in FIG. 39B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layer 771, a light-emitting layer 772, and a light-emitting layer 773) are provided between the layer 780 and the layer 790 as illustrated in FIG. 39C and FIG. 39D are other variations of the single structure. Although FIG. 39C and FIG. 39D each illustrate an example in which three light-emitting layers are included, the number of light-emitting layers in a light-emitting device having a single structure may be two or four or more. A light-emitting device having a single structure may include a buffer layer between two light-emitting layers. A carrier-transport layer (a hole-transport layer or an electron-transport layer) can be used as the buffer layer, for example.

A structure in which a plurality of light-emitting units (a light-emitting unit 763a and a light-emitting unit 763b) are connected in series with a charge-generation layer (also referred to as an intermediate layer) 785 therebetween as illustrated in FIG. 39E and FIG. 39F is referred to as a tandem structure in this specification. The tandem structure may be referred to as a stack structure. The tandem structure enables a light-emitting device capable of high-luminance light emission. Furthermore, the tandem structure allows the amount of current needed for obtaining the same luminance to be reduced as compared with the case of using a single structure, and thus can improve the reliability.

Note that FIG. 39D and FIG. 39F each illustrate an example in which the display apparatus includes a layer 764 overlapping with the light-emitting device. FIG. 39D illustrates an example in which the layer 764 overlaps with the light-emitting device illustrated in FIG. 39C, and FIG. 39F illustrates an example in which the layer 764 overlaps with the light-emitting device illustrated in FIG. 39E. In FIG. 39D and FIG. 39F, a conductive film that transmits visible light is used for the upper electrode 762 so that light is extracted through the upper electrode 762.

One or both of a color conversion layer and a color filter (coloring layer) can be used as the layer 764.

In FIG. 39C and FIG. 39D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 39D for converting blue light emitted from the light-emitting device into light with a longer wavelength, so that red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIG. 39C and FIG. 39D, light-emitting substances that emit light of different colors may be used for the light-emitting layer 771, the light-emitting layer 772, and the light-emitting layer 773. White light emission can be obtained by mixing of light emitted from the light-emitting layer 771, the light-emitting layer 772, and the light-emitting layer 773. The light-emitting device having a single structure preferably includes a light-emitting layer including a light-emitting substance that emits blue light and a light-emitting layer including a light-emitting substance that emits visible light with a longer wavelength than blue light, for example.

A color filter may be provided as the layer 764 illustrated in FIG. 39D. When white light passes through the color filter, light of a desired color can be obtained.

In the case where the light-emitting device having a single structure includes three light-emitting layers, for example, a light-emitting layer including a light-emitting substance that emits red (R) light, a light-emitting layer including a light-emitting substance that emits green (G) light, and a light-emitting layer including a light-emitting substance that emits blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer including a light-emitting substance that emits blue (B) light and a light-emitting layer including a light-emitting substance that emits yellow (Y) light are preferably included. Such a structure may be referred to as a BY single structure.

In the light-emitting device that emits white light, two or more kinds of light-emitting substances are preferably included. To obtain white light emission, the two or more kinds of light-emitting substances are selected so as to emit light of complementary colors. In the case of three or more kinds of light-emitting substances, the light-emitting substances are selected such that white light emission can be obtained by mixing of light emitted from the light-emitting substances. For example, when emission colors of a first light-emitting layer and a second light-emitting layer are complementary colors, the light-emitting device can emit white light as a whole. In the case of a light-emitting device including three or more light-emitting layers, the light-emitting device can emit white light by mixing of light emitted from the light-emitting layers.

In FIG. 39C and FIG. 39D, the layer 780 and the layer 790 may each have a stacked-layer structure of two or more layers as illustrated in FIG. 39B.

In FIG. 39E and FIG. 39F, light-emitting substances that emit light of the same color, or the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In the subpixel that emits blue light, blue light emitted from the light-emitting device can be extracted. In each of the subpixel that emits red light and the subpixel that emits green light, a color conversion layer is provided as the layer 764 illustrated in FIG. 39F for converting blue light emitted from the light-emitting device into light with a longer wavelength, so that red light or green light can be extracted. As the layer 764, both a color conversion layer and a coloring layer are preferably used.

In the case where light-emitting devices with the structure illustrated in FIG. 39E or FIG. 39F are used in subpixels emitting light of different colors, light-emitting substances may be different between the subpixels. Specifically, in the light-emitting device included in the subpixel that emits red light, a light-emitting substance that emits red light may be used for each of the light-emitting layer 771 and the light-emitting layer 772. Similarly, in the light-emitting device included in the subpixel that emits green light, a light-emitting substance that emits green light may be used for each of the light-emitting layer 771 and the light-emitting layer 772. In the light-emitting device included in the subpixel that emits blue light, a light-emitting substance that emits blue light may be used for each of the light-emitting layer 771 and the light-emitting layer 772. A display apparatus with such a structure includes a light-emitting device with a tandem structure and can be regarded to have an SBS structure. Thus, the display apparatus can have advantages of both of a tandem structure and an SBS structure. Accordingly, a highly reliable light-emitting device capable of high-luminance light emission can be obtained.

In FIG. 39E and FIG. 39F, light-emitting substances that emit light of different colors may be used for the light-emitting layer 771 and the light-emitting layer 772. When the light-emitting layer 771 and the light-emitting layer 772 emit light of complementary colors, white light emission can be obtained. A color filter may be provided as the layer 764 illustrated in FIG. 39F. When white light passes through the color filter, light of a desired color can be obtained.

Although FIG. 39E and FIG. 39F each illustrate an example in which the light-emitting unit 763a includes one light-emitting layer 771 and the light-emitting unit 763b includes one light-emitting layer 772, one embodiment of the present invention is not limited to the example. Each of the light-emitting unit 763a and the light-emitting unit 763b may include two or more light-emitting layers.

Although FIG. 39E and FIG. 39F each illustrate an example of a light-emitting device including two light-emitting units, one embodiment of the present invention is not limited to the example. The light-emitting device may include three or more light-emitting units. Note that a structure including two light-emitting units and a structure including three light-emitting units may be referred to as a two-unit tandem structure and a three-unit tandem structure, respectively.

In each of FIG. 39E and FIG. 39F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

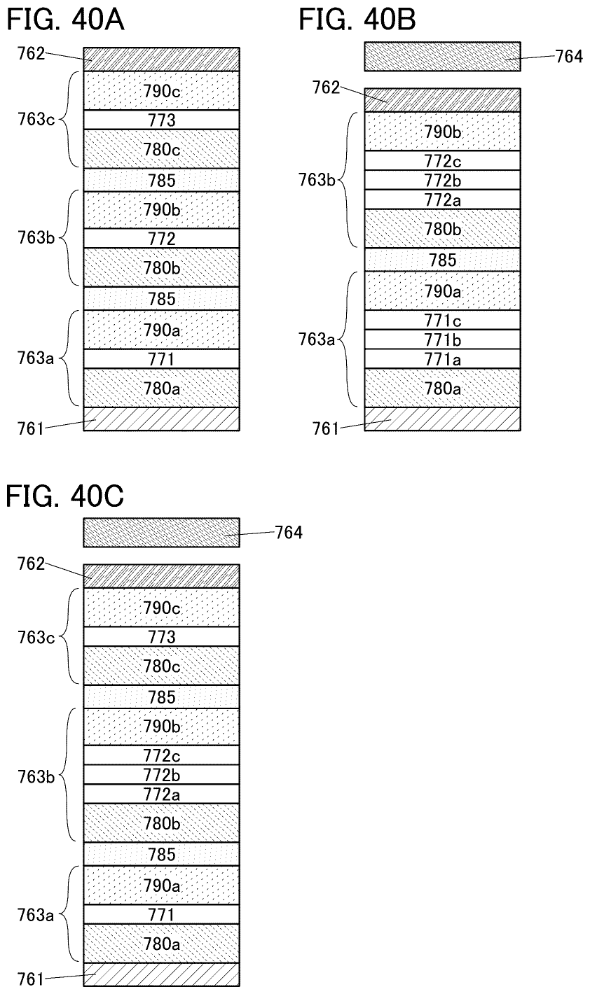

Examples of the light-emitting device with a tandem structure are structures illustrated in FIG. 40A to FIG. 40C.

FIG. 40A illustrates a structure including three light-emitting units. In FIG. 40A, a plurality of light-emitting units (a light-emitting unit 763a, a light-emitting unit 763b, and a light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 40A, the light-emitting layer 771, the light-emitting layer 772, and the light-emitting layer 773 preferably include light-emitting substances that emit light of the same color. Specifically, the light-emitting layer 771, the light-emitting layer 772, and the light-emitting layer 773 can each include a light-emitting substance that emits red (R) light (what is called an R\R\R three-unit tandem structure), the light-emitting layer 771, the light-emitting layer 772, and the light-emitting layer 773 can each include a light-emitting substance that emits green (G) light (what is called a G\G\G three-unit tandem structure), or the light-emitting layer 771, the light-emitting layer 772, and the light-emitting layer 773 can each include a light-emitting substance that emits blue (B) light (what is called a B\B\B three-unit tandem structure). Note that “a\b” means that a light-emitting unit including a light-emitting substance that emits light of a color “b” is provided over a light-emitting unit including a light-emitting substance that emits light of a color “a” with a charge-generation layer therebetween, and “a” and “b” each mean a color.

In FIG. 40A, light-emitting substances that emit light of different colors may be used for some or all of the light-emitting layer 771, the light-emitting layer 772, and the light-emitting layer 773. Examples of the combination of emission colors for the light-emitting layer 771, the light-emitting layer 772, and the light-emitting layer 773 include a combination of blue (B) for two of them and yellow (Y) for the other; and a combination of red (R) for one of them, green (G) for another, and blue (B) for the other.

Note that the light-emitting substances that emit light of the same color is not limited to the above structure. For example, a light-emitting device with a tandem structure may be employed in which light-emitting units each including a plurality of light-emitting layers are stacked as illustrated in FIG. 40B. FIG. 40B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 40B, by selecting light-emitting substances for the light-emitting layer 771a, the light-emitting layer 771b, and the light-emitting layer 771c such that white light emission is obtained when light emitted from the light-emitting layers is mixed, the light-emitting unit 763a enables white (W) light emission. Furthermore, by selecting light-emitting substances for the light-emitting layer 772a, the light-emitting layer 772b, and the light-emitting layer 772c such that white light emission is obtained when light emitted from the light-emitting layers is mixed, the light-emitting unit 763b enables white (W) light emission. That is, the structure illustrated in FIG. 40B is a two-unit tandem structure of W\W. Note that there is no particular limitation on the stacking order of light-emitting substances from which white light emission is obtained. A practitioner can select an optimum stacking order as appropriate. Although not illustrated, a three-unit tandem structure of W\W\W or a tandem structure with four or more units may be employed.

In the case of a light-emitting device with a tandem structure, any of the following structures may be employed: a two-unit tandem structure of B\Y or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a color “a” and a light-emitting substance that emits light of a color “b”.

Alternatively, a light-emitting unit including one light-emitting layer and a light-emitting unit including a plurality of light-emitting layers may be used in combination as illustrated in FIG. 40C.

Specifically, in the structure illustrated in FIG. 40C, a plurality of light-emitting units (the light-emitting unit 763a, the light-emitting unit 763b, and the light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 40C can be, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display apparatus includes a light-emitting device emitting infrared light, a conductive film transmitting visible light and infrared light is preferably used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the display apparatus.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (Ag—Pd—Cu, also referred to as APC). Other examples of the material include an element belonging to Group 1 or Group 2 of the periodic table that is not exemplified above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes of the light-emitting device is preferably an electrode having properties of transmitting and reflecting visible light (transflective electrode), and the other is preferably an electrode having a visible-light-reflecting property (reflective electrode). When the light-emitting device has a microcavity structure, light obtained from the light-emitting layer can be resonated between the electrodes, whereby light emitted from the light-emitting device can be intensified.

The transmittance of light of the electrode having a visible-light-transmitting property is greater than or equal to 40%. For example, in the case of using an electrode having a visible-light-transmitting property in the light-emitting device, an electrode having a visible light (light at a wavelength greater than or equal to 400 nm and less than 750 nm) transmittance higher than or equal to 40% is preferably used. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer including any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer includes one or more kinds of light-emitting substances. As the light-emitting substance, a substance whose emission color is blue, violet, bluish violet, green, yellow green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use any of after-mentioned substances each having a high hole-transport property that can be used for the hole-transport layer. As the electron-transport material, it is possible to use any of after-mentioned substances each having a high electron-transport property that can be used for the electron-transport layer. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer injects holes from the anode to the hole-transport layer and includes a substance having a high hole-injection property. Examples of a substance having a high hole-injection property include an aromatic amine compound and a composite material including a hole-transport material and an acceptor material (electron-accepting material).

As the hole-transport material, any of after-mentioned substances each having a high hole-transport property that can be used for a hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferred because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the substance having a high hole-injection property, a material containing a hole-transport material and the above-described oxide of a metal belonging to Group 4 to Group 8 of the periodic table (typically, molybdenum oxide) may be used, for example.

The hole-transport layer transports holes injected from the anode by the hole-injection layer, to the light-emitting layer. The hole-transport layer includes a hole-transport material. The hole-transport material is preferably a substance having a hole mobility higher than or equal to 1×10⁻⁶ cm²/Vs. Note that other substances can also be used as long as the substances have a hole-transport property higher than an electron-transport property. As the hole-transport material, substances having a high hole-transport property, such as a n-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer having a hole-transport property and including a material that can block an electron. Among the above-described hole-transport materials, a material having an electron-blocking property can be used for the electron-blocking layer.

The electron-blocking layer has a hole-transport property, and thus can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer includes an electron-transport material. The electron-transport material is preferably a substance having an electron mobility higher than or equal to 1×10⁻⁶ cm²/Vs. Note that other substances can also be used as long as the substances have an electron-transport property higher than a hole-transport property. As the electron-transport material, any of the following substances having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a x-electron deficient heteroaromatic compound such as a nitrogen-containing heteroaromatic compound.

The hole-blocking layer is provided in contact with the light-emitting layer. The hole-blocking layer is a layer having an electron-transport property and including a material that can block a hole. Among the above-described electron-transport materials, a material having a hole-blocking property can be used for the hole-blocking layer.

The hole-blocking layer has an electron-transport property, and thus can also be referred to as an electron-transport layer. Among electron-transport layers, a layer having a hole-blocking property can also be referred to as a hole-blocking layer.

The electron-injection layer injects electrons from the cathode to the electron-transport layer and includes a substance having a high electron-injection property. As the substance having a high electron-injection property, an alkali metal, an alkaline earth metal, or a compound thereof can be used. As the substance having a high electron-injection property, a composite material including an electron-transport material and a donor material (electron-donating material) can also be used.

The lowest unoccupied molecular orbital (LUMO) level of the substance having a high electron-injection property preferably has a small difference (specifically, 0.5 eV or less) from the work function of a material used for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material. For example, the charge-generation region preferably includes the above-described hole-transport material and acceptor material that can be used for the hole-injection layer.

The charge-generation layer preferably includes a layer including a substance having a high electron-injection property. The layer can also be referred to as an electron-injection buffer layer. The electron-injection buffer layer is preferably provided between the charge-generation region and the electron-transport layer. The electron-injection buffer layer can reduce an injection barrier between the charge-generation region and the electron-transport layer; thus, electrons generated in the charge-generation region can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, and further preferably includes an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer including a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) to transfer electrons smoothly.

For the electron-relay layer, a phthalocyanine-based material such as copper (II) phthalocyanine (abbreviation: CuPc), or a metal complex having a metal-oxygen bond and an aromatic ligand is preferably used.

Note that the charge-generation region, the electron-injection buffer layer, and the electron-relay layer cannot be clearly distinguished from one another on the basis of the cross-sectional shape or properties in some cases.

The charge-generation layer may contain a donor material instead of an acceptor material. For example, the charge-generation layer may include a layer including the above-described electron-transport material and donor material that can be used for the electron-injection layer.

When the charge-generation layer is provided between two light-emitting units to be stacked, an increase in driving voltage can be inhibited.

The structure described in this embodiment can be used in an appropriate combination with any of the structures described in the other embodiments.

### Embodiment 4

In this embodiment, a structure example of the light-emitting device 61 that achieves full-color display in the display apparatus 50 will be described.

A plurality of light-emitting devices 61 provided in the display portion 235 of the display apparatus 50 can be obtained by a photolithography method without a shadow mask such as a metal mask. Accordingly, a high-definition display apparatus with a high aperture ratio, which had been difficult to achieve, can be fabricated. Moreover, a leakage current between adjacent EL layers is reduced; thus, a display apparatus with a high contrast and high display quality can be fabricated.

Although it is difficult to set the distance between adjacent light-emitting devices 61 to be less than 10 μm by a formation method using a metal mask, for example, a photolithography method can shorten the distance to be less than or equal to 8 μm, less than or equal to 3 μm, less than or equal to 2 μm, or less than or equal to 1 μm. Here, the distance between adjacent light-emitting devices 61 can be determined by the distance between end portions of two adjacent pixel electrodes. Alternatively, the distance between adjacent light-emitting devices 61 can be determined by the distance between end portions of two adjacent EL layers.

In this specification and the like, a display apparatus formed using a metal mask or an FMM (fine metal mask, high-definition metal mask) may be referred to as a display apparatus having an MM (metal mask) structure. In this specification and the like, a display apparatus formed without using a metal mask or an FMM may be referred to as a display apparatus having an MML (metal maskless) structure.

By shortening the distance between adjacent light-emitting devices 61 in the above manner, the area of a non-light-emitting region that may exist between two light-emitting devices can be significantly reduced, and the aperture ratio can be close to 100%. For example, the aperture ratio is higher than or equal to 50%, higher than or equal to 60%, higher than or equal to 70%, higher than or equal to 80%, or higher than or equal to 90%; that is, an aperture ratio lower than 100% can be achieved.

Furthermore, a pattern (also referred to as a processing size) of the EL layer itself can be made much smaller than that in the case of using a metal mask. For example, in the case of using a metal mask for forming EL layers separately, a variation in the thickness occurs between the center and the edge of the EL layer. This causes a reduction in an effective area that can be used as a light-emitting region with respect to the area of the EL layer. In contrast, in the above manufacturing method, an EL layer is formed by processing a film formed to have a uniform thickness, which enables a uniform thickness in the EL layer. Thus, even in a fine pattern, almost the whole area can be used as a light-emitting region. Therefore, the above manufacturing method makes it possible to achieve high definition and a high aperture ratio.

In many cases, an organic film formed using an FMM (Fine Metal Mask) has an extremely small taper angle (e.g., a taper angle of greater than 0° and less than) 30° so that the thickness of the film becomes smaller in a portion closer to an end portion. Therefore, it is difficult to clearly observe the side surface of an organic film formed using an FMM because the side surface and the top surface are continuously connected. In contrast, an EL layer included in one embodiment of the present invention is processed without using an FMM, and has a clear side surface. In particular, part of the taper angle of the EL layer included in one embodiment of the present invention is preferably greater than or equal to 30° and less than or equal to 120°, further preferably greater than or equal to 60° and less than or equal to 120°.

Note that in this specification and the like, an end portion of an object having a tapered shape indicates that the end portion of the object has a cross-sectional shape in which the angle between the side surface (the surface) of the object and the formation surface (the bottom surface) of the object is greater than 0° and less than 90° in a region of the end portion, and the thickness continuously increases from the end portion. A taper angle refers to an angle between a bottom surface (a formation surface) and a side surface (a surface) at an end portion of the object.

A more specific structure example is described below.

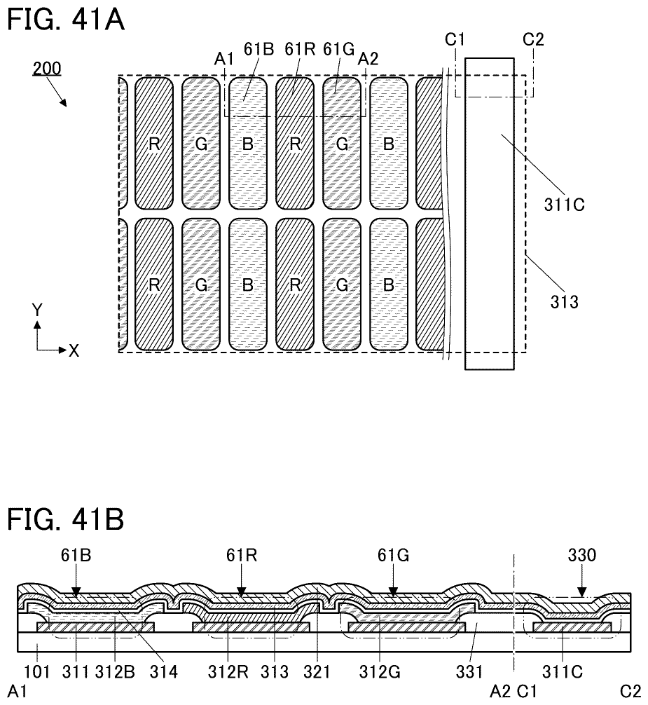

FIG. 41A is a schematic top view of part of the display portion 235 included in the display apparatus 50. The display apparatus 50 includes a plurality of light-emitting devices 61R that emit red light, a plurality of light-emitting devices 61G that emit green light, and a plurality of light-emitting devices 61B that emit blue light over a substrate 101 provided with a semiconductor circuit. In FIG. 41A, light-emitting regions of the light-emitting devices are denoted by R, G, and B to easily differentiate the light-emitting devices. Note that the substrate 101 is a substrate over which the semiconductor device described in the above embodiment is formed and the description of the above embodiment can be referred to for the details. Note that FIG. 41 does not illustrate the semiconductor device provided over the substrate 101.

The light-emitting devices 61R, the light-emitting devices 61G, and the light-emitting devices 61B are arranged in a stripe pattern. In FIG. 41A, two elements are alternately arranged in one direction. Note that the arrangement method of the light-emitting devices is not limited thereto; another method such as S-stripe arrangement, delta arrangement, Bayer arrangement, or zigzag arrangement may be employed, or PenTile arrangement, diamond arrangement, or the like can also be employed.

FIG. 41A illustrates a connection electrode 311C that is electrically connected to a common electrode 313. The connection electrode 311C is supplied with a potential (e.g., an anode potential or a cathode potential) that is to be supplied to the common electrode 313. The connection electrode 311C is provided outside a display region where the light-emitting devices 61R and the like are arranged. In FIG. 41A, the common electrode 313 is denoted by a dashed line.

The connection electrode 311C can be provided along the outer periphery of the display region. For example, the connection electrode 311C may be provided along one side of the outer periphery of the display region or two or more sides of the outer periphery of the display region. That is, in the case where the display region has a rectangular top surface, the top surface of the connection electrode 311C can have a band shape, an L shape, a square bracket shape, a quadrangular shape, or the like.

FIG. 41B is a schematic cross-sectional view taken along the dashed-dotted line A1-A2 and the dashed-dotted line C1-C2 in FIG. 41A. FIG. 41B is a schematic cross-sectional view of the light-emitting device 61B, the light-emitting device 61R, the light-emitting device 61G, and the connection electrode 311C.

The light-emitting device 61B includes a pixel electrode 311, an organic layer 312B, an organic layer 314, and the common electrode 313. The light-emitting device 61R includes the pixel electrode 311, an organic layer 312R, the organic layer 314, and the common electrode 313. The light-emitting device 61G includes the pixel electrode 311, an organic layer 312G, the organic layer 314, and the common electrode 313. The organic layer 314 and the common electrode 313 are shared by the light-emitting device 61B, the light-emitting device 61R, and the light-emitting device 61G. The organic layer 314 can also be referred to as a common layer. The pixel electrodes 311 are provided apart from each other between the light-emitting devices and between the light-emitting device and the light-receiving device.

The organic layer 312R, the organic layer 312G, and the organic layer 312B each correspond to the EL layer 763 of the above embodiment.

The organic layer 312R contains at least a light-emitting organic compound that emits red light. The organic layer 312G contains at least a light-emitting organic compound that emits green light. The organic layer 312B contains at least a light-emitting organic compound that emits blue light. Each of the organic layer 312R, the organic layer 312G, and the organic layer 312B can also be referred to as an EL layer.

The organic layer 312R, the organic layer 312B, and the organic layer 312G may each include one or more of an electron-injection layer, an electron-transport layer, a hole-injection layer, and a hole-transport layer. The organic layer 314 does not necessarily include the light-emitting layer. For example, the organic layer 314 includes one or more of an electron-injection layer, an electron-transport layer, a hole-injection layer, and a hole-transport layer.

Here, the uppermost layer in the stacked-layer structure of each of the organic layer 312R, the organic layer 312B, and the organic layer 312G, i.e., the layer in contact with the organic layer 314 is preferably a layer other than the light-emitting layer. For example, a structure is preferable in which an electron-injection layer, an electron-transport layer, a hole-injection layer, a hole-transport layer, or a layer other than those covers the light-emitting layer so as to be in contact with the organic layer 314. When the top surface of the light-emitting layer is protected by another layer in manufacturing each light-emitting device, the reliability of the light-emitting device can be improved.

By processing the EL layers by a photolithography method, the distance between pixels can be shortened to less than or equal to 8 μm, less than or equal to 3 μm, less than or equal to 2 μm, or less than or equal to 1 μm. Here, the distance between pixels can be determined by the distance between opposite end portions of the organic layer 312B and the organic layer 312R, the distance between opposite end portions of the organic layer 312B and the organic layer 312G, and the distance between opposite end portions of the organic layer 312R and the organic layer 312G, for example. Alternatively, the distance between pixels can be determined by the distance between opposite end portions of adjacent EL layers for the same color. Alternatively, the distance between pixels can be determined by the distance between opposite end portions of the adjacent pixel electrodes 311. The distance between pixels is shortened in this manner, whereby a display apparatus with high definition and a high aperture ratio can be provided.

The pixel electrode 311 is provided for each element. The common electrode 313 and the organic layer 314 are provided as continuous layers common to the light-emitting devices. A conductive film that transmits visible light is used for either the respective pixel electrodes or the common electrode 313, and a reflective conductive film is used for the other. When the respective pixel electrodes transmit light and the common electrode 313 reflects light, a bottom-emission display apparatus is obtained. When the respective pixel electrodes reflect light and the common electrode 313 transmits light, a top-emission display apparatus is obtained. Note that when both the respective pixel electrodes and the common electrode 313 transmit light, a dual-emission display apparatus can be obtained.

The pixel electrode 311 is electrically connected to a transistor provided in a semiconductor circuit of the substrate 101. The transistor provided on the substrate 101 has a reduced channel length and is miniaturized as described in the above embodiment. For this reason, even when the display apparatus has high definition and the pixel area is reduced, the pixel circuit can be disposed in the reduced pixel area.

The insulating layer 331 is provided to cover end portions of the pixel electrode 311. The end portions of the insulating layer 331 preferably have tapered shapes. Note that in this specification and the like, an end portion of an object having a tapered shape indicates that the end portion of the object has a cross-sectional shape in which the angle between a surface of the object and a formation surface of the object is greater than 0° and less than 90° in a region of the end portion, and the thickness continuously increases from the end portion.

When an organic resin is used for the insulating layer 331, a surface of the insulating layer 331 can be moderately curved. Thus, coverage with a film formed over the insulating layer 331 can be improved.

Examples of materials that can be used for the insulating layer 331 include an acrylic resin, a polyimide resin, an epoxy resin, a polyamide resin, a polyimide-amide resin, a siloxane resin, a benzocyclobutene-based resin, a phenol resin, and precursors of these resins.

Alternatively, an inorganic insulating material may be used for the insulating layer 331. Examples of inorganic insulating materials that can be used for the insulating layer 331 include an oxide, a nitride oxide, an oxynitride, and a nitride, such as silicon oxide, silicon oxynitride, silicon nitride oxide, silicon nitride, aluminum oxide, aluminum oxynitride, and hafnium oxide. Yttrium oxide, zirconium oxide, gallium oxide, tantalum oxide, magnesium oxide, lanthanum oxide, cerium oxide, neodymium oxide, or the like may also be used.

As illustrated in FIG. 41B, there are gaps between two organic layers of light-emitting devices that emit light of different colors and between two organic layers of the light-emitting device and the light-receiving device, and the two organic layers are provided apart from each other. The organic layer 312R, the organic layer 312B, and the organic layer 312G are thus preferably provided so as not to be in contact with each other. This favorably prevents unintentional light emission from being caused by a current flowing through adjacent two organic layers. As a result, the contrast can be increased to achieve a display apparatus with high display quality.

The organic layer 312R, the organic layer 312B, and the organic layer 312G each preferably have a taper angle of greater than or equal to 30°. In an end portion of each of the organic layer 312R, the organic layer 312G, and the organic layer 312B, the angle between the side surface (the surface) of the layer and the bottom surface (the formation surface) of the layer is preferably greater than or equal to 30° and less than or equal to 120°, further preferably greater than or equal to 45° and less than or equal to 120°, still further preferably greater than or equal to 60° and 120°. Alternatively, the organic layer 312R, the organic layer 312G, and the organic layer 312B each preferably have a taper angle of 90° or the neighborhood thereof (greater than or equal to 80° and less than or equal to 100°, for example).

A protective layer 321 is provided over the common electrode 313. The protective layer 321 has a function of preventing diffusion of impurities such as water into each light-emitting device from the above.

The protective layer 321 can have, for example, a single-layer structure or a stacked-layer structure including at least an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 321.

As the protective layer 321, a stacked film of an inorganic insulating film and an organic insulating film can be used. For example, a structure in which an organic insulating film is sandwiched between a pair of inorganic insulating films is preferable. Furthermore, it is preferable that the organic insulating film function as a planarization film. With this structure, the top surface of the organic insulating film can be flat, and accordingly, coverage with the inorganic insulating film over the organic insulating film is improved, leading to an improvement in a barrier property. Moreover, since the top surface of the protective layer 321 is flat, a preferable effect can be obtained; when a component (e.g., a color filter, an electrode of a touch sensor, or a lens array) is provided above the protective layer 321, the component is less affected by an uneven shape caused by the lower structure.

In the connection portion 330, the common electrode 313 is provided on and in contact with the connection electrode 311C, and the protective layer 321 is provided to cover the common electrode 313. In addition, the insulating layer 331 is provided to cover end portions of the connection electrode 311C.

A structure example of a display apparatus that is partly different from that in FIG. 41B is described below. Specifically, an example in which the insulating layer 331 is not provided is described.

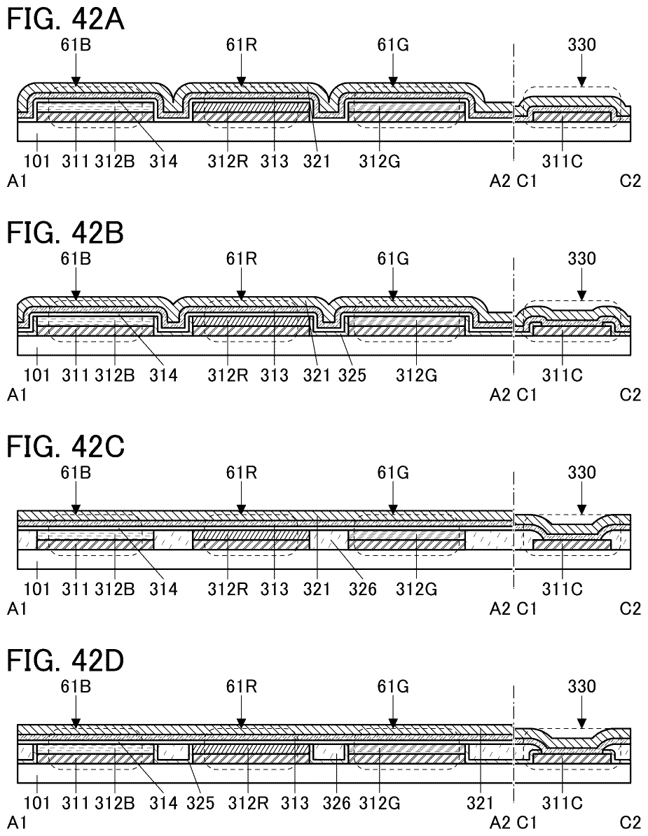

FIG. 42A to FIG. 42C show examples of the case where the side surface of the pixel electrode 311 is substantially aligned with the side surfaces of the organic layer 312R, the organic layer 312B, or the organic layer 312G.

In FIG. 42A, the organic layer 314 is provided to cover the top surfaces and the side surfaces of the organic layer 312R, the organic layer 312B, and the organic layer 312G. The organic layer 314 can prevent the pixel electrode 311 and the common electrode 313 from being in contact with each other and being electrically short-circuited.

FIG. 42B shows an example in which an insulating layer 325 is provided in contact with the side surfaces of the organic layer 312R, the organic layer 312B, the organic layer 312G, and the pixel electrode 311. The insulating layer 325 can prevent the pixel electrode 311 and the common electrode 313 from being electrically short-circuited and effectively inhibit a leakage current therebetween.

The insulating layer 325 can be an insulating layer including an inorganic material. For the insulating layer 325, an oxide, a nitride, an oxynitride, or a nitride oxide can be used, for example. The insulating layer 325 may have a single-layer structure or a stacked-layer structure. Examples of the oxide include silicon oxide, aluminum oxide, magnesium oxide, indium-gallium-zinc oxide, gallium oxide, germanium oxide, yttrium oxide, zirconium oxide, lanthanum oxide, neodymium oxide, hafnium oxide, and tantalum oxide. Examples of the nitride include silicon nitride and aluminum nitride. Examples of the oxynitride include silicon oxynitride and aluminum oxynitride. Examples of the nitride oxide include silicon nitride oxide and aluminum nitride oxide. In particular, when an aluminum oxide film, a hafnium oxide film, or a silicon oxide film formed by an ALD method is used as the insulating layer 325, the insulating layer 325 having few pin holes and an excellent function of protecting the organic layer can be formed.

The insulating layer 325 can be formed by a sputtering method, a CVD method, a PLD method, an ALD method, or the like. The insulating layer 325 is preferably formed by an ALD method achieving good coverage.

In FIG. 42C, resin layers 326 are provided between two adjacent light-emitting devices and between the light-emitting device and the light-receiving device so as to fill the gap between two facing pixel electrodes and the gap between two facing organic layers. The resin layer 326 can planarize the formation surface of the organic layer 314, the common electrode 313, and the like, which prevents disconnection of the common electrode 313 due to poor coverage in a step between adjacent light-emitting devices.

For the resin layer 326, for example, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the resin layer 326, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. Moreover, for the resin layer 326, a photosensitive resin can be used. A photoresist may be used as the photosensitive resin. As the photosensitive resin, a positive photosensitive material or a negative photosensitive material can be used.

A colored material (e.g., a material containing a black pigment) may be used for the resin layer 326 so that the resin layer 326 has a function of blocking stray light from an adjacent pixel and inhibiting color mixture.

In FIG. 42D, the insulating layer 325 and the resin layer 326 over the insulating layer 325 are provided. Since the insulating layer 325 prevents the organic layer 312R or the like from being in contact with the resin layer 326, impurities (e.g., water) included in the resin layer 326 can be prevented from being diffused into the organic layer 312R or the like, whereby a highly reliable display apparatus can be provided.

A reflective film (e.g., a metal film containing one or more of silver, palladium, copper, titanium, aluminum, and the like) may be provided between the insulating layer 325 and the resin layer 326 so that light emitted from the light-emitting layer is reflected by the reflective film; hence, the display apparatus may be provided with a function of increasing the light extraction efficiency.

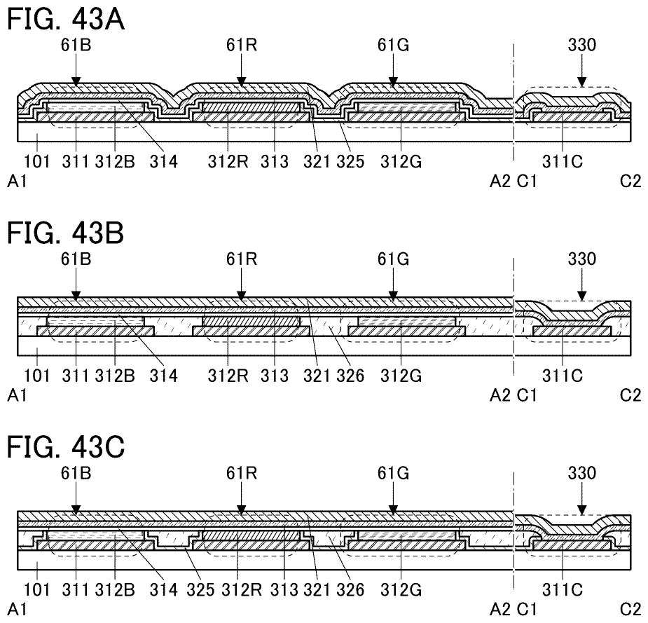

FIG. 43A to FIG. 43C show examples in which the width of the pixel electrode 311 is larger than the width of the organic layer 312R, the organic layer 312B, or the organic layer 312G. The organic layer 312R or the like is provided on the inner side than end portions of the pixel electrode 311.

FIG. 43A shows an example in which the insulating layer 325 is provided. The insulating layer 325 is provided to cover the side surfaces of the organic layers included in the light-emitting device and the light-receiving device and part of the top surface and the side surfaces of the pixel electrode 311.

FIG. 43B shows an example in which the resin layer 326 is provided. The resin layer 326 is positioned between two adjacent light-emitting devices or between the light-emitting device and the light-receiving device, and covers the side surfaces of the organic layers and the top surface and the side surfaces of the pixel electrode 311.

FIG. 43C shows an example in which both the insulating layer 325 and the resin layer 326 are provided. The insulating layer 325 is provided between the organic layer 312R or the like and the resin layer 326.

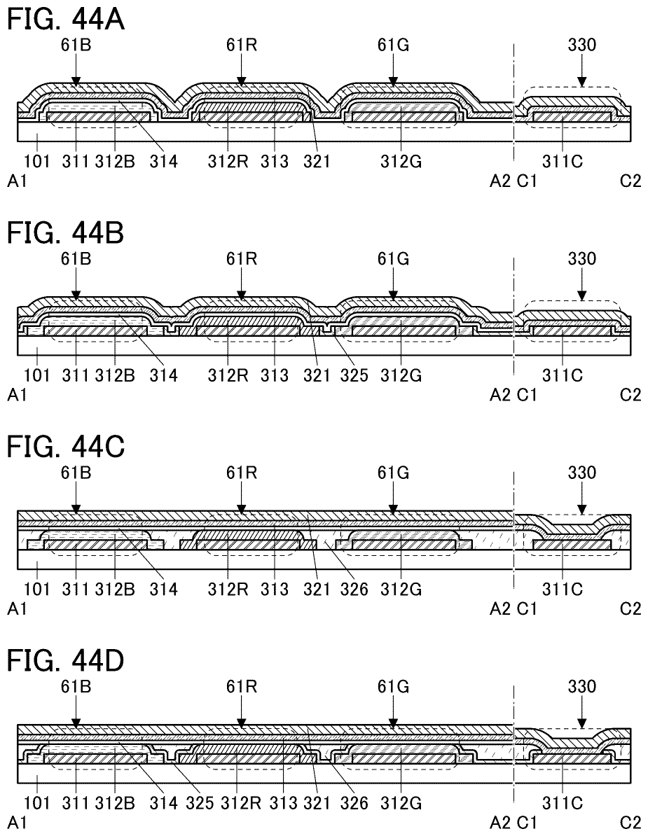

FIG. 44A to FIG. 44D show examples in which the width of the pixel electrode 311 is smaller than the width of the organic layer 312R, the organic layer 312B, or the organic layer 312G. The organic layer 312R or the like extends to an outer side beyond the end portions of the pixel electrode 311.

FIG. 44B shows an example in which the insulating layer 325 is provided. The insulating layer 325 is provided in contact with the side surfaces of the organic layers of two adjacent light-emitting devices. The insulating layer 325 may be provided to cover not only the side surface but also part of the top surface of the organic layer 312R or the like.

FIG. 44C shows an example in which the resin layer 326 is provided. The resin layer 326 is positioned between two adjacent light-emitting devices and covers the side surface and part of the top surface of the organic layer 312R or the like. The resin layer 326 may be formed to be in contact with the side surface of the organic layer 312R or the like and not to cover the top surface thereof.

FIG. 44D shows an example in which both the insulating layer 325 and the resin layer 326 are provided. The insulating layer 325 is provided between the organic layer 312R or the like and the resin layer 326.

Here, a structure example of the resin layer 326 is described.

The top surface of the resin layer 326 is preferably as flat as possible; however, the surface of the resin layer 326 may be depressed or projecting depending on an uneven shape of the formation surface of the resin layer 326, the formation conditions of the resin layer 326, or the like.

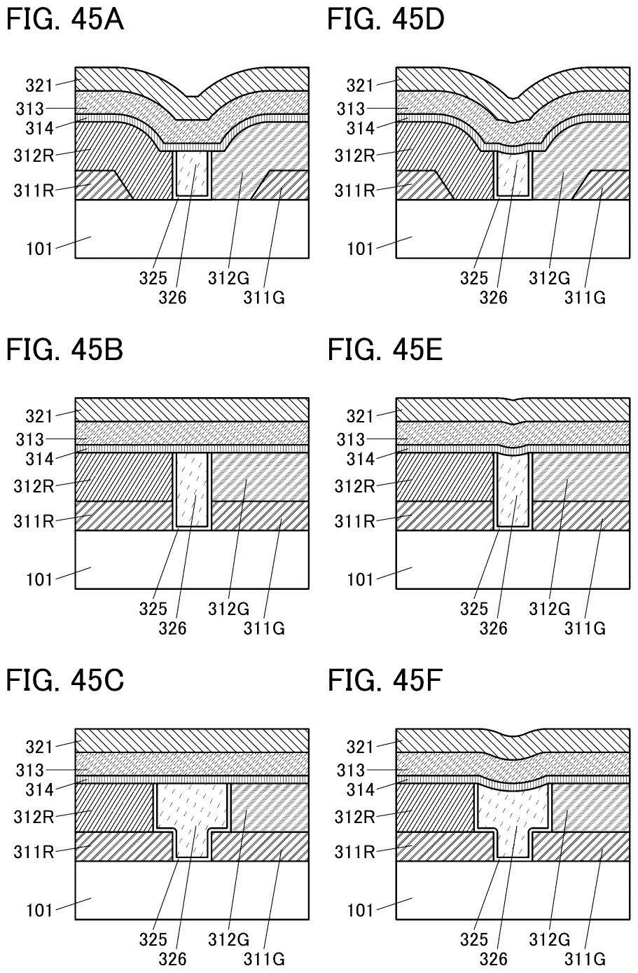

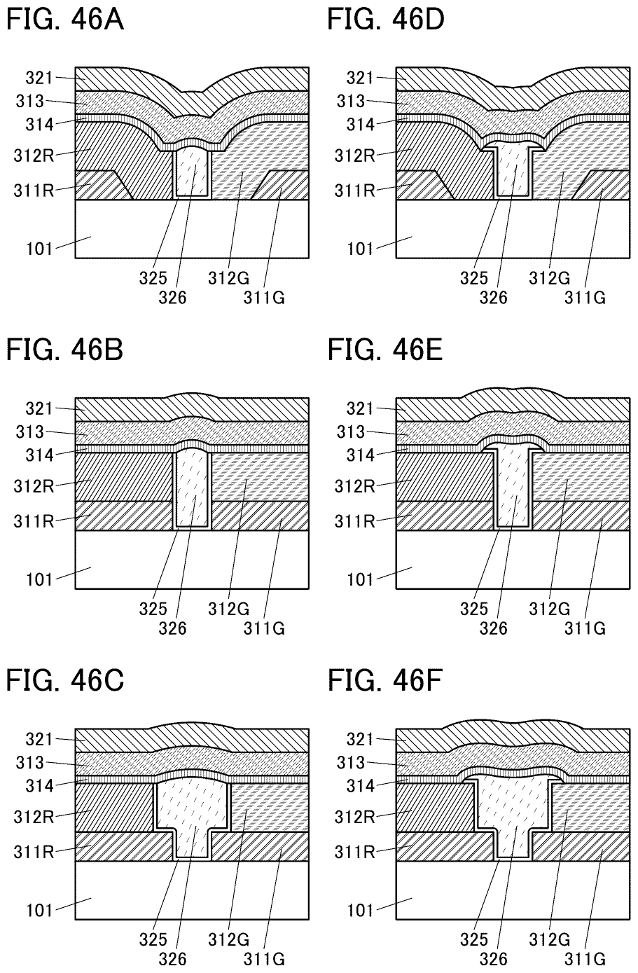

FIG. 45A to FIG. 46F are each an enlarged view of an end portion of the pixel electrode 311R included in the light-emitting device 61R, an end portion of the pixel electrode 311G included in the light-emitting device 61G, and the vicinity thereof.

FIG. 45A, FIG. 45B, and FIG. 45C are each an enlarged view of the resin layer 326 having a flat top surface and the vicinity thereof. FIG. 45A shows an example of the case where the organic layer 312R or the like has a larger width than the pixel electrode 311. FIG. 45B shows an example in which these widths are substantially the same. FIG. 45C shows an example of the case where the organic layer 312R or the like has a smaller width than the pixel electrode 311.

The organic layer 312R or the like is provided to cover the end portions of the pixel electrode 311 as illustrated in FIG. 45A, so that the end portion of the pixel electrode 311 preferably has a tapered shape. Accordingly, the step coverage with the organic layer 312R or the like is improved and a highly reliable display apparatus can be provided.

FIG. 45D, FIG. 45E, and FIG. 45F illustrate examples of the case where the top surface of the resin layer 326 has a depressed portion. Here, FIG. 45D corresponds to FIG. 45A, FIG. 45E corresponds to FIG. 45B, and FIG. 45F corresponds to FIG. 45C. In this case, a depressed portion that reflects the depressed top surface of the resin layer 326 is formed on each of the top surfaces of the organic layer 314, the common electrode 313, and the protective layer 321.

FIG. 46A, FIG. 46B, and FIG. 46C illustrate examples of the case where the top surface of the resin layer 326 has a projecting portion. Here, FIG. 46A corresponds to FIG. 45A, FIG. 46B corresponds to FIG. 45B, and FIG. 46C corresponds to FIG. 45C. In this case, a projecting portion that reflects the projecting top surface of the resin layer 326 is formed on each of the top surfaces of the organic layer 314, the common electrode 313, and the protective layer 321.

FIG. 46D, FIG. 46E, and FIG. 46F each illustrate an example of the case where part of the resin layer 326 covers an upper end portion and part of the top surface of the organic layer 312R and an upper end portion and part of the top surface of the organic layer 312G. Here, FIG. 46D corresponds to FIG. 45A, FIG. 46E corresponds to FIG. 45B, and FIG. 46F corresponds to FIG. 45C. Here, the insulating layer 325 is provided between the resin layer 326 and the top surfaces of the organic layer 312R and the organic layer 312G.

FIG. 46D, FIG. 46E, and FIG. 46F show examples of the case where the top surface of the resin layer 326 is partly depressed. In this case, unevenness that reflects the shape of the resin layer 326 is formed on each of the organic layer 314, the common electrode 313, and the protective layer 321.

The above is the description of the structure example of the resin layer.

The structure described in this embodiment can be used in an appropriate combination with any of the structures described in the other embodiments.

### Embodiment 5

In this embodiment, electronic devices in which the semiconductor device of one embodiment of the present invention can be used will be described.

The semiconductor device of one embodiment of the present invention can be used in a display portion of an electronic device. Thus, an electronic device with high display quality can be obtained. An electronic device with an extremely high definition can be obtained. A highly reliable electronic device can be obtained.

Examples of electronic devices including the semiconductor device or the like of one embodiment of the present invention include display apparatuses such as televisions and monitors, lighting devices, desktop or laptop personal computers, word processors, image reproduction devices which reproduce still images or moving images stored in recording media such as DVDs (Digital Versatile Discs), portable CD players, radios, tape recorders, headphone stereos, stereos, table clocks, wall clocks, cordless phone handsets, transceivers, car phones, cellular phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, tools such as chain saws, smoke detectors, and medical equipment such as dialyzers. Other examples include industrial equipment such as guide lights, traffic lights, conveyor belts, elevators, escalators, industrial robots, power storage systems, and power storage devices for leveling the amount of power supply and smart grid. In addition, moving objects and the like driven by fuel engines or electric motors using electric power from power storage units may also be included in the category of electronic devices. Examples of the moving objects include electric vehicles (EVs), hybrid electric vehicles (HVs) that include both an internal-combustion engine and a motor, plug-in hybrid electric vehicles (PHVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic device of one embodiment of the present invention may include a secondary battery (battery), and it is preferable that the secondary battery be capable of being charged by contactless power transmission.

Examples of the secondary battery include a lithium ion secondary battery, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, and the like on the display portion. When the electronic device includes an antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radioactive rays, flow rate, humidity, a gradient, oscillation, odor, or infrared rays).

The electronic device of one embodiment of the present invention can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Furthermore, an electronic device including a plurality of display portions can have a function of displaying image information mainly on one display portion while displaying text information mainly on another display portion, a function of displaying a three-dimensional image by displaying images on a plurality of display portions with a parallax taken into account, or the like. Furthermore, an electronic device including an image receiving portion can have a function of taking a still image or a moving image, a function of automatically or manually correcting a taken image, a function of storing a taken image in a recording medium (an external recording medium or a recording medium incorporated in the electronic device), a function of displaying a taken image on a display portion, or the like. Note that functions of the electronic device of one embodiment of the present invention are not limited thereto, and the electronic devices can have a variety of functions.

The semiconductor device of one embodiment of the present invention can display high-definition images. Thus, the semiconductor device of one embodiment of the present invention can be suitably used especially for a portable electronic device, a wearable electronic device (wearable device), an e-book reader, and the like. For example, the semiconductor device can be suitably used for xR devices such as a VR device and an AR device.

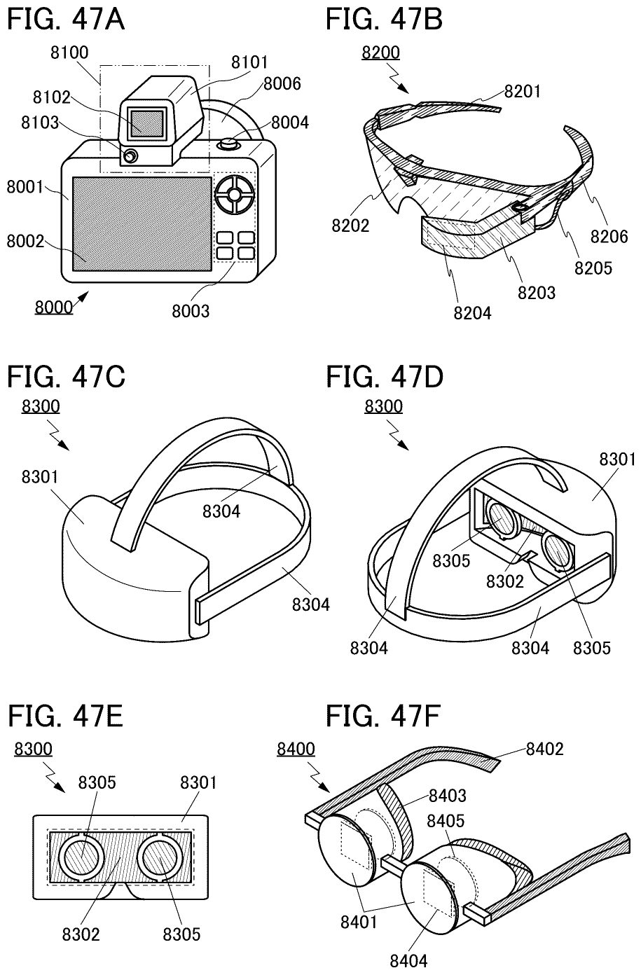

FIG. 47A is a diagram illustrating the appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000. Note that the lens 8006 and the housing may be integrated with each other in the camera 8000.

Images can be taken with the camera 8000 at the press of the shutter button 8004 or the touch of the display portion 8002 serving as a touch panel.

The housing 8001 includes a mount including an electrode, so that the finder 8100, a stroboscope, or the like can be connected to the housing 8001.

The finder 8100 includes a housing 8101, a display portion 8102, a button 8103, and the like.

The housing 8101 is attached to the camera 8000 with the mount engaging with a mount of the camera 8000. The finder 8100 can display, for example, a video received from the camera 8000 on the display portion 8102.

The button 8103 has a function of a power supply button or the like.

For example, the semiconductor device of one embodiment of the present invention can be used in the display portion 8002 of the camera 8000 and the display portion 8102 of the finder 8100. Note that the finder 8100 may be incorporated in the camera 8000.

FIG. 47B is a diagram illustrating the appearance of a head-mounted display 8200.

The head-mounted display 8200 includes a wearing portion 8201, a lens 8202, a main body 8203, a display portion 8204, a cable 8205, and the like. A battery 8206 is incorporated in the mounting portion 8201.

The cable 8205 supplies electric power from the battery 8206 to the main body 8203. The main body 8203 includes a wireless receiver or the like to receive image data and display it on the display portion 8204. The main body 8203 includes a camera, and data on the movement of eyeballs or eyelids of a user can be used as an input means.

The mounting portion 8201 may be provided with a plurality of electrodes capable of sensing a current flowing in response to the movement of the user's eyeball in a position in contact with the user to have a function of recognizing the user's sight line. Furthermore, the mounting portion 8201 may have a function of monitoring the user's pulse with use of the current flowing through the electrodes. The mounting portion 8201 may include sensors such as a temperature sensor, a pressure sensor, and an acceleration sensor so that the user's biological information can be displayed on the display portion 8204 and an image displayed on the display portion 8204 can be changed in accordance with the movement of the user's head.

The semiconductor device of one embodiment of the present invention can be used in the display portion 8204.

FIG. 47C to FIG. 47E are diagrams illustrating the appearance of a head-mounted display 8300. The head-mounted display 8300 includes a housing 8301, a display portion 8302, a band-like fixing member 8304, and a pair of lenses 8305.

A user can perceive display on the display portion 8302 through the lenses 8305. Note that the display portion 8302 is preferably placed in the curved state, in which case the user can feel a high realistic sensation. Another image displayed in another region of the display portion 8302 is viewed through the lenses 8305, so that three-dimensional display using parallax or the like can be performed. Note that the structure is not limited to the structure in which one display portion 8302 is provided; two display portions 8302 may be provided and one display portion may be provided per eye of the user.

The semiconductor device of one embodiment of the present invention can be used for the display portion 8302. The semiconductor device of one embodiment of the present invention can achieve extremely high definition. For example, a pixel is not easily seen by the user even when the user sees display that is magnified with use of the lenses 8305 as illustrated in FIG. 47E. In other words, a video with a strong sense of reality can be seen by the user with use of the display portion 8302.

FIG. 47F is a diagram illustrating the appearance of a goggle-type head-mounted display 8400. The head-mounted display 8400 includes a pair of housings 8401, a mounting portion 8402, and a cushion 8403. A display portion 8404 and a lens 8405 are provided in each of the pair of housings 8401. The pair of display portions 8404 may display different images, whereby three-dimensional display using parallax can be performed.

A user can see display on the display portion 8404 through the lens 8405. The lens 8405 has a focus adjustment mechanism and can adjust the position according to the user's eyesight. The display portion 8404 is preferably a square or a horizontal rectangle. This can improve a realistic sensation.

The mounting portion 8402 preferably has plasticity and elasticity so as to be adjusted to fit the size of the user's face and not to slide down. In addition, part of the mounting portion 8402 preferably has a vibration mechanism functioning as a bone conduction earphone. Thus, without additionally requiring an audio device such as earphones or a speaker, the user can enjoy video and sound only by wearing the head-mounted display 8400. Note that the housing 8401 may have a function of outputting sound data by wireless communication.

The mounting portion 8402 and the cushion 8403 are portions in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. Furthermore, when a sponge or the like whose surface is covered with cloth, leather (natural leather or synthetic leather), or the like is used, a gap is unlikely to be generated between the user's face and the cushion 8403, whereby light leakage can be suitably prevented. Furthermore, using such a material is preferable because it has a soft texture and the user does not feel cold when wearing the head-mounted display 8400 in a cold season, for example. The member to be in contact with the user's skin, such as the cushion 8403 or the wearing portion 8402, is preferably detachable, in which case cleaning or replacement can be easily performed.

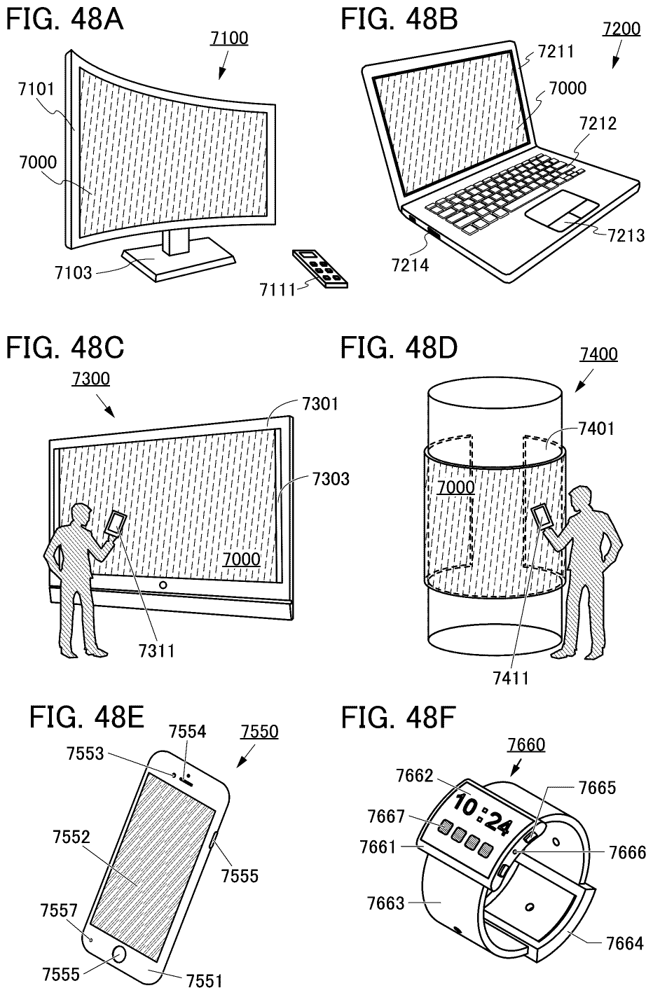

FIG. 48A illustrates an example of a television device. In a television device 7100, a display portion 7000 is incorporated in a housing 7101. Here, a structure in which the housing 7101 is supported by a stand 7103 is illustrated.

The semiconductor device of one embodiment of the present invention can be used for the display portion 7000.

Operation of the television device 7100 illustrated in FIG. 48A can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 48B illustrates an example of a laptop personal computer. The laptop personal computer 7200 includes a housing 7211, a keyboard 7212, a pointing device 7213, an external connection port 7214, and the like. In the housing 7211, the display portion 7000 is incorporated.

The semiconductor device of one embodiment of the present invention can be used for the display portion 7000.

FIG. 48C and FIG. 48D illustrate examples of digital signage.

Digital signage 7300 illustrated in FIG. 48C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 48D is digital signage 7400 attached to a cylindrical pillar 7401. The digital signage 7400 includes the display portion 7000 provided along a curved surface of the pillar 7401. In FIG. 48C and FIG. 48D, the semiconductor device of one embodiment of the present invention can be used for the display portion 7000.

The larger display portion 7000 can provide a larger amount of information at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 48C and FIG. 48D, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

An information terminal 7550 illustrated in FIG. 48E includes a housing 7551, a display portion 7552, a microphone 7557, a speaker portion 7554, a camera 7553, operation switches 7555, and the like. For example, the semiconductor device of one embodiment of the present invention can be used for the display portion 7552. The display portion 7552 has a function of a touch panel. The information terminal 7550 also includes an antenna, a battery, and the like inside the housing 7551. The information terminal 7550 can be used as, for example, a smartphone, a mobile phone, a tablet information terminal, a tablet personal computer, an e-book reader, or the like.

FIG. 48F illustrates an example of a watch-type information terminal. An information terminal 7660 includes a housing 7661, a display portion 7662, a band 7663, a buckle 7664, an operation switch 7665, an input/output terminal 7666, and the like. In addition, the information terminal 7660 includes an antenna, a battery, and the like inside the housing 7661. The information terminal 7660 is capable of executing a variety of applications such as mobile phone calls, e-mailing, viewing and editing texts, music reproduction, Internet communication, and a computer game.

The display portion 7662 includes a touch sensor, and operation can be performed by touching the screen with a finger, a stylus, or the like. For example, with a touch on an icon 7667 displayed on the display portion 7662, an application can be started. The operation switches 7665 can have a variety of functions such as time setting, power on/off operation, on/off operation of wireless communication, setting and cancellation of a silent mode, and setting and cancellation of a power saving mode. For example, the functions of the operation switches 7665 can be set by the operation system incorporated in the information terminal 7660.

The information terminal 7660 can execute near field communication conformable to a communication standard. For example, mutual communication between the information terminal 7660 and a headset capable of wireless communication enables hands-free calling. The information terminal 7660 includes an input/output terminal 7666, and can perform data transmission and reception with another information terminal through the input/output terminal 7666. In addition, charging can be performed via the input/output terminal 7666. Note that the charging operation may be performed by wireless power feeding without using the input/output terminal 7666.

The structure described in this embodiment can be used in combination as appropriate with any of the structures described in the other embodiments and Example.

### Example

In this example, transistors of one embodiment of the present invention were fabricated and their electrical characteristics were evaluated.

In this example, the semiconductor devices 30 illustrated in FIG. 15A and the like and the semiconductor devices 40 illustrated in FIG. 19A and the like were fabricated as samples. The number (p) of transistors 100 connected in parallel was varied between the semiconductor devices 30. The number (g) of transistors 100 connected in series was varied between the semiconductor devices 40. A semiconductor device in which transistors were connected in series and parallel was also fabricated.

The top-view shapes of the opening 141 and the opening 143 were circular in each of the transistors 100 connected in series, parallel, or series and parallel. The width D143 of the opening 143 was approximately 2 μm.

### <Fabrication of Sample>

First, an approximately 100-nm-thick titanium film over the substrate 102 and an approximately 50-nm-thick In—Sn—Si oxide (ITSO) film over the titanium film were formed by a sputtering method, and then processed to form the conductive layer 112a. A glass substrate was used as the substrate 102.

Next, an approximately 150-nm-thick silicon nitride film was formed as the insulating film 110af, and an approximately 500-nm-thick silicon oxynitride film was formed as the insulating film 110bf.

Next, an approximately 20-nm-thick metal oxide layer was formed as the metal oxide layer 149 over the insulating film 110bf. The metal oxide layer was formed by a sputtering method using an IGZO sputtering target with an atomic ratio of metal elements of In:Ga:Zn=1:1:1. Next, heat treatment was performed at 250° C. in a dry air atmosphere for one hour. An oven apparatus was used for the heat treatment.

Next, the metal oxide layer 149 was removed. The metal oxide layer 149 was removed by a wet etching method.

Next, an approximately 170-nm-thick silicon nitride film was formed as the insulating film 110cf over the insulating film 110bf.

Then, an approximately 100-nm-thick In—Sn—Si oxide (ITSO) film was formed as the conductive film 112f over the insulating film 110bf by a sputtering method.

Then, the conductive film 112f was processed to obtain the conductive layer 112B.

Next, the conductive layer 112B in a region overlapping with the conductive layer 112a was removed to form the conductive layer 112b having the opening 143, and the insulating film 110af, the insulating film 110bf, and the insulating film 110cf in a region overlapping with the conductive layer 112a were removed to form the insulating layer 110 having the opening 141.

The conductive layer 112B was removed by a wet etching method. The insulating film 110af, the insulating film 110bf, and the insulating film 110cf were removed by a dry etching method.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1.

Next, heat treatment was performed at 350° C. in a dry air atmosphere for one hour. An oven apparatus was used for the heat treatment.

Then, the metal oxide film 108f was processed to obtain the semiconductor layer 108.

Next, an approximately 50-nm thick silicon oxynitride film was formed as the insulating layer 106 by a plasma CVD method.

Next, an approximately 50-nm-thick titanium film, an approximately 200-nm-thick aluminum film, and an approximately 50-nm-thick titanium film were each formed by a sputtering method. After that, the conductive films were processed to obtain the conductive layer 104.

In this manner, the transistor was formed.

Next, an approximately 300-nm-thick silicon nitride oxide film was formed by a plasma CVD method as a protective layer of the transistor.

Next, heat treatment was performed at 300° C. in a dry air atmosphere for one hour. An oven apparatus was used for the heat treatment.

Then, an approximately 1.5-μm-thick polyimide film was formed.

Next, heat treatment was performed at 250° C. in a nitrogen atmosphere for one hour. An oven apparatus was used for the heat treatment.

Through the above process, the samples were obtained.

### <Electrical Characteristics of Transistor 1>

Then, the Id-Vg characteristics of the transistors of the samples fabricated above were measured.

For measuring the Id-Vg characteristics of the transistors, a voltage applied to the gate electrode (hereinafter also referred to as gate voltage (Vg)) was applied from −3 V to +3 V in increments of 0.1 V. A voltage applied to the source electrode (hereinafter also referred to as source voltage (Vs)) was 0 V (comm). A voltage applied to the drain electrode (hereinafter also referred to as drain voltage (Vd)) was 1 V, 2 V, 3 V, 5 V, 10 V, and 15 V. Note that the lower measurement limit of a drain current (Id) was approximately 1×10⁻¹³ A.

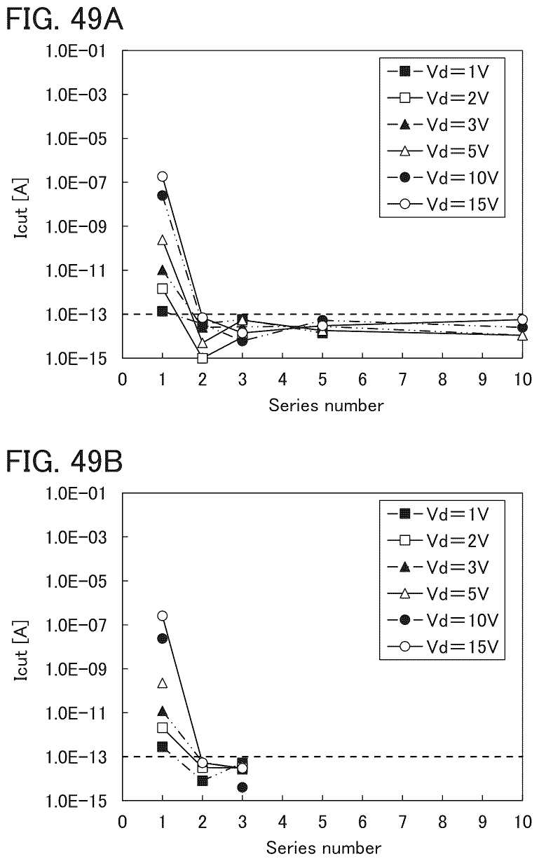

FIG. 49A shows drain currents (Id) at a gate voltage (Vg) of 0 V (hereinafter referred to as Icut) in the case where the number of transistors connected in parallel (hereinafter referred to as a parallel number) was 1 and the number of transistors connected in series (hereinafter referred to as a series number) was varied. In FIG. 49A, the horizontal axis represents the series number, and the vertical axis represents Icut. In FIG. 49A, the lower measurement limit is denoted by a dashed line. It was confirmed that when the series number was two or more, Icut was small as shown in FIG. 49A. It was also confirmed that even in the case where the drain voltage (Vd) was set to 15 V, i.e., made high, Icut was approximately 1×10⁻¹³ A, which was the lower measurement limit.

FIG. 49B shows Icut in the case where the parallel number was 10 and the series number was varied. In FIG. 49B, the horizontal axis represents the series number, and the vertical axis represents Icut. It was confirmed that when the series number was two or more, Icut was small as shown in FIG. 49B, even though the parallel number was increased. It was confirmed that also in the case where the drain voltage (Vd) was set to 15 V, i.e., made high, Icut was approximately 1×10⁻¹³ A, which was the lower measurement limit.

### <Electrical Characteristics of Transistor 2>

A change in the Id-Vg characteristics of the samples before and after the application of a high drain voltage (Vd) was evaluated. Specifically, the first Id-Vg characteristics were measured firstly, the gate voltage (Vg) was set to 0 V, the drain voltage (Vd) was swept from 0 V to 15 V, and then the second Id-Vg characteristics were measured. For the measurement of the Id-Vg characteristics, the gate voltage (Vg) was applied from −3 V to +3 V in increments of 0.1 V. In addition, the source voltage (Vs) was 0 V (comm), and the drain voltage (Vd) was 0.1 V and 1.2 V.

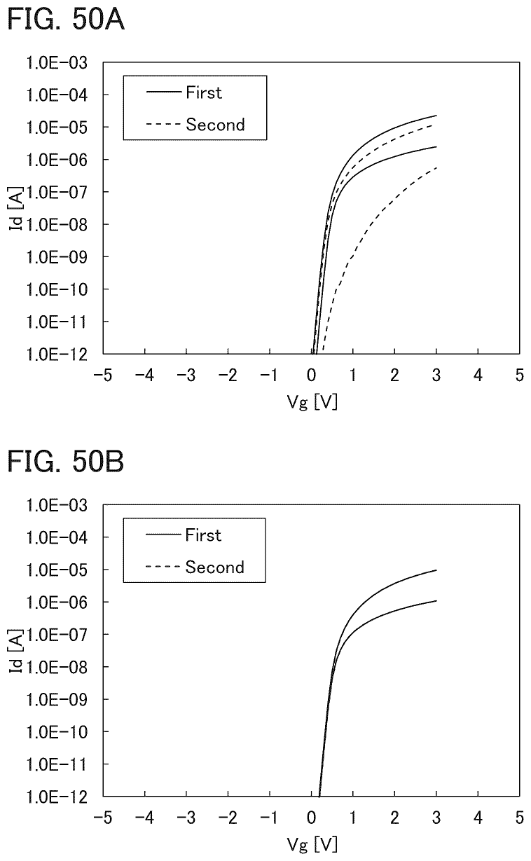

FIG. 50A shows the Id-Vg characteristics in the case where the series number was 1 and the parallel number was 1. FIG. 50B shows the Id-Vg characteristics in the case where the series number was 2 and the parallel number was 1. In each of FIG. 50A and FIG. 50B, the horizontal axis represents the gate voltage (Vg), and the vertical axis represents the drain current (Id). In addition, the first Id-Vg characteristics are denoted by solid lines, and the second Id-Vg characteristics are denoted by dashed lines.

It was confirmed that in the case where the series number was 1, the Id-Vg characteristics changed as shown in FIG. 50A. As described above, Icut was higher in the case where the series number was 1 than in the case where the series number was 2; thus, it can be considered that application of a high drain voltage (Vd) at a gate voltage (Vg) of 0 V caused hot-carrier degradation, leading to a change in Id-Vg characteristics. Meanwhile, it was confirmed that in the case where the series number was 2, the Id-Vg characteristics hardly changed as shown in FIG. 50B. As described above, in the case where the series number was 2, Icut was low; thus, it can be considered that hot-carrier degradation was inhibited and high reliability was exhibited.

### <Electrical Characteristics of Transistor 3>

The Id-Vg characteristics of the transistors of the samples were measured, and the on-state currents of the transistors were evaluated.

For the measurement of the Id-Vg characteristics of the transistors, the gate voltage (Vg) was applied from −3 V to +3 V in increments of 0.1 V. In addition, the source voltage (Vs) was 0 V (comm), and the drain voltage (Vd) was 1.2 V.

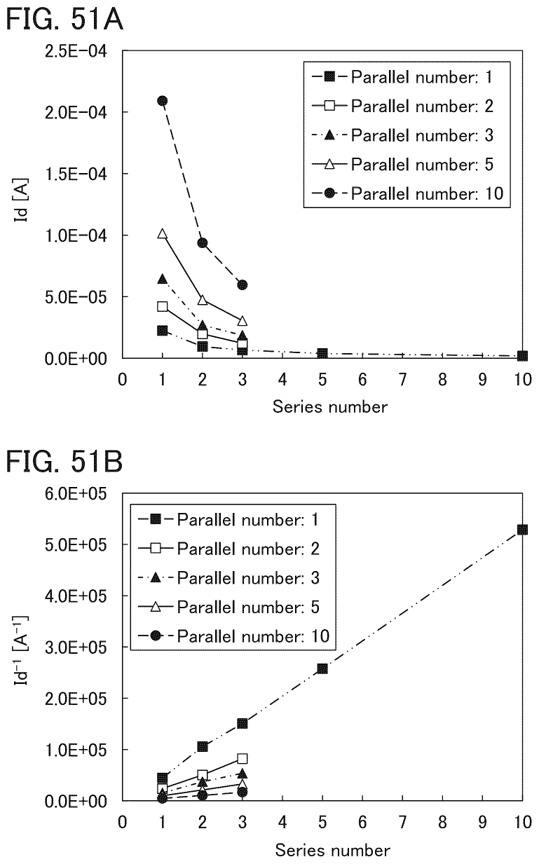

FIG. 51A shows drain currents (Id) at a gate voltage (Vg) of 3 V. In FIG. 51A, the horizontal axis represents the series number, and the vertical axis represents the drain current (Id). FIG. 51B shows correlations between the series number and the inverse of the drain current (Id). In FIG. 51B, the horizontal axis represents the series number, and the vertical axis represents the inverse of the drain current (Id).

As shown in FIG. 51A and FIG. 51B, it was confirmed that as the series number was larger, the on-state current was lower, that is, the inverse of the on-state current was proportional to the series number. It was also confirmed that by increasing the parallel number, the on-state current was increased.

As described above, it was confirmed in this example that by changing the number of transistors connected in series, connected in parallel, or connected in series and parallel, electrical characteristics and reliability were varied. Accordingly, it was confirmed that a connection method and the number of connected transistors can be selected depending on electrical characteristics and reliability required for the transistors.

### REFERENCE NUMERALS

ANO: wiring, C31: capacitor, C41: capacitor, GL: wiring, INV: inverter circuit, LAT: latch circuit, LIN: terminal, ROUT: terminal, SL: wiring, SMP: terminal, Tr31: transistor, Tr33: transistor, Tr35: transistor, Tr36: transistor, Tr41: transistor, Tr43: transistor, Tr45: transistor, Tr47: transistor, VCOM: wiring, 10A: semiconductor device, 10B: semiconductor device, 10C: semiconductor device, 10: semiconductor device, 20: semiconductor device, 30: semiconductor device, 40: semiconductor device, 50A: display apparatus, 50: display apparatus, 51: pixel circuit, 52A: transistor, 52B: transistor, 53: capacitor, 61B: light-emitting device, 61G: light-emitting device, 61R: light-emitting device, 61: light-emitting device, 100_1: transistor, 100_2: transistor, 100_3: transistor, 100_4: transistor, 100_p: transistor, 100_q: transistor, 100A: transistor, 100: transistor, 101: substrate, 102: substrate, 104: conductive layer, 106: insulating layer, 108_1: semiconductor layer, 108_2: semiconductor layer, 108_3: semiconductor layer, 108_4: semiconductor layer, 108f: metal oxide film, 108: semiconductor layer, 110a: insulating layer, 110af: insulating film, 110b: insulating layer, 110bf: insulating film, 110c: insulating layer, 110cf: insulating film, 110f: insulating film, 110: insulating layer, 111B: pixel electrode, 111G: pixel electrode, 111R: pixel electrode, 111: pixel electrode, 112a: conductive layer, 112a_1: conductive layer, 112a_2: conductive layer, 112a_2A: conductive layer, 112B: conductive layer, 112b: conductive layer, 112c: conductive layer, 112f: conductive film, 113B: layer, 113G: layer, 113R: layer, 113: layer, 114: common layer, 115: common electrode, 117: light-blocking layer, 118B: mask layer, 118G: mask layer, 118R: mask layer, 118: mask layer, 119B: mask layer, 119G: mask layer, 119R: mask layer, 119: mask layer, 123: conductive layer, 124B: conductive layer, 124G: conductive layer, 124p: conductive layer, 124q: conductive layer, 124R: conductive layer, 125: insulating layer, 126B: conductive layer, 126G: conductive layer, 126p: conductive layer, 126q: conductive layer, 126R: conductive layer, 127: insulating layer, 128: layer, 129B: conductive layer, 129G: conductive layer, 129p: conductive layer, 129q: conductive layer, 129R: conductive layer, 130B: light-emitting device, 130G: light-emitting device, 130R: light-emitting device, 130: light-emitting device, 131: protective layer, 140: connection portion, 141_1: opening, 141_2: opening, 141_3: opening, 141_4: opening, 141: opening, 142: adhesive layer, 143_1: opening, 143_2: opening, 143_3: opening, 143_4: opening, 143: opening, 145_1: opening, 145_2: opening, 145_3: opening, 145_4: opening, 145: opening, 149: metal oxide layer, 152: substrate, 153: insulating layer, 165: wiring, 166: conductive layer, 172: FPC, 173: IC, 195: insulating layer, 197: insulating layer, 200A: transistor, 200: transistor, 201: transistor, 204: conductive layer, 205G: transistor, 205R: transistor, 206: insulating layer, 208f: metal oxide film, 208: semiconductor layer, 210a: insulating layer, 210af: insulating film, 210b: insulating layer, 210bf: insulating film, 210c: insulating layer, 210cf: insulating film, 210f: insulating film, 210: insulating layer, 212a: conductive layer, 212a_1: conductive layer, 212a_2: conductive layer, 212B: conductive layer, 212b: conductive layer, 212f: conductive film, 214: connection portion, 230a: pixel, 230b: pixel, 230c: pixel, 230d: pixel, 230e: pixel, 230: pixel, 231: first driver circuit portion, 232: second driver circuit portion, 233: peripheral driver circuit, 235: display portion, 236: wiring, 237: wiring, 239: insulating layer, 240A: pixel, 240B: pixel, 240: pixel, 241: opening, 242: connection layer, 243: opening, 249: metal oxide layer, 311C: connection electrode, 311G: pixel electrode, 311R: pixel electrode, 311: pixel electrode, 312B: organic layer, 312G: organic layer, 312R: organic layer, 313: common electrode, 314: organic layer, 321: protective layer, 325: insulating layer, 326: resin layer, 330: connection portion, 331: insulating layer, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 7550: information terminal, 7551: housing, 7552: display portion, 7553: camera, 7554: speaker portion, 7555: operation switch, 7557: microphone, 7660: information terminal, 7661: housing, 7662: display portion, 7663: band, 7664: buckle, 7665: operation switch, 7666: input/output terminal, 7667: icon, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: mounting portion, 8202: lens, 8203: main body, 8204: display portion, 8205: cable, 8206: battery, 8300: head-mounted display, 8301: housing, 8302: display portion, 8304: fixing member, 8305: lens, 8400: head-mounted display, 8401: housing, 8402: wearing portion, 8403: cushion, 8404: display portion, 8405: lens

1. A semiconductor device comprising:
a first transistor, a second transistor, a first insulating layer, and a second insulating layer,
wherein the first transistor comprises a first semiconductor layer, a first conductive layer, a second conductive layer comprising a region overlapping with the first conductive layer with the first insulating layer therebetween, a third conductive layer, and a third insulating layer,
wherein the second conductive layer and the first insulating layer comprise a first opening reaching the first conductive layer,
wherein the first semiconductor layer is in contact with a top surface and a side surface of the second conductive layer, a side surface of the first insulating layer, and a top surface of the first conductive layer,
wherein the third insulating layer is provided over the first insulating layer, the first semiconductor layer, and the second conductive layer,
wherein the third conductive layer is provided over the third insulating layer,
wherein the second insulating layer is provided over the third conductive layer and the third insulating layer,
wherein the second transistor comprises a second semiconductor layer, the second conductive layer, a fourth conductive layer comprising a region overlapping with the second conductive layer with the second insulating layer and the third insulating layer therebetween, a fifth conductive layer, and a fourth insulating layer,
wherein the fourth conductive layer, the second insulating layer, and the third insulating layer comprise a second opening reaching the second conductive layer,
wherein the second semiconductor layer is in contact with a top surface and a side surface of the fourth conductive layer, a side surface of the second insulating layer, a side surface of the third insulating layer, and the top surface of the second conductive layer,
wherein the fourth insulating layer is provided over the second semiconductor layer,
wherein the fifth conductive layer is provided over the fourth insulating layer, and
wherein the first insulating layer comprises a stacked-layer structure of a fifth insulating layer and a sixth insulating layer over the fifth insulating layer.

2. (canceled)

3. A semiconductor device comprising:
a first transistor, a second transistor, a first insulating layer, and a second insulating layer,
wherein the first transistor comprises a first semiconductor layer, a first conductive layer, a second conductive layer comprising a region overlapping with the first conductive layer with the first insulating layer therebetween, a third conductive layer, and a third insulating layer,
wherein the second conductive layer and the first insulating layer comprise a first opening reaching the first conductive layer,
wherein the first semiconductor layer is in contact with a top surface and a side surface of the second conductive layer, a side surface of the first insulating layer, and a top surface of the first conductive layer,
wherein the third insulating layer is provided over the first insulating layer, the first semiconductor layer, and the second conductive layer,
wherein the third conductive layer is provided over the third insulating layer,
wherein the second insulating layer is provided over the third conductive layer and the third insulating layer,
wherein the second transistor comprises a second semiconductor layer, the third conductive layer, a fourth conductive layer comprising a region overlapping with the third conductive layer with the second insulating layer therebetween, a fifth conductive layer, and a fourth insulating layer,
wherein the fourth conductive layer and the second insulating layer comprise a second opening reaching the third conductive layer,
wherein the second semiconductor layer is in contact with a top surface and a side surface of the fourth conductive layer, a side surface of the second insulating layer, and a top surface of the third conductive layer,
wherein the fourth insulating layer is provided over the second semiconductor layer,
wherein the fifth conductive layer is provided over the fourth insulating layer, and
wherein the first insulating layer comprises a stacked-layer structure of a fifth insulating layer and a sixth insulating layer over the fifth insulating layer.

4. (canceled)

5. The semiconductor device according to claim 1,
wherein the first insulating layer comprises a seventh insulating layer,
wherein the seventh insulating layer is positioned between the fifth insulating layer and the first conductive layer, and
wherein the seventh insulating layer comprises a region having a higher film density than the fifth insulating layer.

6. The semiconductor device according to claim 1,
wherein the first insulating layer comprises a seventh insulating layer,
wherein the seventh insulating layer is positioned between the fifth insulating layer and the first conductive layer, and
wherein the seventh insulating layer comprises a region having a higher nitrogen content than the fifth insulating layer.

7. The semiconductor device according to claim 1,
wherein a thickness of the first insulating layer is greater than or equal to 0.01 μm and less than 3 μm.

8. The semiconductor device according to claim 1,
wherein the first conductive layer comprises an oxide conductor.

9. The semiconductor device according to claim 1,
wherein the first conductive layer comprises a sixth conductive layer and a seventh conductive layer over the sixth conductive layer,
wherein the seventh conductive layer comprises a third opening,
wherein the first semiconductor layer comprises a region in contact with the sixth conductive layer through the third opening, and
wherein the sixth conductive layer comprises an oxide conductor.

10. The semiconductor device according to claim 1,
wherein the first semiconductor layer and the second semiconductor layer each comprise indium, and
wherein a proportion of the number of indium atoms in the total number of atoms of all contained metal elements is higher in the second semiconductor layer than in the first semiconductor layer.

11. The semiconductor device according to claim 1,
wherein the first semiconductor layer and the second semiconductor layer each comprise indium, and
wherein a proportion of the number of indium atoms in the total number of atoms of all contained metal elements is higher in the first semiconductor layer than in the second semiconductor layer.

12. The semiconductor device according to claim 1,
wherein the sixth insulating layer comprises a region having a higher film density than the fifth insulating layer.

13. The semiconductor device according to claim 3,
wherein the sixth insulating layer comprises a region having a higher film density than the fifth insulating layer.

14. The semiconductor device according to claim 3,
wherein the first insulating layer comprises a seventh insulating layer,
wherein the seventh insulating layer is positioned between the fifth insulating layer and the first conductive layer, and
wherein the seventh insulating layer comprises a region having a higher film density than the fifth insulating layer.

15. The semiconductor device according to claim 3,
wherein the first insulating layer comprises a seventh insulating layer,
wherein the seventh insulating layer is positioned between the fifth insulating layer and the first conductive layer, and
wherein the seventh insulating layer comprises a region having a higher nitrogen content than the fifth insulating layer.

16. The semiconductor device according to claim 3,
wherein a thickness of the first insulating layer is greater than or equal to 0.01 μm and less than 3 μm.

17. The semiconductor device according to claim 3,
wherein the first conductive layer comprises an oxide conductor.

18. The semiconductor device according to claim 3,
wherein the first conductive layer comprises a sixth conductive layer and a seventh conductive layer over the sixth conductive layer,
wherein the seventh conductive layer comprises a third opening,
wherein the first semiconductor layer comprises a region in contact with the sixth conductive layer through the third opening, and
wherein the sixth conductive layer comprises an oxide conductor.

19. The semiconductor device according to claim 3,
wherein the first semiconductor layer and the second semiconductor layer each comprise indium, and
wherein a proportion of the number of indium atoms in the total number of atoms of all contained metal elements is higher in the second semiconductor layer than in the first semiconductor layer.

20. The semiconductor device according to claim 3,
wherein the first semiconductor layer and the second semiconductor layer each comprise indium, and
wherein a proportion of the number of indium atoms in the total number of atoms of all contained metal elements is higher in the first semiconductor layer than in the second semiconductor layer.
